(19) United States
(12) Patent Application Publication
(10) Pub. No.: US 2024/0381745 A1
(43) Pub. Date: Nov. 14, 2024

(54) Display Device and Electronic Device

(71) Applicant: Semiconductor Energy Laboratory Co., Ltd., Kanagawa-ken (JP)

(72) Inventors: Hisao IKEDA, Zama, Kanagawa (JP); Daiki KAKAMURA, Atsugi, Kanagawa (JP); Ryo HATSUMI, Hadano, Kanagawa (JP); Shunpei YAMAZAKI, Setagaya, Tokyo (JP)

(73) Assignee: Semiconductor Energy Laboratory Co., Ltd., Kanagawa-ken (JP)

(21) Appl. No.: 18/683,621

(22) PCT Filed: Aug. 5, 2022
(86) PCT No.: PCT/IB2022/057290

§ 371 Date: Feb. 14, 2024

(30) Foreign Application Priority Data
Aug. 18, 2021 (JP) 2021-133160

(51) Int. Cl. H10K 59/80; H10K 59/38

(52) U.S. Cl. CPC H10K 59/879; H10K 59/38

(57) ABSTRACT

A display device with high display quality is provided. The display device includes a light-emitting device; a lens provided over the light-emitting device to include a region overlapping with at least the light-emitting device; a protective layer provided to cover the lens; and a coloring layer provided over the protective layer. The light-emitting device includes an EL layer interposed between a common electrode and a pixel electrode. The EL layer contains a first light-emitting material emitting blue light and a second light-emitting material emitting light having a longer wavelength than blue light. The refractive index of the lens is higher than the refractive index of the common electrode, and the refractive index of the protective layer is lower than the refractive index of the lens.

### TECHNICAL FIELD

One embodiment of the present invention relates to a display device and an electronic device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

### BACKGROUND ART

Recent display devices have been expected to be applied to a variety of uses. Usage examples of large-sized display devices include a television device for home use (also referred to as TV or television receiver), digital signage, and a PID (Public Information Display). Display devices have also been used for, for example, smartphones and tablet terminals each including a touch panel.

Furthermore, higher-resolution display devices have been required. As devices requiring high-resolution display devices, for example, devices for virtual reality (VR), augmented reality (AR), substitutional reality (SR), or mixed reality (MR) have been actively developed.

Light-emitting apparatuses that include light-emitting devices (also referred to as light-emitting elements) have been developed as display devices, for example. Light-emitting devices (also referred to as EL devices or EL elements) utilizing electroluminescence (hereinafter referred to as EL) have features such as ease of reduction in thickness and weight, high-speed response to input signals, and driving with a constant DC voltage power source, and have been used in display devices.

Patent Document 1 discloses a display device for VR that includes an organic EL device (also referred to as organic EL element).

To have improved light extraction efficiency, a display device employs a structure in which light emitted from a light-emitting device is extracted through a microlens. Patent Document 2 discloses a method for forming a microlens using a radiation-sensitive resin composite.

### REFERENCE

### Patent Documents

[Patent Document 1] PCT International Publication No. 2018/087625
[Patent Document 2] Japanese Published Patent Application No. 2020-101659

### SUMMARY OF THE INVENTION

### Problems to be Solved by the Invention

An object of one embodiment of the present invention is to provide a display device with high display quality and an electronic device that includes a display device with high display quality. An object of one embodiment of the present invention is to provide a high-resolution display device and an electronic device that includes a high-resolution display device. An object of one embodiment of the present invention is to provide a high-definition display device and an electronic device that includes a high-definition display device. An object of one embodiment of the present invention is to provide a high-luminance display device and an electronic device that includes a high-luminance display device. An object of one embodiment of the present invention is to provide a display device having high light detection performance and an electronic device that includes a display device having high light detection performance. An object of one embodiment of the present invention is to provide a highly reliable display device and an electronic device that includes a highly reliable display device. An object of one embodiment of the present invention is to provide a display device with high yield and an electronic device that includes a display device with high yield.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a display device that includes a first light-emitting device; a lens over the first light-emitting device, the lens including a region overlapping with the first light-emitting device; a protective layer covering the lens; and a coloring layer over the protective layer. The first light-emitting device includes a pixel electrode, an EL layer over the pixel electrode, and a common electrode over the EL layer; the EL layer includes a first light-emitting material emitting blue light and a second light-emitting material emitting light having a longer wavelength than blue light; a refractive index of the lens is higher than a refractive index of the common electrode; and a refractive index of the protective layer is lower than the refractive index of the lens.

Preferably, the above display device includes a second light-emitting device adjacent to the first light-emitting device, and the second light-emitting device has the same structure as the first light-emitting device and includes an insulating layer in a region between the first light-emitting device and the second light-emitting device.

In the above, a top surface of the insulating layer preferably has a convex curved shape.

In the above, the lens is preferably a plano-convex lens that has a planar surface on a side facing the common electrode and has a convex shape on a side facing the coloring layer.

Another embodiment of the present invention is a display device that includes a first light-emitting device; a first lens over the first light-emitting device, the first lens including a region overlapping with the first light-emitting device; a light-receiving device; a second lens over the light-receiving device, the second lens overlapping with the light-receiving device; a protective layer covering the first lens and the second lens; and a coloring layer over the protective layer. The first light-emitting device includes a first pixel electrode, an EL layer over the first pixel electrode, and a common electrode over the EL layer; the EL layer includes a first light-emitting material emitting blue light and a second light-emitting material emitting light having a longer wavelength than blue light; the light-receiving device includes a second pixel electrode, an active layer over the second pixel electrode, and the common electrode over the active layer; the active layer functions as a photoelectric conversion layer; a refractive index of the first lens and a refractive index of the second lens are each higher than a refractive index of the common electrode; and a refractive index of the protective layer is lower than the refractive index of the first lens and the refractive index of the second lens.

Preferably, the above display device includes a second light-emitting device adjacent to each of the first light-emitting device and the light-receiving device, and the second light-emitting device has the same structure as the first light-emitting device, includes a first insulating layer in a region between the first light-emitting device and the second light-emitting device, and includes a second insulating layer in a region between the second light-emitting device and the light-receiving device.

In the above, preferably, the first insulating layer and the second insulating layer contain the same material, and a top surface of the first insulating layer and a top surface of the second insulating layer each have a convex curved shape.

In the above, each of the first lens and the second lens is preferably a plano-convex lens that has a planar surface on a side facing the common electrode and has a convex shape on a side facing the coloring layer.

Another embodiment of the present invention is an electronic device which includes the above-described display device and an optical member and in which the display device can project display on the optical member; and the optical member is capable of transmitting light, and an image in which an image transmitted through the optical member and the display are superimposed on each other can be seen when the optical member is seen.

### Effect of the Invention

According to one embodiment of the present invention, a display device with high display quality and an electronic device that includes a display device with high display quality can be provided. According to one embodiment of the present invention, a high-resolution display device and an electronic device that includes a high-resolution display device can be provided. According to one embodiment of the present invention, a high-definition display device and an electronic device that includes a high-definition display device can be provided. According to one embodiment of the present invention, a high-luminance display device and an electronic device that includes a high-luminance display device can be provided. According to one embodiment of the present invention, a display device having high light detection performance and an electronic device that includes a display device having high light detection performance can be provided. According to one embodiment of the present invention, a highly reliable display device and an electronic device that includes a highly reliable display device can be provided. According to one embodiment of the present invention, a display device with high yield and an electronic device that includes a display device with high yield can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a display device. FIG. 1B is a cross-sectional view illustrating the example of the display device.

FIG. 2A and FIG. 2B are cross-sectional views illustrating examples of a display device.

FIG. 3A and FIG. 3B are cross-sectional views illustrating examples of a display device.

FIG. 4A and FIG. 4B are cross-sectional views illustrating an example of a display device.

FIG. 5A and FIG. 5B are cross-sectional views illustrating an example of a display device.

FIG. 6A and FIG. 6B are cross-sectional views illustrating an example of a display device.

FIG. 7A and FIG. 7B are cross-sectional views illustrating an example of a display device.

FIG. 8A and FIG. 8B are cross-sectional views illustrating examples of a display device.

FIG. 9A and FIG. 9B are cross-sectional views illustrating examples of a display device.

FIG. 10A to FIG. 10C are cross-sectional views illustrating examples of a display device.

FIG. 11A is a top view illustrating an example of a display device. FIG. 11B is a cross-sectional view illustrating the example of the display device.

FIG. 12A to FIG. 12C are cross-sectional views illustrating an example of a method for manufacturing a display device.

FIG. 13A to FIG. 13C are cross-sectional views illustrating an example of a method for manufacturing a display device.

FIG. 14A and FIG. 14B are cross-sectional views illustrating an example of a method for manufacturing a display device.

FIG. 15A and FIG. 15B are cross-sectional views illustrating an example of a method for manufacturing a display device.

FIG. 16A and FIG. 16B are cross-sectional views illustrating an example of a method for manufacturing a display device.

FIG. 17A and FIG. 17B are cross-sectional views illustrating an example of a method for manufacturing a display device.

FIG. 18 is a cross-sectional view illustrating an example of a method for manufacturing a display device.

FIG. 19A to FIG. 19D are cross-sectional views illustrating an example of a method for manufacturing a display device.

FIG. 20A to FIG. 20F are diagrams illustrating examples of pixels.

FIG. 21A to FIG. 21J are diagrams illustrating examples of a pixel.

FIG. 22A and FIG. 22B are perspective views illustrating an example of a display device.

FIG. 23 is a cross-sectional view illustrating an example of a display device.

FIG. 24 is a cross-sectional view illustrating an example of a display device.

FIG. 25 is a cross-sectional view illustrating an example of a display device.

FIG. 26 is a cross-sectional view illustrating an example of a display device.

FIG. 27 is a cross-sectional view illustrating an example of a display device.

FIG. 28 is a cross-sectional view illustrating an example of a display device.

FIG. 29 is a cross-sectional view illustrating an example of a display device.

FIG. 30 is a perspective view illustrating an example of a display device.

FIG. 31A is a cross-sectional view illustrating an example of a display device. FIG. 31B and FIG. 31C are cross-sectional views illustrating examples of transistors.

FIG. 32 is a cross-sectional view illustrating an example of a display device.

FIG. 33A to FIG. 33F are diagrams illustrating structure examples of a light-emitting device.

FIG. 34A and FIG. 34B are diagrams illustrating structure examples of a light-receiving device.

FIG. 34C to FIG. 34E are diagrams illustrating structure examples of a display device.

FIG. 35A to FIG. 35D are diagrams illustrating examples of electronic devices.

FIG. 36A to FIG. 36F are diagrams illustrating examples of electronic devices.

FIG. 37A to FIG. 37G are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same reference numerals are commonly used for the same portions or portions having similar functions in different drawings, and a repeated description thereof is omitted. The same hatching pattern is applied to portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in drawings.

Note that the term “film” and the term “layer” can be interchanged with each other depending on the case or the circumstances. For example, the term “conductive layer” can be replaced with the term “conductive film”. For another example, the term “insulating film” can be replaced with the term “insulating layer”.

In this specification and the like, a device fabricated using a metal mask or an FMM (fine metal mask) is sometimes referred to as a device having an MM (metal mask) structure. In this specification and the like, a device fabricated without using a metal mask or an FMM is sometimes referred to as a device having an MML (metal maskless) structure.

In this specification and the like, a structure in which light-emitting layers of light-emitting devices having different emission wavelengths are separately formed is sometimes referred to as an SBS (Side By Side) structure. The SBS structure allows optimization of materials and structures of light-emitting devices and thus can extend freedom of choice of the materials and the structures, which makes it easy to improve the luminance and the reliability.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be distinguished from each other on the basis of the cross-sectional shape, properties, or the like in some cases. Furthermore, one layer may have two or three functions of the carrier-injection layer, the carrier-transport layer, and the carrier-blocking layer in some cases.

In this specification and the like, a light-emitting device includes an EL layer between a pair of electrodes. The EL layer includes at least a light-emitting layer. In this specification and the like, a light-receiving device (also referred to as a light-receiving element) includes at least an active layer that functions as a photoelectric conversion layer between a pair of electrodes. In this specification and the like, one of the pair of electrodes may be referred to as a pixel electrode and the other may be referred to as a common electrode.

Note that in this specification and the like, a tapered shape refers to a shape such that at least part of a side surface of a component is inclined with respect to a substrate surface (or a formation surface). For example, a tapered shape refers to a shape that includes a region where the angle formed by the inclined side surface and the substrate surface (or the formation surface) (such an angle is also referred to as a taper angle) is greater than 0° and less than 90°. Note that the side surface of the component and the substrate surface (or the formation surface) are not necessarily completely flat and may be substantially flat with a slight curvature or substantially flat with slight unevenness.

### Embodiment 1

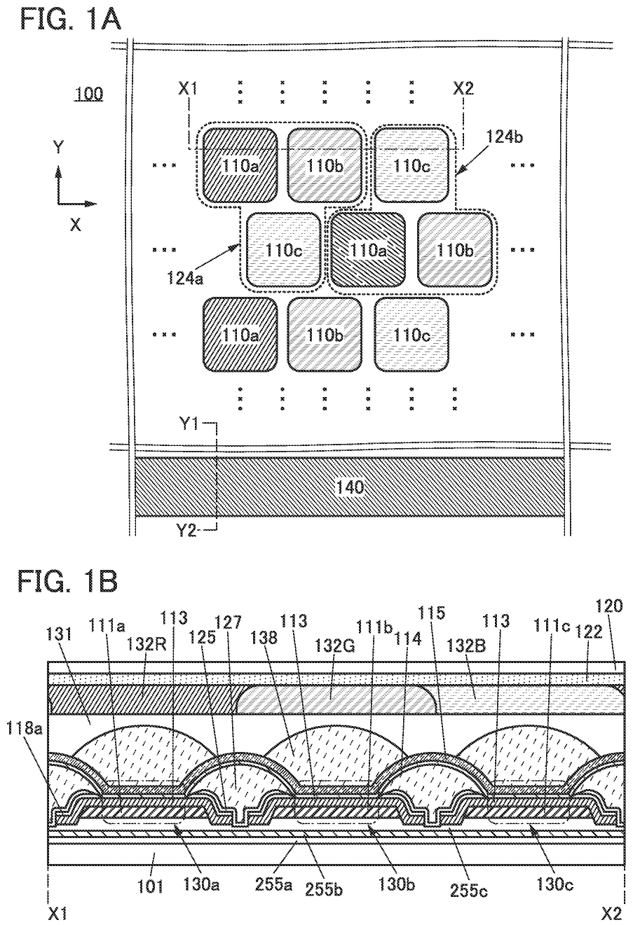

In this embodiment, display devices of embodiments of the present invention are described with reference to FIG. 1 to FIG. 11.

In the display device of one embodiment of the present invention, subpixels include light-emitting devices including EL layers with the same structure, and coloring layers overlapping with the light-emitting devices. When the subpixels are provided with coloring layers that transmit visible light of different colors, full-color display can be performed.

When light-emitting devices including EL layers with the same structure are used, layers included in the light-emitting devices other than pixel electrodes (e.g., a light-emitting layer) can be common to a plurality of subpixels. Thus, the plurality of subpixels can share a continuous film. However, some of the layers included in the light-emitting device have relatively high conductivity. When the plurality of subpixels share a continuous film with high conductivity, leakage current might be generated between the subpixels. Particularly when an increase in the resolution or the aperture ratio of a display device reduces the distance between subpixels, the leakage current might become too high to ignore and cause a decrease in display quality or the like of the display device.

In view of the above, in the display device of one embodiment of the present invention, at least one layer included in the EL layer is formed into an island shape in each light-emitting device. When at least one layer included in the EL layer is separated between the light-emitting devices, generation of crosstalk between adjacent subpixels can be inhibited. This enables the display device to achieve both high resolution and high display quality.

Note that in this specification and the like, the term “island shape” refers to a state where two or more layers formed using the same material in the same step are physically separated from each other. For example, “island-shaped light-emitting layer” means a state where the light-emitting layer and its adjacent light-emitting layer are physically separated from each other.

For example, an island-shaped light-emitting layer can be formed by a vacuum evaporation method using a metal mask. However, this method causes a deviation from the designed shape and position of an island-shaped light-emitting layer due to various influences such as the low accuracy of the metal mask, the positional deviation between the metal mask and a substrate, a warp of the metal mask, and the vapor-scattering-induced expansion of outline of the formed film; accordingly, it is difficult to achieve high resolution and a high aperture ratio of the display device. In addition, the outline of the layer may blur during vapor deposition, whereby the thickness of an end portion may be reduced. That is, the thickness of the island-shaped light-emitting layer may vary from area to area. In the case of fabricating a display device with a large size, high definition, or high resolution, the manufacturing yield might be reduced because of low dimensional accuracy of the metal mask and deformation due to heat or the like.

In view of this, in fabricating a display device of one embodiment of the present invention, fine patterning of light-emitting layers is performed by a photolithography method without a shadow mask such as a metal mask. Specifically, pixel electrodes are formed for the respective subpixels, and then a light-emitting layer is formed across the pixel electrodes. After that, the light-emitting layer is processed by a photolithography method, so that one island-shaped light-emitting layer is formed per pixel electrode. Thus, the light-emitting layer can be divided for the respective subpixels, so that island-shaped light-emitting layers can be formed for the respective subpixels.

In the case of processing the light-emitting layer into an island shape, a structure is possible where processing is performed by a photolithography method directly on the light-emitting layer. In the case of this structure, damage to the light-emitting layer (e.g., processing damage) might significantly degrade the reliability. In view of this, in fabrication of the display device of one embodiment of the present invention, a mask layer (also referred to as a sacrificial layer, a protective layer, or the like) or the like is preferably formed over a layer positioned above the light-emitting layer (e.g., a carrier-transport layer or a carrier-injection layer, specifically, an electron-transport layer, an electron-injection layer, or the like), followed by processing of the light-emitting layer into an island shape. Such a method provides a highly reliable display device. A layer provided between the light-emitting layer and the mask layer can inhibit the light-emitting layer from being exposed on the outermost surface during the fabrication process of the display device and can reduce damage to the light-emitting layer.

Note that in this specification and the like, each of a mask film and a mask layer is positioned above at least a light-emitting layer (specifically, a layer processed into an island shape among layers included in an EL layer) and has a function of protecting the light-emitting layer in the manufacturing process.

In the light-emitting devices, not all layers included in the EL layers need to be formed separately, and some layers of the EL layers can be formed in the same step. Examples of the layers (also referred to as functional layers) of the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In a method for manufacturing a display device of one embodiment of the present invention, after some layers included in the EL layers are formed into an island shape for each subpixel, at least part of the mask layer is removed and then other layers (sometimes referred to as common layers) included in the EL layers and a common electrode (also referred to as an upper electrode) are each formed so as to be shared by the subpixels (formed as one film). For example, a carrier-injection layer and a common electrode can be formed so as to be shared by the subpixels.

Meanwhile, the carrier-injection layer is often a layer having relatively high conductivity in the EL layer. Therefore, when the carrier-injection layer is in contact with the side surface of any layer of the EL layer formed into an island shape or the side surface of the pixel electrode, the light-emitting device might be short-circuited. Note that also in the case where the carrier-injection layer is provided in an island shape and the common electrode is formed to be shared by the light-emitting devices of different colors, the light-emitting device might be short-circuited when the common electrode is in contact with the side surface of the EL layer or the side surface of the pixel electrode.

Thus, the display device of one embodiment of the present invention includes an insulating layer covering at least the side surface of the island-shaped light-emitting layer. The insulating layer preferably covers part of the top surface of the island-shaped light-emitting layer.

This can inhibit at least some layers of the island-shaped EL layer and the pixel electrode from being in contact with the carrier-injection layer or the common electrode. Hence, a short circuit of the light-emitting device is inhibited, and the reliability of the light-emitting device can be increased.

In a cross-sectional view, an end portion of the insulating layer preferably has a tapered shape with a taper angle greater than 0° and less than 90°. In that case, disconnection of the common layer and the common electrode provided over the insulating layer can be prevented from occurring. Accordingly, a connection defect between the light-emitting devices caused by disconnection of the common layer and the common electrode can be inhibited. Moreover, an increase in electric resistance of the common electrode caused by local thinning of the common electrode due to a step at the end portion of the insulating layer can be inhibited.

Note that in this specification and the like, disconnection refers to a phenomenon in which a layer, a film, or an electrode is disconnected because of the shape of the formation surface (e.g., a step).

As described above, the island-shaped light-emitting layers fabricated by the method for manufacturing a display device of one embodiment of the present invention are formed not by using a fine metal mask but by processing a light-emitting layer formed over the entire surface. Accordingly, a high-resolution display device or a display device with a high aperture ratio, which has been difficult to achieve, can be manufactured. Moreover, providing the mask layer over the light-emitting layer can reduce damage to the light-emitting layer in the fabrication process of the display device, resulting in an increase in reliability of the light-emitting device.

The processing of the light-emitting layer by a photolithography method is preferably performed a small number of times, in which case the manufacturing cost can be reduced and the manufacturing yield can be improved. In the method for manufacturing a display device of one embodiment of the present invention, the number of times of processing of the light-emitting layer by a photolithography method can be one; thus, the display device can be fabricated with high yield.

It is difficult to reduce the distance between adjacent light-emitting devices to less than 10 μm with a formation method using a metal mask, for example. However, the method using photolithography according to one embodiment of the present invention can shorten the distance between adjacent light-emitting devices, the distance between adjacent EL layers, or the distance between adjacent pixel electrodes to less than 10 μm, less than or equal to 5 μm, less than or equal to 3 μm, less than or equal to 2 μm, less than or equal to 1.5 μm, less than or equal to 1 μm, or even less than or equal to 0.5 μm, for example, in a process over a glass substrate. Using a light exposure apparatus for LSI can further shorten the distance between adjacent light-emitting devices, the distance between adjacent EL layers, or the distance between adjacent pixel electrodes to less than or equal to 500 nm, less than or equal to 200 nm, less than or equal to 100 nm, or even less than or equal to 50 nm, for example, in a process over a Si wafer. Accordingly, the area of a non-light-emitting region that could exist between two light-emitting devices can be significantly reduced, and the aperture ratio can be close to 100%. For example, the display device of one embodiment of the present invention can achieve an aperture ratio higher than or equal to 40%, higher than or equal to 50%, higher than or equal to 60%, higher than or equal to 70%, higher than or equal to 80%, or higher than or equal to 90%, and lower than 100%.

Note that increasing the aperture ratio of the display device can improve the reliability of the display device. Specifically, with reference to the lifetime of a display device including an organic EL device and having an aperture ratio of 10%, the lifetime of a display device having an aperture ratio of 20% (that is, two times the aperture ratio of the reference) is approximately 3.25 times as long as that of the reference, and the lifetime of a display device having an aperture ratio of 40% (that is, four times the aperture ratio of the reference) is approximately 10.6 times as long as that of the reference. Thus, the density of current flowing to the organic EL device can be reduced with increasing aperture ratio, and accordingly the lifetime of the display device can be increased. The display device of one embodiment of the present invention can have a higher aperture ratio and thus can have higher display quality. Furthermore, the increase in aperture ratio has excellent effect that the reliability (especially the lifetime) of the display device can be significantly improved.

Furthermore, a processing size of the light-emitting layer itself can be made much smaller than that in the case of using a fine metal mask. For example, in the case of using a metal mask for forming light-emitting layers separately, a variation in the thickness occurs between the center and the edge of the light-emitting layer after processing. This causes a reduction in an effective area that can be used as a light-emitting region with respect to the whole area of the light-emitting layer after processing. By contrast, in the manufacturing method of one embodiment of the present invention, a film formed to have a uniform thickness is processed, so that island-shaped light-emitting layers can be formed to have a uniform thickness. Accordingly, even when the processing size of the light-emitting layer is minute, almost the whole area can be used as a light-emitting region. Thus, a display device having both high resolution and a high aperture ratio can be fabricated. Furthermore, the display device can be reduced in size and weight.

Specifically, for example, the display device of one embodiment of the present invention can have a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Furthermore, the display device of one embodiment of the present invention includes a convex-lens-shaped structure body over the light-emitting device. By providing the structure body over the light-emitting device, the efficiency of extraction of light emitted from the light-emitting device to the outside can be increased.

Since the light-emitting device used for one embodiment of the present invention has a top-emission structure, the light emitted from the light-emitting device is extracted to the outside through a light-transmitting conductive film that is one electrode of the light-emitting device and that transmits visible light. At this time, part of the light emitted from the light-emitting device proceeds in the lateral direction through the light-transmitting conductive film as a waveguide, causing a reduction in the efficiency of light extraction to the outside. In one embodiment of the present invention, the convex-lens-shaped structure body provided over the light-transmitting conductive film can inhibit light from proceeding in the lateral direction, whereby the efficiency of light extraction to the outside can be increased.

In the case where the display device includes a light-receiving device in one embodiment of the present invention, the convex-lens-shaped structure body can also be provided over the light-receiving device. When the structure body provided over the light-receiving device has a diameter larger than an effective area of a light-receiving portion, the capability of condensing light onto the light-receiving portion can be improved and the light-receiving device can have improved photosensitivity.

Note that although the convex-lens-shaped structure body can be provided over each of the light-emitting device and the light-receiving device, the convex-lens-shaped structure body may be provided over one of the light-emitting device and the light-receiving device.

In this specification, the above convex-lens-shaped structure body is simply referred to as a lens or a microlens in some cases. The lenses that are regularly arranged are sometimes referred to as a microlens array (MLA).

### Structure Example of Display Device

In Structure example of display device, cross-sectional structures of the display device of one embodiment of the present invention are mainly described, and a method for manufacturing the display device of one embodiment of the present invention will be described in detail in Embodiment 2.

FIG. 1A is a top view of a display device 100. The display device 100 includes a display portion in which a plurality of pixels 124a and a plurality of pixels 124b are arranged, and a connection portion 140 provided outside the display portion. The pixels 124a and the pixels 124b each include a plurality of subpixels (a subpixel 110a, a subpixel 110b, and a subpixel 110c) and employ delta arrangement. The connection portion 140 can also be referred to as a cathode contact portion.

The top surface shapes of the subpixels illustrated in FIG. 1A correspond to the top surface shapes of light-emitting regions. In this specification and the like, a top surface shape refers to a shape in a plan view, i.e., a shape seen from above.

Examples of the top surface shape of the subpixel include polygons such as a triangle, a tetragon (including a rectangle and a square), and a pentagon; polygons with rounded corners; an ellipse; and a circle.

The range of the circuit layout for forming the subpixels is not limited to the range of the subpixels illustrated in FIG. 1A and may be placed outside the subpixels. Each subpixel includes, for example, a transistor that injects a current to make a light-emitting device emit light. For example, the transistors included in the subpixel 110a may be positioned within the range of the subpixel 110b illustrated in FIG. 1A, or some or all of the transistors may be positioned outside the range of the subpixel 110a.

Although the subpixel 110a, the subpixel 110b, and the subpixel 110c have the same or substantially the same aperture ratio (also referred to as size or size of a light-emitting region) in FIG. 1A, one embodiment of the present invention is not limited thereto. The aperture ratio of each of the subpixel 110a, the subpixel 110b, and the subpixel 110c can be determined as appropriate. The subpixel 110a, the subpixel 110b, and the subpixel 110c may have different aperture ratios, or two or more of the subpixel 110a, the subpixel 110b, and the subpixel 110c may have the same or substantially the same aperture ratio.

As described above, the pixel 124a and the pixel 124b illustrated in FIG. 1A employ delta arrangement. As described above, the pixel 124a and the pixel 124b illustrated in FIG. 1A are each composed of three subpixels: the subpixel 110a, the subpixel 110b, and the subpixel 110c. The subpixel 110a, the subpixel 110b, and the subpixel 110c emit light of different colors. As examples of the subpixel 110a, the subpixel 110b, and the subpixel 110c, subpixels of three colors of red (R), green (G), and blue (B), subpixels of three colors of yellow (Y), cyan (C), and magenta (M), and the like can be given. The number of types of subpixels is not limited to three, and may be four or more. As examples of the four subpixels, subpixels of four colors of R, G, B, and white (W), subpixels of four colors of R, G, B, and Y, and the like can be given.

In this specification and the like, the row direction is sometimes referred to as X direction and the column direction is sometimes referred to as Y direction. The X direction and the Y direction intersect with each other and are, for example, orthogonal to each other (see FIG. 1A).

Although FIG. 1A illustrates an example where the connection portion 140 is positioned on the lower side of the display portion in the top view, there is no particular limitation on the position of the connection portion 140. The connection portion 140 may be provided in at least one of the upper side, the right side, the left side, and the lower side of the display portion in the top view, and may be provided so as to surround the four sides of the display portion. The top surface shape of the connection portion 140 can be a belt-like shape, an L shape, a U shape, a frame-like shape, or the like. The number of connection portions 140 can be one or more.

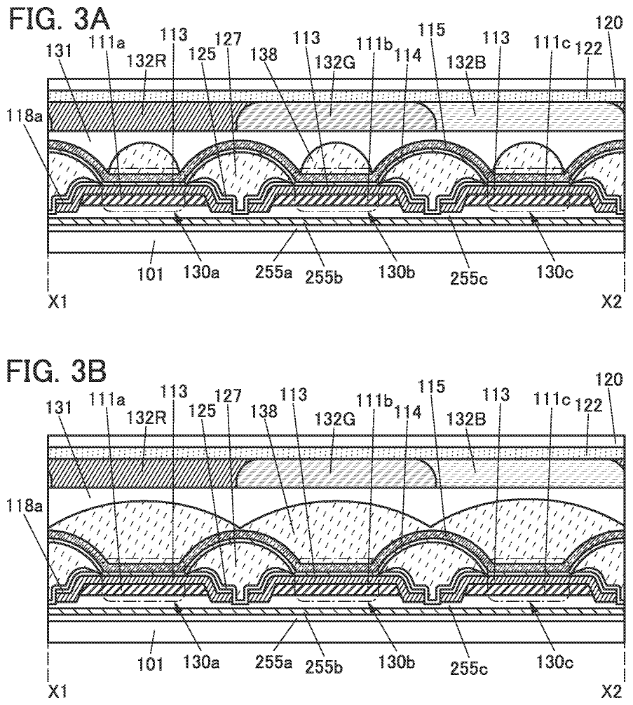

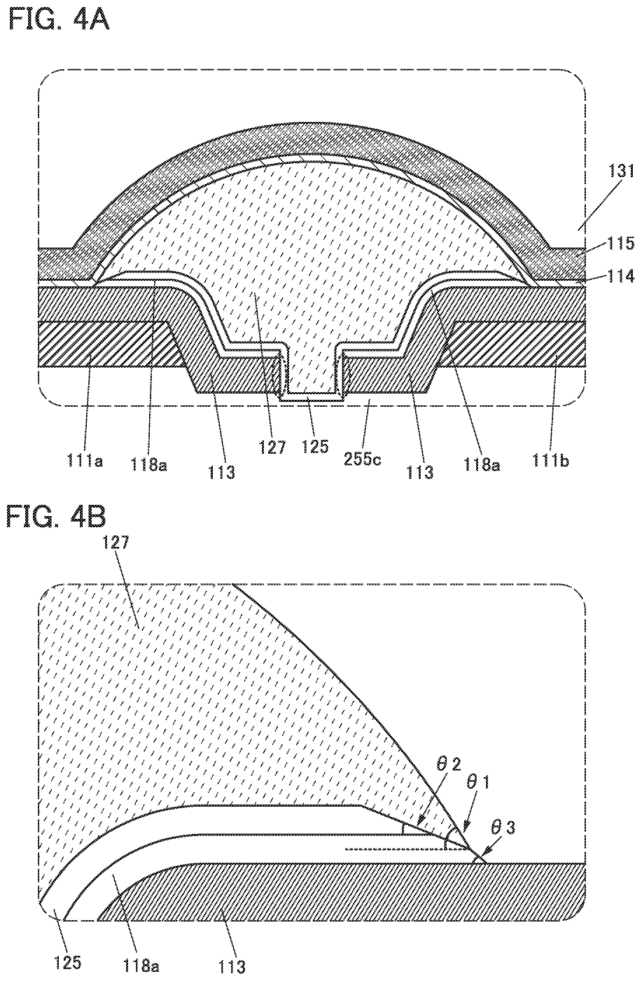

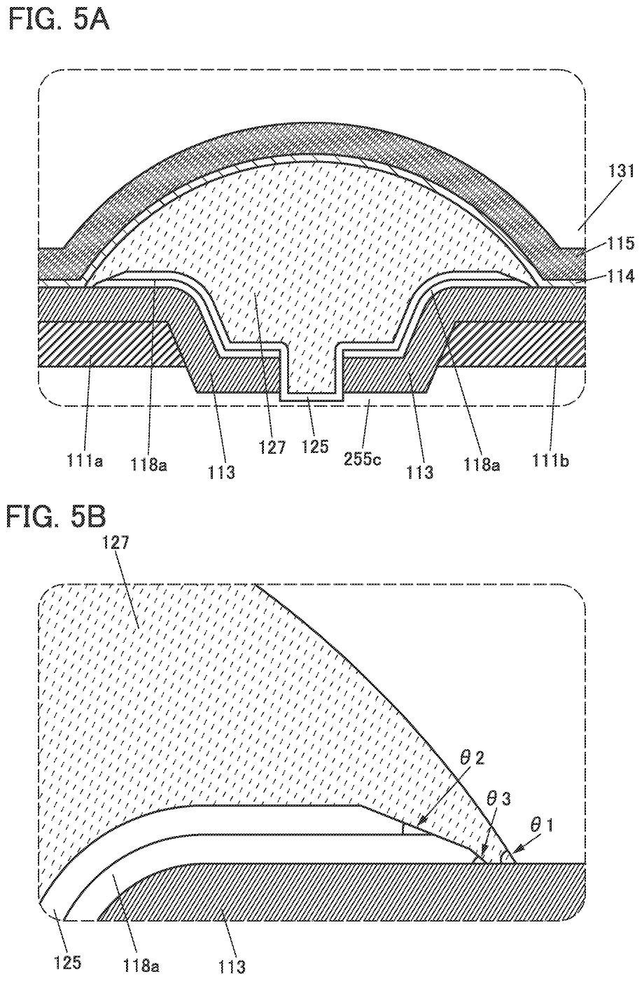

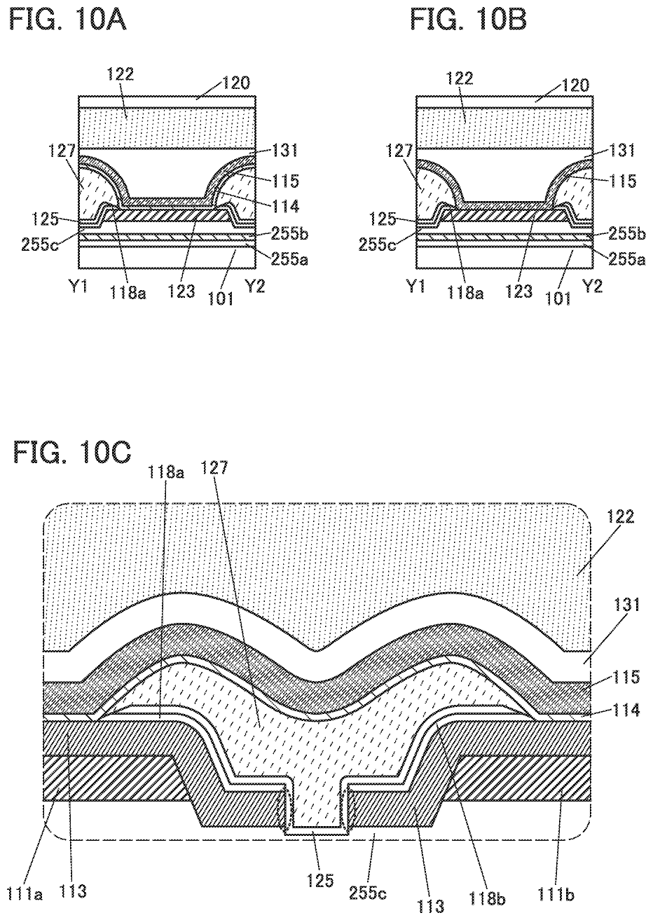

FIG. 1B is a cross-sectional view along the dashed-dotted line X1-X2 in FIG. 1A. FIG. 3A and FIG. 3B show modification examples of FIG. 1B. FIG. 4A and FIG. 4B are enlarged views of part of the cross-sectional view in FIG. 1B. FIG. 5 to FIG. 8 and FIG. 10C show modification examples of FIG. 4. FIG. 10A and FIG. 10B each illustrate a cross-sectional view along the dashed-dotted line Y1-Y2 in FIG. 1A.

The subpixel 110a includes a light-emitting device 130a and a coloring layer 132R transmitting red light. Thus, light emitted from the light-emitting device 130a is extracted as red light to the outside of the display device 100 through the coloring layer 132R.

Similarly, the subpixel 110b includes a light-emitting device 130b and a coloring layer 132G transmitting green light. Thus, light emitted from the light-emitting device 130b is extracted as green light to the outside of the display device 100 through the coloring layer 132G.

Similarly, the subpixel 110c includes a light-emitting device 130c and a coloring layer 132B transmitting blue light. Thus, light emitted from the light-emitting device 130c is extracted as blue light to the outside of the display device 100 through the coloring layer 132B.

As illustrated in FIG. 1B, in the display device 100, insulating layers (an insulating layer 255a, an insulating layer 255b, and an insulating layer 255c) are provided over a layer 101 including transistors (the transistors are not illustrated in the drawing). The light-emitting device 130a, the light-emitting device 130b, and the light-emitting device 130c are provided over the insulating layers. A lens 138 is provided over each light-emitting device so as to include a region overlapping with at least the light-emitting device, and the protective layer 131 is provided to cover the lenses 138. The coloring layer 132R, the coloring layer 132G, and the coloring layer 132B are provided over the protective layer 131, and the substrate 120 is attached onto the coloring layer 132R, the coloring layer 132G, and the coloring layer 132B with the resin layer 122. In a region between adjacent light-emitting devices, an insulating layer 125 and an insulating layer 127 over the insulating layer 125 are provided.

Although FIG. 1B illustrates a plurality of cross sections of the insulating layer 125 and the insulating layer 127, the insulating layer 125 and the insulating layer 127 are each a continuous layer when the display device 100 is seen from above. In other words, the display device 100 can have a structure including one insulating layer 125 and one insulating layer 127, for example. Note that the display device 100 may include a plurality of the insulating layers 125 which are separated from each other and a plurality of the insulating layers 127 which are separated from each other.

The display device of one embodiment of the present invention has a top-emission structure where light is emitted in a direction opposite to the substrate where the light-emitting device is formed.

The layer 101 including transistors can employ a stacked-layer structure where a plurality of transistors are provided over a substrate and an insulating layer is provided to cover these transistors, for example. The insulating layer over the transistors may have a single-layer structure or a stacked-layer structure. In FIG. 1B, the insulating layer 255a, the insulating layer 255b over the insulating layer 255a, and the insulating layer 255c over the insulating layer 255b are illustrated as the insulating layer over the transistors. The insulating layers may have a depressed portion between adjacent light-emitting devices. FIG. 1B and the like illustrate examples where a depressed portion is provided in the insulating layer 255c. Note that the insulating layers (the insulating layer 255a to the insulating layer 255c) over the transistors can be regarded as part of the layer 101 including transistors.

As each of the insulating layer 255a, the insulating layer 255b, and the insulating layer 255c, any of a variety of inorganic insulating films such as an oxide insulating film, a nitride insulating film, an oxynitride insulating film, and a nitride oxide insulating film can be suitably used. As each of the insulating layer 255a and the insulating layer 255c, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. Specifically, it is preferable that a silicon oxide film be used as each of the insulating layer 255a and the insulating layer 255c and a silicon nitride film be used as the insulating layer 255b. The insulating layer 255b preferably has a function of an etching protective film.

Note that in this specification and the like, an oxynitride refers to a material in which an oxygen content is higher than a nitrogen content, and a nitride oxide refers to a material in which a nitrogen content is higher than an oxygen content. For example, silicon oxynitride refers to a material in which an oxygen content is higher than a nitrogen content, and silicon nitride oxide refers to a material in which a nitrogen content is higher than an oxygen content.

Structure examples of the layer 101 including transistors will be described later in Embodiment 4.

As the light-emitting device, an OLED (Organic Light Emitting Diode) or a QLED (Quantum-dot Light Emitting Diode) is preferably used. Examples of a light-emitting substance contained in the light-emitting device include a substance exhibiting fluorescence (a fluorescent material), a substance exhibiting phosphorescence (a phosphorescent material), an inorganic compound (a quantum dot material or the like), and a substance exhibiting thermally activated delayed fluorescence (a thermally activated delayed fluorescence (TADF) material). In addition, an LED (Light Emitting Diode) such as a micro LED can also be used as the light-emitting device.

The light-emitting device can emit white light. Furthermore, the color purity can be increased when the light-emitting device has a microcavity structure.

Embodiment 5 can be referred to for the structure and materials of the light-emitting device.

One of a pair of electrodes of the light-emitting device functions as an anode and the other electrode functions as a cathode. The case where the pixel electrode functions as an anode and the common electrode functions as a cathode is described below as an example in some cases.

The light-emitting device 130a includes a pixel electrode 111a over the insulating layer 255c, an island-shaped first layer 113 over the pixel electrode 111a, a common layer 114 over the first layer 113, and a common electrode 115 over the common layer 114. The light-emitting device 130b includes a pixel electrode 111b over the insulating layer 255c, the island-shaped first layer 113 over the pixel electrode 111b, the common layer 114 over the first layer 113, and the common electrode 115 over the common layer 114. The light-emitting device 130c includes a pixel electrode 111c over the insulating layer 255c, the island-shaped first layer 113 over the pixel electrode 111c, the common layer 114 over the first layer 113, and the common electrode 115 over the common layer 114. In each of the light-emitting device 130a, the light-emitting device 130b, and the light-emitting device 130c, the first layer 113 and the common layer 114 can be collectively referred to as an EL layer.

In the EL layers included in the light-emitting devices, the island-shaped layers provided in the respective light-emitting devices are referred to as the first layers 113, and the layer shared by the light-emitting devices is referred to as the common layer 114 in this specification and the like. Note that in this specification and the like, the first layers 113 are sometimes referred to as island-shaped EL layers, EL layers formed into an island shape, or the like, in which case the common layer 114 is not included in the EL layer.

The light-emitting device 130a, the light-emitting device 130b, and the light-emitting device 130c each include the first layer 113, and the first layers 113 are apart from each other. When the EL layer is provided in an island shape for each light-emitting device, a leakage current between adjacent light-emitting devices can be inhibited. This can prevent crosstalk due to unintended light emission, so that a display device with extremely high contrast can be obtained. Specifically, a display device having high current efficiency at low luminance can be obtained.

When the light-emitting device 130a, the light-emitting device 130b, and the light-emitting device 130c include EL layers with the same structure, the steps of fabricating the display device can be reduced, which can reduce the manufacturing cost and increase the manufacturing yield.

End portions of the pixel electrode 111a, the pixel electrode 111b, and the pixel electrode 111c each preferably have a tapered shape. Specifically, the end portions of the pixel electrode 111a, the pixel electrode 111b, and the pixel electrode 111c each preferably have a tapered shape with a taper angle greater than 0° and less than 90°. In the case where the end portions of these pixel electrodes have a tapered shape, the first layers 113 provided along the side surfaces of the pixel electrodes also have a tapered shape. When the side surface of the pixel electrode has a tapered shape, coverage with the EL layer provided along the side surface of the pixel electrode can be improved. Furthermore, when the side surface of the pixel electrode has a tapered shape, a material (also referred to as dust or particles) in the fabrication step is easily removed by treatment such as cleaning, which is preferable.

In FIG. 1B, an insulating layer covering an end portion of the top surface of the pixel electrode is not provided between the pixel electrode and the first layer 113. Thus, the distance between adjacent light-emitting devices can be extremely short. Accordingly, the display device can have high resolution or high definition. In addition, a mask for forming the insulating layer is not needed, which leads to a reduction in manufacturing cost of the display device.

Furthermore, light emitted from the EL layer can be extracted efficiently with a structure where an insulating layer covering the end portion of the top surface of the pixel electrode is not provided between the pixel electrode and the EL layer, i.e., a structure where an insulating layer is not provided between the pixel electrode and the EL layer. Therefore, the viewing angle dependence of the display device of one embodiment of the present invention can be extremely small. A reduction in the viewing angle dependence leads to an increase in visibility of an image on the display device. For example, in the display device of one embodiment of the present invention, the viewing angle (the maximum angle with a certain contrast ratio maintained when the screen is seen from an oblique direction) can be greater than or equal to 100° and less than 180°, preferably greater than or equal to 150° and less than or equal to 170°. Note that the above viewing angle refers to that in both the vertical direction and the horizontal direction.

The light-emitting device of this embodiment may have either a single structure (a structure including only one light-emitting unit) or a tandem structure (a structure including a plurality of light-emitting units). The light-emitting unit includes at least one light-emitting layer.

The first layer 113 includes at least a light-emitting layer. The first layer 113 may include one or more of a hole-injection layer, a hole-transport layer, a hole-blocking layer, a charge-generation layer, an electron-blocking layer, an electron-transport layer, and an electron-injection layer.

For example, the first layer 113 can contain a light-emitting material that emits blue light and a light-emitting material that emits visible light having a longer wavelength than blue light. For example, a structure containing a light-emitting material that emits blue light and a light-emitting material that emits yellow light, or a structure containing a light-emitting material that emits blue light, a light-emitting material that emits green light, and a light-emitting material that emits red light can be used for the first layer 113.

As each of the light-emitting device 130a, the light-emitting device 130b, and the light-emitting device 130c, for example, a single-structure light-emitting device including two light-emitting layers, which are a light-emitting layer emitting yellow (Y) light and a light-emitting layer emitting blue (B) light, or a single-structure light-emitting device including three light-emitting layers, which are a light-emitting layer emitting red (R) light, a light-emitting layer emitting green (G) light, and a light-emitting layer emitting blue light, can be used. As examples of the number of stacked light-emitting layers and the order of colors thereof, a three-layer structure of R, G, and B and a three-layer structure of R, B, and G from the anode side can be given. Another layer (also referred to as a buffer layer) may be provided between two light-emitting layers.

In the case where a light-emitting device with a tandem structure is used, examples of applicable structures are as follows: a two-unit tandem structure including a light-emitting unit that emits yellow light and a light-emitting unit that emits blue light; a two-unit tandem structure including a light-emitting unit that emits red light and green light and a light-emitting unit that emits blue light; and a three-unit tandem structure in which a light-emitting unit that emits blue light, a light-emitting unit that emits yellow, yellow-green, or green light and red light, and a light-emitting unit that emits blue light are stacked in this order. Examples of the number of stacked light-emitting units and the order of colors from an anode side include a two-unit structure of B and Y; a two-unit structure of B and X; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

In the case of using a tandem light-emitting device, the first layer 113 includes a plurality of light-emitting units. A charge-generation layer is preferably provided between the light-emitting units.

The light-emitting unit includes at least one light-emitting layer. For example, when emission colors of the plurality of light-emitting units are complementary to each other, the light-emitting device can emit white light. The light-emitting unit may include one or more of a hole-injection layer, a hole-transport layer, a hole-blocking layer, an electron-blocking layer, an electron-transport layer, and an electron-injection layer.

In the case where the light-emitting device configured to emit white light has a microcavity structure, light with a specific wavelength such as red light, green light, blue light, or infrared light is sometimes intensified and emitted.

The first layer 113 may include a hole-injection layer, a hole-transport layer, a light-emitting layer, and an electron-transport layer in this order, for example. In addition, an electron-blocking layer may be provided between the hole-transport layer and the light-emitting layer. Furthermore, an electron-injection layer may be provided over the electron-transport layer.

The first layer 113 may include an electron-injection layer, an electron-transport layer, a light-emitting layer, and a hole-transport layer in this order, for example. In addition, a hole-blocking layer may be provided between the electron-transport layer and the light-emitting layer. Furthermore, a hole-injection layer may be provided over the hole-transport layer.

The first layer 113 preferably includes a light-emitting layer and a carrier-transport layer (an electron-transport layer or a hole-transport layer) over the light-emitting layer. Since a surface of the first layer 113 is exposed in the manufacturing process of the display device, providing the carrier-transport layer over the light-emitting layer inhibits the light-emitting layer from being exposed on the outermost surface, so that damage to the light-emitting layer can be reduced. Thus, the reliability of the light-emitting device can be increased.

The first layer 113 includes a first light-emitting unit, a charge-generation layer, and a second light-emitting unit, for example.

The second light-emitting unit preferably includes a light-emitting layer and a carrier-transport layer (an electron-transport layer or a hole-transport layer) over the light-emitting layer. Since a surface of the second light-emitting unit is exposed in the manufacturing process of the display device, providing the carrier-transport layer over the light-emitting layer inhibits the light-emitting layer from being exposed on the outermost surface, so that damage to the light-emitting layer can be reduced. Thus, the reliability of the light-emitting device can be increased. Note that in the case where three or more light-emitting units are provided, the uppermost light-emitting unit preferably includes a light-emitting layer and a carrier-transport layer (an electron-transport layer or a hole-transport layer) over the light-emitting layer.

The common layer 114 includes an electron-injection layer or a hole-injection layer, for example. Alternatively, the common layer 114 may include a stack of an electron-transport layer and an electron-injection layer, and may include a stack of a hole-transport layer and a hole-injection layer. The common layer 114 is shared by the light-emitting device 130a, the light-emitting device 130b, and the light-emitting device 130c.

FIG. 1B illustrates an example where an end portion of the first layer 113 is positioned outward from the end portion of the pixel electrode. In FIG. 1B, the first layer 113 is formed to cover the end portion of the pixel electrode. Such a structure enables the entire top surface of the pixel electrode to be a light-emitting region, and the aperture ratio can be easily increased as compared with the structure where an end portion of the island-shaped EL layer is positioned inward from the end portion of the pixel electrode.

Covering the side surface of the pixel electrode with the EL layer inhibits contact between the pixel electrode and the common electrode 115, thereby inhibiting a short circuit of the light-emitting device. Furthermore, the distance between the light-emitting region (i.e., the region overlapping with the pixel electrode) in the EL layer and the end portion of the EL layer can be increased. Since the end portion of the EL layer might be damaged by processing, the use of a region away from the end portion of the EL layer as a light-emitting region can improve the reliability of the light-emitting device in some cases.

The common electrode 115 is shared by the light-emitting device 130a, the light-emitting device 130b, and the light-emitting device 130c. The common electrode 115 shared by the light-emitting devices is electrically connected to a conductive layer 123 provided in the connection portion 140 (see FIG. 10A and FIG. 10B). As the conductive layer 123, a conductive layer formed using the same material in the same step as the pixel electrode 111a, the pixel electrode 111b, and the pixel electrode 111c is preferably used.

Note that FIG. 10A illustrates an example where the common layer 114 is provided over the conductive layer 123 and the conductive layer 123 and the common electrode 115 are electrically connected to each other through the common layer 114. The common layer 114 is not necessarily provided in the connection portion 140. In FIG. 10B, the conductive layer 123 and the common electrode 115 are directly connected to each other. For example, by using a mask for defining a film formation area (also referred to as an area mask, a rough metal mask, or the like to be distinguished from a fine metal mask), the common layer 114 can be formed in a region different from a region where the common electrode 115 is formed.

In FIG. 1B, a mask layer 118a is positioned over the first layer 113 included in the light-emitting device. The mask layer 118a is a remaining portion of a mask layer provided in contact with the top surface of the first layer 113 at the time of processing the first layer 113. Thus, in the display device of one embodiment of the present invention, the mask layer used for protecting the EL layer in the manufacture of the display device may partly remain.

In FIG. 1B, one end portion of the mask layer 118a is aligned or substantially aligned with the end portion of the first layer 113, and the other end portion of the mask layer 118a is positioned over the first layer 113. Here, the other end portion of the mask layer 118a preferably overlaps with the first layer 113 and the pixel electrode. In that case, the other end portion of the mask layer 118a is easily formed over a substantially flat surface of the first layer 113. The mask layer 118a remains between the top surface of the EL layer processed into an island shape (the first layer 113) and the insulating layer 125. The mask layer will be described in detail in Embodiment 2.

In the case where end portions are aligned or substantially aligned with each other and the case where top surface shapes are the same or substantially the same, it can be said that outlines of stacked layers at least partly overlap with each other in a top view. For example, in the case where the upper layer and the lower layer are processed with the use of the same mask pattern or mask patterns that are partly the same, it can be said that end portions of the upper layer and the lower layer are aligned or substantially aligned with each other and that top surface shapes of the upper layer and the lower layer are the same or substantially the same. However, in some cases, the outlines do not completely overlap with each other and the upper layer is positioned inward from the lower layer or the upper layer is positioned outward from the lower layer; such a case is also represented by the expression “end portions are substantially aligned with each other” or “top surface shapes are the same or substantially the same”.

The side surface of the first layer 113 is covered with the insulating layer 125. The insulating layer 127 overlaps with the side surface of the first layer 113 with the insulating layer 125 therebetween.

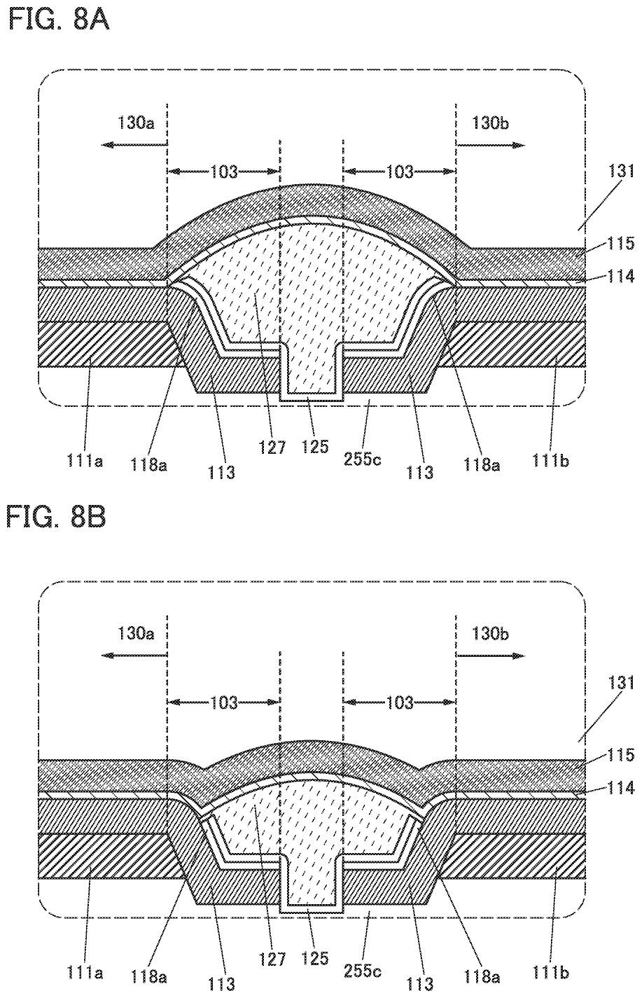

The top surface of the first layer 113 is partly covered with the mask layer 118a. The insulating layer 125 and the insulating layer 127 overlap with part of the top surface of each of the adjacent first layers 113 with the mask layer 118a therebetween. Note that the top surface of each of the adjacent first layers 113 is not limited to the top surface of a flat portion overlapping with the top surface of the pixel electrode, and can include the top surfaces of the inclined portion and the flat portion (see a region 103 in FIG. 8A) which are positioned outward from the top surface of the pixel electrode.

The side surface and part of the top surface of each of the first layers 113 are covered with at least one of the insulating layer 125, the insulating layer 127, and the mask layer 118a, so that the common layer 114 (or the common electrode 115) can be inhibited from being in contact with the side surfaces of the pixel electrode 111a, the pixel electrode 111b, the pixel electrode 111c, and the first layers 113, inhibiting a short circuit of the light-emitting devices. Thus, the reliability of the light-emitting devices can be increased.

The insulating layer 125 is preferably in contact with the side surfaces of the first layers 113 (see portions surrounded by dashed lines including the end portions of the first layers 113 and the vicinities thereof illustrated in FIG. 4A). The insulating layer 125 in contact with the first layers 113 can prevent peeling of the first layers 113. Close contact between the insulating layer 125 and the first layers 113 has an effect of fixing or bonding the adjacent first layers 113 by the insulating layer 125. Thus, the reliability of the light-emitting devices can be increased. The manufacturing yield of the light-emitting devices can be increased.

When the insulating layer 125 and the insulating layer 127 cover both the side surface and part of the top surface of the first layer 113 as illustrated in FIG. 1B, peeling of the EL layer can be further prevented and the reliability of the light-emitting device can be improved. The manufacturing yield of the light-emitting device can be increased.

FIG. 1B illustrates an example where the stacked-layer structure of the first layer 113, the mask layer 118a, the insulating layer 125, and the insulating layer 127 is positioned over the end portion of the pixel electrode 11a, the end portion of the pixel electrode 111b, and the end portion of the pixel electrode 111c.

FIG. 1B illustrates a structure where the end portions of the pixel electrode 11a, the pixel electrode 111b, and the pixel electrode 111c are each covered with the first layer 113 and the insulating layer 125 is in contact with the side surfaces of the first layers 113.

The insulating layer 127 is provided over the insulating layer 125 to fill a depressed portion formed along the insulating layer 125. The insulating layer 127 can overlap with the side surface and part of the top surface of the first layer 113 with the insulating layer 125 therebetween. The insulating layer 127 preferably covers at least part of the side surface of the insulating layer 125.

The insulating layer 125 and the insulating layer 127 can fill a gap between the adjacent island-shaped EL layers, whereby unevenness with a large level difference on the formation surface of layers (e.g., a carrier-injection layer and the common electrode) provided over the island-shaped EL layers can be reduced and the formation surface can be flatter. Consequently, the coverage with the carrier-injection layer, the common electrode, and the like over the island-shaped EL layers can be improved.

The common layer 114 and the common electrode 115 are provided over the first layers 113, the mask layers 118a, the insulating layer 125, and the insulating layer 127. At the stage before the insulating layer 125 and the insulating layer 127 are provided, a step is generated owing to a region where the pixel electrode and the island-shaped EL layer are provided and a region where the pixel electrode and the island-shaped EL layer are not provided (a region between the light-emitting devices). In the display device of one embodiment of the present invention, the step can be planarized with the insulating layer 125 and the insulating layer 127, and the coverage with the common layer 114 and the common electrode 115 over the island-shaped EL layers can be improved. Thus, a connection defect between the light-emitting devices caused by disconnection of the common layer 114 and the common electrode 115 due to the step can be inhibited. In addition, an increase in electric resistance of the common electrode 115 caused by local thinning of the common electrode 115 due to the step can be inhibited.

The top surface of the insulating layer 127 preferably has a shape with higher planarity; however, it may include a projecting portion, a convex curved surface, a concave curved surface, or a depressed portion. For example, the top surface of the insulating layer 127 preferably has a smooth convex curved shape with high planarity.

The common layer 114 is provided over the pixel electrodes (the pixel electrode 11a, the pixel electrode 111b, and the pixel electrode 111c), the first layers 113, the mask layers 118a, the insulating layer 125, and the insulating layer 127 to cover them, and the common electrode 115 is provided over the common layer 114. The lens 138 is provided over each of the light-emitting devices (the light-emitting device 130a, the light-emitting device 130b, and the light-emitting device 130c) so as to include a region overlapping with at least the light-emitting device. The protective layer 131 is provided over the lenses 138 to cover the lenses 138.

The lenses 138 each preferably have a convex curved surface. The lenses 138 are preferably formed using a material having a higher refractive index than the common electrode 115 and the protective layer 131, each of which includes regions in contact with the lenses 138. For example, the lenses 138 are preferably formed using the same material as the insulating layer 127. In that case, the lenses 138 function as plano-convex lenses (which will be described later) for light emitted from the light-emitting devices, and the light can be extracted toward the coloring layers (the coloring layer 132R, the coloring layer 132G, and the coloring layer 132B) through the lenses 138 and the protective layer 131 more efficiently than when the lenses 138 are not provided. In other words, providing the lenses 138 over the light-emitting devices can increase the luminance of the display device.

Next, examples of materials of the insulating layer 125, the insulating layer 127, and the lenses 138 are described.

The insulating layer 125 can contain an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium-gallium-zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferably used because it has high selectivity with respect to the EL layer in etching and has a function of protecting the EL layer when the insulating layer 127 to be described later is formed. In particular, when an inorganic insulating film such as an aluminum oxide film, a hafnium oxide film, or a silicon oxide film that is formed by an atomic layer deposition (ALD) method is used for the insulating layer 125, it is possible to form the insulating layer 125 that has few pinholes and an excellent function of protecting the EL layer. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

Note that in this specification and the like, a barrier insulating layer refers to an insulating layer having a barrier property. A barrier property in this specification and the like refers to a function of inhibiting diffusion of a particular substance (also referred to as low permeability). Alternatively, a barrier property refers to a function of capturing or fixing (also referred to as gettering) a particular substance.

When the insulating layer 125 has a function of a barrier insulating layer or a gettering function, entry of impurities (typically, at least one of water and oxygen) that might diffuse into the light-emitting devices from the outside can be inhibited. With this structure, a highly reliable light-emitting device and a highly reliable display device can be provided.

The insulating layer 125 preferably has a low impurity concentration. In that case, deterioration of the EL layer due to entry of impurities from the insulating layer 125 into the EL layer can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

Note that the insulating layer 125 and the mask layer 118a can be formed using the same material. In that case, the boundary between the insulating layer 125 and the mask layer 118a is sometimes unclear, so that the layers cannot be distinguished from each other. Thus, the insulating layer 125 and the mask layer 118a are observed as one layer in some cases. That is, in observation, it sometimes seems that one layer is provided in contact with the side surface and part of the top surface of the first layer 113, and the insulating layer 127 covers at least part of the side surface of the one layer.

The insulating layer 127 provided over the insulating layer 125 has a function of reducing unevenness with a large level difference on the insulating layer 125 formed between adjacent light-emitting devices. In other words, the insulating layer 127 has an effect of improving the planarity of the formation surface of the common electrode 115.

As each of the insulating layer 127 and the lenses 138, an insulating layer containing an organic material can be suitably used. As the organic material, a photosensitive organic resin is preferably used, and for example, a photosensitive acrylic resin is preferably used. Note that in this specification and the like, an acrylic resin refers to not only a polymethacrylic acid ester or a methacrylic resin, but also all the acrylic polymers in a broad sense in some cases.

For the insulating layer 127 and the lenses 138, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like may be used. Alternatively, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used for the insulating layer 127 and the lenses 138. A photoresist may be used as the photosensitive resin. As the photosensitive organic resin, either a positive material or a negative material may be used.

The insulating layer 127 may be formed using a material absorbing visible light. When the insulating layer 127 absorbs light emitted from the light-emitting device, leakage of light (stray light) from the light-emitting device to the adjacent light-emitting device through the insulating layer 127 can be inhibited. Thus, the display quality of the display device can be improved. Since the display quality of the display device can be improved without using a polarizing plate in the display device, the weight and thickness of the display device can be reduced.

Examples of the material absorbing visible light include a material containing a pigment of black or the like, a material containing a dye, a resin material with a light-absorbing property (e.g., polyimide), and a resin material that can be used for a color filter (a color filter material). A resin material obtained by stacking or mixing color filter materials of two or three or more colors is particularly preferably used to enhance the effect of blocking visible light. In particular, mixing color filter materials of three or more colors enables the formation of a black or nearly black resin layer.

As described above, the lenses 138 each function as a plano-convex lens (which will be described later) for extracting the light emitted from the light-emitting device efficiently and causing the light to be emitted toward the coloring layer. Thus, the lenses 138 are preferably formed using a material that transmits visible light (i.e., has a light-transmitting property). For example, in the case where a material absorbing visible light is used for the insulating layer 127 as described above, a different material (a material that transmits visible light) is preferably used for the lenses 138. In the case where a material that transmits visible light is used for the insulating layer 127, the same material is preferably used for the lenses 138.

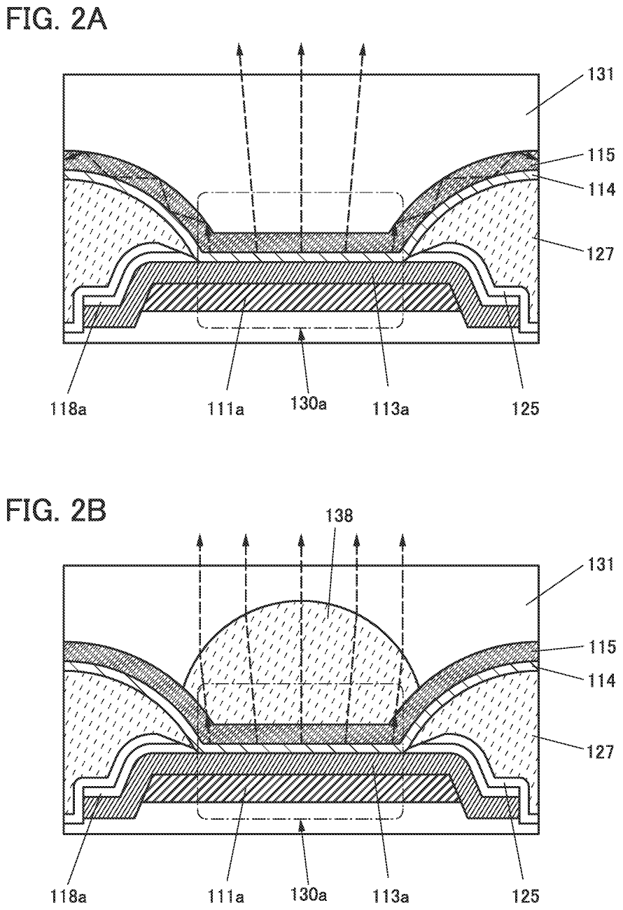

FIG. 2A and FIG. 2B are diagrams illustrating the effect of the lenses 138 provided over the light-emitting devices (the light-emitting device 130a, the light-emitting device 130b, and the light-emitting device 130c). Note that FIG. 2A shows a cross-sectional view of the case where the lens 138 is not provided over the light-emitting device 130a, and FIG. 2B shows a cross-sectional view of the case where the lens 138 is provided over the light-emitting device 130a.

Although the difference in optical path between the case where the lens 138 is not provided over the light-emitting device 130a and the case where the lens 138 is provided over the light-emitting device 130a is described below with reference to FIG. 2A and FIG. 2B, similar description can be applied to the structure over the light-emitting device 130b and the structure over the light-emitting device 130c.

FIG. 2A is a diagram simply illustrating an optical path of light emitted from the light-emitting device over which the lens 138 is not provided. Note that slight reflection or the like at interfaces between layers is not illustrated. Most of the light emitted from the light-emitting device passes through a perpendicular optical path or a substantially perpendicular optical path and is extracted to the outside. However, as illustrated in FIG. 2A, part of the light emitted from the light-emitting device proceeds in the lateral direction through the common electrode 115, which is formed of a light-transmitting conductive film and provided over the insulating layer 127, as a waveguide, and fails to be extracted to the outside. That is, this phenomenon may be one factor in a reduction in light extraction efficiency.

As an example of a factor causing the above common electrode 115 to serve as a waveguide, a difference in refractive index between the common electrode 115 and layers over and under the common electrode 115 can be given. Another factor is an increase in incident angle of light entering the common electrode 115 over the insulating layer 127 due to the common electrode 115 provided to extend beyond the insulating layer 127.

As illustrated in FIG. 2A, the protective layer 131 is provided over and in contact with the common electrode 115, and the common layer 114 is provided under and in contact with the common electrode 115. Here, when n₁₁₅>n₁₃₁ and n₁₁₅>n₁₁₄ are satisfied, where n₁₁₅ is the refractive index of the common electrode 115, n₁₃₁ is the refractive index of the protective layer 131, and n₁₁₄ is the refractive index of the common layer 114, light with a large incident angle with respect to an interface of each layer is likely to be totally reflected. Thus, the light does not enter the protective layer 131 or the common layer 114 and proceeds in the lateral direction through the common electrode 115 as a waveguide. Note that the refractive index here refers to a refractive index with respect to light in the range of the wavelengths of light emitted from the light-emitting devices (the wavelength range of blue to red) or a refractive index with respect to visible light.

In the case where the light-emitting device has a micro optical resonator (microcavity) structure, an electrode having a light-transmitting property and a light-reflecting property (a semi-transmissive and semi-reflective electrode) is preferably used as the common electrode 115. Thus, an electrode having a reflecting property is formed on the common layer 114 side of the common electrode 115 in some cases. Thus, light reflection by the electrode is one of the factors causing the common electrode 115 to serve as a waveguide.

Therefore, in one embodiment of the present invention, as illustrated in FIG. 2B, the lens 138 is provided between the common electrode 115 and the protective layer 131 in a region overlapping with at least a light-emitting portion of the light-emitting device. Note that in FIG. 2B, the light-emitting portion is a region where the first layer 113 and the common layer 114 are in contact with each other. In the case where the common layer 114 is not provided, the light-emitting portion is a region where the first layer 113 and the common electrode 115 are in contact with each other.

A lens having a convex surface and a planar surface on the surface opposite to the convex surface as illustrated in FIG. 2B is referred to as a plano-convex lens. The lens 138 can be fabricated using a material and a process similar to those for the insulating layer 127 described above.

In one embodiment of the present invention, the lens 138 is formed such that the surface opposite to the convex surface of the plano-convex lens is in contact with the common electrode 115. Furthermore, n₁₃₈ is equivalent to n₁₁₅, preferably higher than n₁₁₅, where n₁₃₈ is the refractive index of the lens 138.

With such a structure, even when light enters the interface between the common electrode 115 and the lens 138 at a large incident angle, the light is not totally reflected at the interface but is transmitted from the common electrode 115 to the lens 138 side. Thus, providing the lens 138 having the aforementioned refractive index can increase the extraction efficiency of light emitted from the light-emitting device.

Even in the case where n₁₃₈ is lower than n₁₁₅, setting the difference therebetween small can inhibit light that has entered the interface between the common electrode 115 and the lens 138 at a relatively large incident angle from being totally reflected at the interface and can facilitate transmission of the light from the common electrode 115 to the lens 138 side. In that case, for example, n₁₃₈ is a value smaller than n₁₁₅ by 1% to 30%, preferably n₁₃₈ is a value smaller than n₁₁₅ by 1% to 20%, and further preferably n₁₃₈ is a value smaller than n₁₁₅ by 1% to 10%.

As described above, providing the lenses 138 over the light-emitting devices can increase the luminance of the display device in one embodiment of the present invention.

FIG. 3A and FIG. 3B are modification examples of the cross-sectional view of the display device 100 shown in FIG. 1B. The size of the lens 138 in FIG. 3A and FIG. 3B is different from that in FIG. 1B.

Specifically, in FIG. 1B, the lenses 138 are provided such that an end portion of each lens 138 includes a region overlapping with part of the insulating layer 127. In FIG. 1B, the lenses 138 are provided such that the adjacent lenses 138 do not include a region where the end portions thereof overlap with each other.

By contrast, in FIG. 3A, the lenses 138 are each provided only over a substantially flat top surface portion of the common electrode 115 overlapping with the light-emitting device, and unlike in FIG. 1B, the lenses 138 do not include a region overlapping with the insulating layer 127. That is, the lens 138 illustrated in FIG. 3A can be regarded as having a smaller size than the lens 138 illustrated in FIG. 1B.

Meanwhile, in FIG. 3B, the lenses 138 are each provided to include not only a portion overlapping with the light-emitting device but also a region overlapping with part of the insulating layer 127. Unlike in FIG. 1B, the lenses 138 are provided such that the end portion of the lens 138 and the end portion of the adjacent lens 138 are in contact with each other. That is, the lens 138 illustrated in FIG. 3B can be regarded as having a larger size than the lens 138 illustrated in FIG. 1B.

Next, a structure of the insulating layer 127 and the vicinity thereof will be described with reference to FIG. 4A and FIG. 4B. FIG. 4A is an enlarged cross-sectional view of a region including the insulating layer 127 between the light-emitting device 130a and the light-emitting device 130b and the vicinity of the insulating layer 127. The description made below using the insulating layer 127 between the light-emitting device 130a and the light-emitting device 130b as an example applies to the insulating layer 127 between the light-emitting device 130b and the light-emitting device 130c and the insulating layer 127 between the light-emitting device 130c and the light-emitting device 130a. FIG. 4B is an enlarged view of an end portion of the insulating layer 127 over the first layer 113 included in the light-emitting device 130b and the vicinity thereof illustrated in FIG. 4A.

As illustrated in FIG. 4A, the first layer 113 is provided to cover the pixel electrode 111a and another first layer 113 is provided to cover the pixel electrode 111b. The mask layers 118a are provided in contact with parts of the top surfaces of the first layers 113, and the insulating layer 125 is provided in contact with the top surfaces and the side surfaces of two of the mask layers 118a, the side surfaces of two of the first layers 113, and the top surface of the insulating layer 255c. The insulating layer 125 covers parts of the top surfaces of the two first layers 113. The insulating layer 127 is provided in contact with the top surface of the insulating layer 125. The insulating layer 127 overlaps with the side surfaces and parts of the top surfaces of the two first layers 113 with the insulating layer 125 therebetween, and is in contact with at least part of the side surface of the insulating layer 125. The common layer 114 is provided to cover the first layers 113, the mask layers 118a, the insulating layer 125, and the insulating layer 127, and the common electrode 115 is provided over the common layer 114.

As illustrated in FIG. 4B, the end portion of the insulating layer 127 preferably has a tapered shape with a taper angle θ1 in the cross-sectional view of the display device. The taper angle θ1 is an angle formed by the side surface of the insulating layer 127 and the substrate surface. Note that the taper angle θ1 is not limited to the angle with the substrate surface, and may be an angle formed by the side surface of the insulating layer 127 and the top surface of the flat portion of the first layer 113 or the top surface of a flat portion of the pixel electrode 111b.

The taper angle θ1 of the insulating layer 127 is greater than 0° and less than 90°, preferably greater than or equal to 10°, preferably less than or equal to 60°, further preferably less than or equal to 45°, still further preferably less than or equal to 20°. When the end portion of the insulating layer 127 has such a tapered shape, the common layer 114 and the common electrode 115 that are provided over the insulating layer 127 can be formed with favorable coverage, thereby inhibiting disconnection, local thinning, or the like of the common layer 114 and the common electrode 115. Consequently, the in-plane uniformity of the thicknesses of the common layer 114 and the common electrode 115 can be increased, so that the display quality of the display device can be improved.

As illustrated in FIG. 4A, the top surface of the insulating layer 127 preferably has a convex curved shape in a cross-sectional view of the display device. The top surface of the insulating layer 127 preferably has a convex curved shape gently bulging toward the center. The insulating layer 127 preferably has a shape such that the convex curved portion at the center portion of the top surface is connected smoothly to the tapered portion of the end portion. When the insulating layer 127 has such a shape, the common layer 114 and the common electrode 115 can be formed with good coverage over the whole insulating layer 127.

As illustrated in FIG. 10C, the top surface of the insulating layer 127 may have a concave curved shape in a cross-sectional view of the display device. In FIG. 10C, the top surface of the insulating layer 127 has a shape bulging gently toward the center, i.e., includes a convex curved surface, and has a shape such that its center and the vicinity thereof are depressed, i.e., includes a concave curved surface. In FIG. 10C, the insulating layer 127 has a shape such that the convex curved portion of the top surface is connected smoothly to the tapered portion of the end portion. Even when the insulating layer 127 has such a shape, the common layer 114 and the common electrode 115 can be formed with good coverage over the whole insulating layer 127. When the insulating layer 127 has a concave curved surface in its center portion as illustrated in FIG. 10C, stress of the insulating layer 127 can be relieved. More specifically, when the insulating layer 127 has a concave curved surface in its center portion, local stress generated at the end portion of the insulating layer 127 can be relieved, so that one or more of peeling between the first layer 113 and the mask layer 118a, peeling between the mask layer 118a and the insulating layer 125, and peeling between the insulating layer 125 and the insulating layer 127 can be inhibited.

As illustrated in FIG. 4B, the end portion of the insulating layer 127 is preferably positioned outward from an end portion of the insulating layer 125. In that case, unevenness of the surface where the common layer 114 and the common electrode 115 are formed is reduced, and coverage with the common layer 114 and the common electrode 115 can be improved.

As illustrated in FIG. 4B, the end portion of the insulating layer 125 preferably has a tapered shape with a taper angle θ2 in the cross-sectional view of the display device. The taper angle θ2 is an angle formed by the side surface of the insulating layer 125 and the substrate surface. Note that the taper angle θ2 is not limited to the angle with the substrate surface, and may be an angle formed by the side surface of the insulating layer 125 and the top surface of the flat portion of the first layer 113 or the top surface of the flat portion of the pixel electrode 111b.

The taper angle θ2 of the insulating layer 125 is greater than 0° and less than 90°, preferably greater than or equal to 10°, preferably less than or equal to 60°, further preferably less than or equal to 45°, still further preferably less than or equal to 20°.

As illustrated in FIG. 4B, the end portion of the mask layer 118a preferably has a tapered shape with a taper angle θ3 in the cross-sectional view of the display device. The taper angle θ3 is an angle formed by the side surface of the mask layer 118a and the substrate surface. Note that the taper angle θ3 is not limited to the angle with the substrate surface, and may be an angle formed by the side surface of the mask layer 118a and the top surface of the flat portion of the first layer 113 or the top surface of the flat portion of the pixel electrode 111b.

The taper angle θ3 of the mask layer 118a is greater than 0° and less than 90°, preferably greater than or equal to 10°, preferably less than or equal to 60°, further preferably less than or equal to 45°, still further preferably less than or equal to 20°. When the mask layer 118a has such a tapered shape, the common layer 114 and the common electrode 115 that are provided over the mask layer 118a can be formed with favorable coverage.

The end portion of the mask layer 118a is preferably positioned outward from the end portion of the insulating layer 125. In that case, unevenness of the surface where the common layer 114 and the common electrode 115 are formed is reduced, and coverage with the common layer 114 and the common electrode 115 can be improved.

Although the details will be described in Manufacturing method example of a display device in Embodiment 2, when the insulating layer 125 and the mask layer 118a are collectively etched, the insulating layer 125 and the mask layer 118a under the end portion of the insulating layer 127 are eliminated by side etching and accordingly a cavity is formed in some cases. The cavity causes unevenness in the formation surface of the common layer 114 and the common electrode 115, so that disconnection is likely to occur in the common layer 114 and the common electrode 115. Thus, the etching treatment is performed in two separate steps and heat treatment is performed therebetween, whereby even when a cavity is formed by the first etching treatment, the cavity can be filled with the insulating layer 127 deformed by the heat treatment. In addition, since the second etching treatment etches a thin film, the amount of side etching is small and thus a cavity is not easily formed or formed to be extremely small. Thus, generation of unevenness in the formation surface of the common layer 114 and the common electrode 115 can be inhibited and accordingly disconnection of the common layer 114 and the common electrode 115 can be inhibited. Since the etching treatment is performed twice in this manner, the taper angle θ2 and the taper angle θ3 are different from each other in some cases. Furthermore, the taper angle θ2 and the taper angle θ3 may each be smaller than the taper angle θ1.

The insulating layer 127 covers at least part of the side surface of the mask layer 118a in some cases. For example, FIG. 4B illustrates an example where the insulating layer 127 covers and touches an inclined surface positioned at the end portion of the mask layer 118a which is formed by the first etching treatment, and an inclined surface positioned at the end portion of the mask layer 118a which is formed by the second etching treatment is exposed. These two inclined surfaces can sometimes be distinguished from each other because of having different taper angles. There might be almost no difference between the taper angles formed at the side surfaces by the two etching steps; in that case, the inclined surfaces cannot be distinguished from each other.

FIG. 5A and FIG. 5B illustrate an example where the insulating layer 127 covers the entire side surface of the mask layer 118a. Specifically, in FIG. 5B, the insulating layer 127 covers and touches both of the two inclined surfaces. This structure is preferably employed, in which case the formation surface of the common layer 114 and the common electrode 115 can have reduced unevenness as compared with the formation surface in FIG. 4B. FIG. 5B illustrates an example where the end portion of the insulating layer 127 is positioned outward from the end portion of the mask layer 118a. As illustrated in FIG. 4B, the end portion of the insulating layer 127 may be positioned inward from the end portion of the mask layer 118a, or may be aligned or substantially aligned with the end portion of the mask layer 118a. As illustrated in FIG. 5B, the insulating layer 127 is in contact with the first layer 113 in some cases.

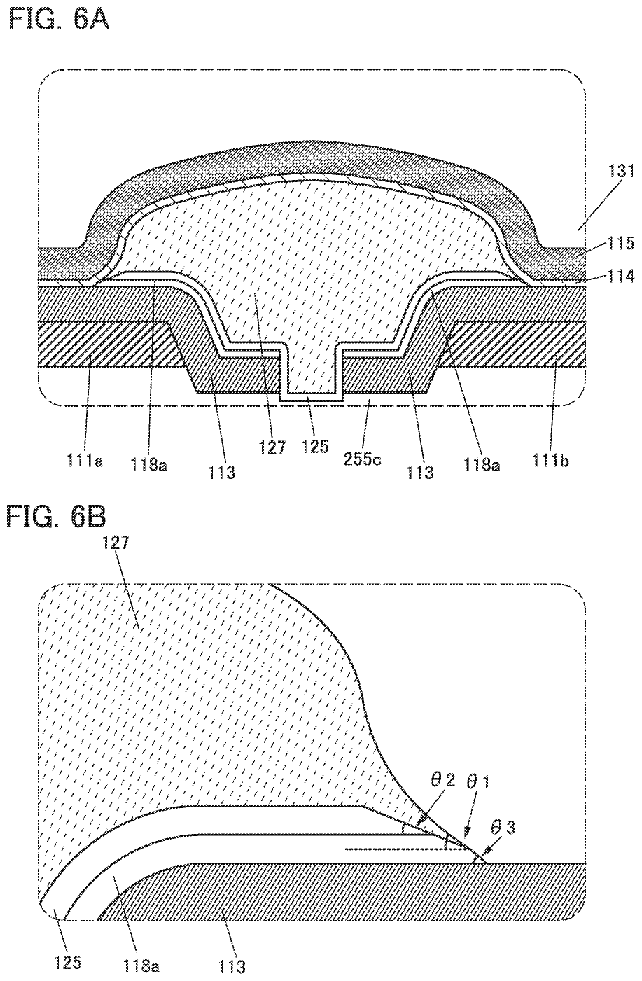

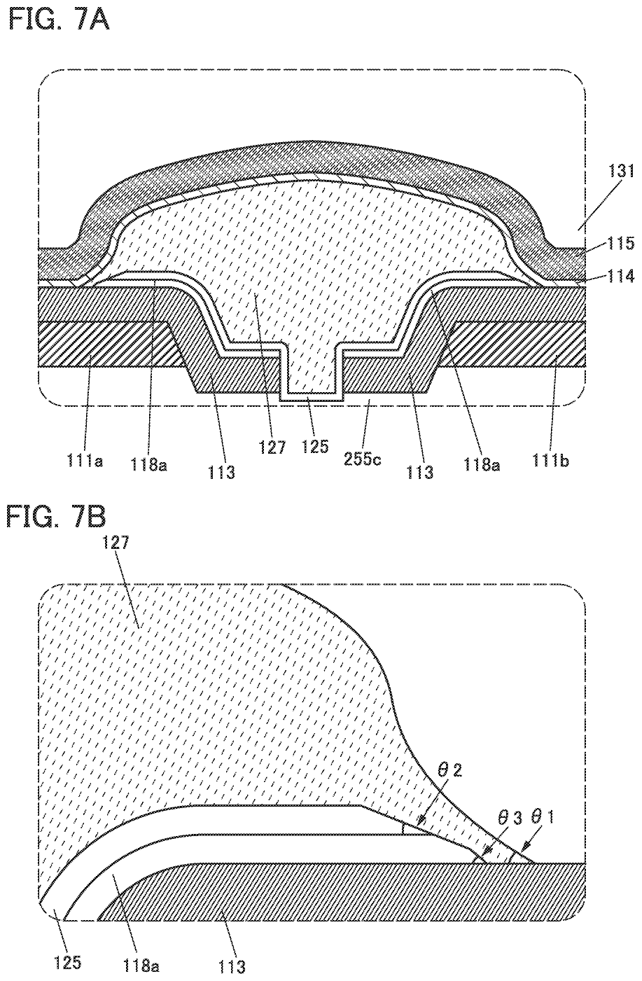

FIG. 6A, FIG. 6B, FIG. 7A, and FIG. 7B illustrate examples where the side surface of the insulating layer 127 has a concave curved shape (also referred to as a narrowed portion, a depressed portion, a dent, a hollow, or the like). Depending on the materials and the formation conditions (e.g., heating temperature, heating time, and heating atmosphere) of the insulating layer 127, a concave curved shape is formed in the side surface of the insulating layer 127 in some cases.

FIG. 6A and FIG. 6B illustrate an example where the insulating layer 127 covers part of the side surface of the mask layer 118a and the other part of the side surface of the mask layer 118a is exposed. FIG. 7A and FIG. 7B illustrate an example where the insulating layer 127 covers and touches the entire side surface of the mask layer 118a.

The taper angle θ1 to the taper angle θ3 in FIG. 5 to FIG. 7 are also preferably within the above range.

As illustrated in FIG. 4 to FIG. 7, it is preferable that one end portion of the insulating layer 127 overlap with the top surface of the pixel electrode 111a and the other end portion of the insulating layer 127 overlap with the top surface of the pixel electrode 111b. With such a structure, the end portions of the insulating layer 127 can be formed over the substantially flat regions of the first layers 113. This makes it relatively easy to form a tapered shape in each of the insulating layer 127, the insulating layer 125, and the mask layers 118a. In addition, peeling of the pixel electrode 111a, the pixel electrode 111b, and the first layers 113 can be inhibited. Meanwhile, a portion where the top surface of the pixel electrode and the insulating layer 127 overlap with each other is preferably smaller to make the light-emitting region of the light-emitting device wider and the aperture ratio higher.

Note that the insulating layer 127 does not necessarily overlap with the top surface of the pixel electrode. As illustrated in FIG. 8A, the insulating layer 127 does not necessarily overlap with the top surface of the pixel electrode, and one end portion of the insulating layer 127 may overlap with the side surface of the pixel electrode 111a and the other end portion of the insulating layer 127 may overlap with the side surface of the pixel electrode 111b. As illustrated in FIG. 8B, the insulating layer 127 does not necessarily overlap with the pixel electrode, and may be provided in a region interposed between the pixel electrode 111a and the pixel electrode 111b. In FIG. 8A and FIG. 8B, part or the whole of the top surface of the first layer 113 in the inclined portion and the flat portion (the region 103) positioned outward from the top surface of the pixel electrode is covered with the mask layer 118a, the insulating layer 125, and the insulating layer 127. Even such a structure can reduce unevenness of the formation surface of the common layer 114 and the common electrode 115 and improve the coverage with the common layer 114 and the common electrode 115, as compared with the structure where the mask layer 118a, the insulating layer 125, and the insulating layer 127 are not provided.

As described above, in the structures illustrated in FIG. 4 to FIG. 8, the insulating layer 127, the insulating layer 125, and the mask layer 118a are provided and thus, the common layer 114 and the common electrode 115 can be formed with favorable coverage from the substantially flat region of the first layer 113 to the substantially flat region of the adjacent first layer 113. It is thus possible to prevent formation of a disconnected portion and a locally thinned portion in the common layer 114 and the common electrode 115. Thus, a connection defect between the light-emitting devices due to a disconnected portion and an increase in electric resistance due to a locally thinned portion can be inhibited from being caused in the common layer 114 and the common electrode 115 between the light-emitting devices. Thus, the display device of one embodiment of the present invention can have improved display quality.

The lens 138 is provided over each of the light-emitting devices (the light-emitting device 130a, the light-emitting device 130b, and the light-emitting device 130c) so as to include a region overlapping with at least the light-emitting device. With such a structure, light emitted from the light-emitting devices can be extracted toward the coloring layers (the coloring layer 132R, the coloring layer 132G, and the coloring layer 132B) more efficiently than when the lenses 138 are not provided, as described with reference to FIG. 2. Furthermore, the lenses 138 can increase the amount of light emitted toward the coloring layers and thus, the amount of current injected to the EL layers to make the light-emitting devices emit light can be reduced as compared with the case where the lenses 138 are not provided, inhibiting deterioration of the EL layers. Thus, the display device of one embodiment of the present invention can have higher reliability as well as higher luminance.

The protective layer 131 is preferably provided over the light-emitting device 130a, the light-emitting device 130b, the light-emitting device 130c, and the lenses 138. Providing the protective layer 131 can improve the reliability of the light-emitting devices. Furthermore, damage to the lenses 138 can be prevented. The protective layer 131 may have a single-layer structure or a stacked-layer structure of two or more layers.

There is no limitation on the conductivity of the protective layer 131. As the protective layer 131, at least one of an insulating film, a semiconductor film, and a conductive film can be used.

The protective layer 131 including an inorganic film can inhibit deterioration of the light-emitting devices by preventing oxidation of the common electrode 115 and inhibiting entry of impurities (e.g., moisture and oxygen) into the light-emitting devices, for example; thus, the reliability of the display device can be improved.

As the protective layer 131, an inorganic insulating film such as an oxide insulating film, a nitride insulating film, an oxynitride insulating film, or a nitride oxide insulating film can be used, for example. Specific examples of these inorganic insulating films are as listed in the description of the insulating layer 125. In particular, the protective layer 131 preferably includes a nitride insulating film or a nitride oxide insulating film, and further preferably includes a nitride insulating film.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting devices is extracted through the lenses 138 and the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can employ, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (such as water and oxygen) to the EL layer side.

Furthermore, the protective layer 131 may include an organic film. For example, the protective layer 131 may include both an organic film and an inorganic film. Examples of an organic material that can be used for the protective layer 131 include organic insulating materials that can be used for the insulating layer 127.

In the case where the protective layer 131 is formed using the same material as the insulating layer 127, a different material is preferably used for the lenses 138. Specifically, the lenses 138 are preferably formed using a material having a higher refractive index than the protective layer 131 and the insulating layer 127. In that case, the lenses 138 covered with the protective layer 131 function as plano-convex lenses, and light emitted from the light-emitting devices can be efficiently extracted toward the coloring layers.

The protective layer 131 may have a stacked-layer structure of two layers which are formed by different film formation methods. Specifically, the first layer of the protective layer 131 may be formed by an ALD method, and the second layer of the protective layer 131 may be formed by a sputtering method.

A variety of optical members can be provided on the outer surface of the substrate 120. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 120. For example, a glass layer or a silica layer (SiO, layer) is preferably provided as the surface protective layer to inhibit the surface contamination and generation of a scratch. The surface protective layer may be formed using DLC (diamond like carbon), aluminum oxide (AlOₓ), a polyester-based material, a polycarbonate-based material, or the like. For the surface protective layer, a material having high visible-light transmittance is preferably used. The surface protective layer is preferably formed using a material with high hardness.

For the substrate 120, glass, quartz, ceramic, sapphire, a resin, a metal, an alloy, a semiconductor, or the like can be used. The substrate on the side from which light from the light-emitting device is extracted is formed using a material that transmits the light. When a flexible material is used for the substrate 120, the display device can have increased flexibility. Furthermore, a polarizing plate may be used as the substrate 120.

For the substrate 120, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as the substrate 120.

In the case where a circularly polarizing plate overlaps with the display device, a highly optically isotropic substrate is preferably used as the substrate included in the display device. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of the film having high optical isotropy include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of the display device might be changed, e.g., creases are generated. Thus, for the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

For the resin layer 122, any of a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. Alternatively, a two-liquid-mixture-type resin may be used. An adhesive sheet or the like may be used.

In the example illustrated in FIG. 1B, the coloring layer 132R, the coloring layer 132G, and the coloring layer 132B are directly provided over the light-emitting device 130a, the light-emitting device 130b, and the light-emitting device 130c with the lenses 138 and the protective layer 131 therebetween. With such a structure, the alignment accuracy of the light-emitting devices and the coloring layers can be improved. Such a structure is preferably employed, in which case the distance between the light-emitting devices and the coloring layers can be reduced and thus, color mixing can be inhibited and the viewing angle characteristics can be improved.

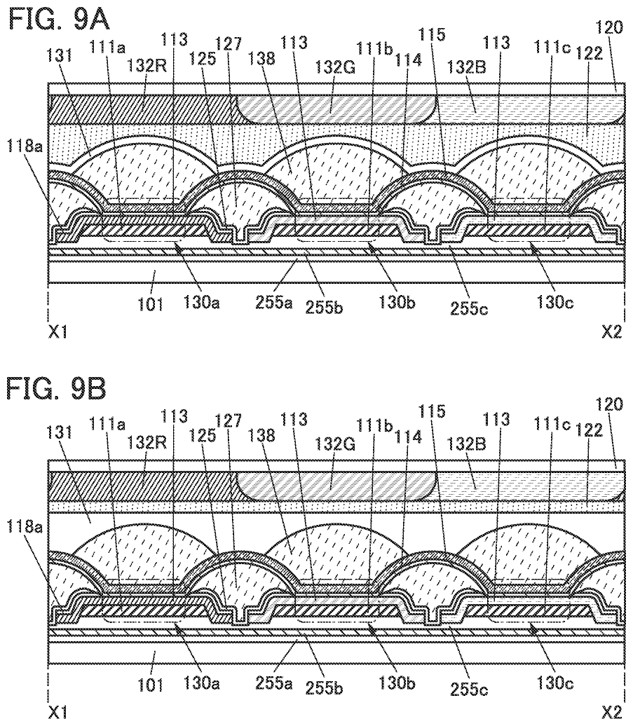

FIG. 9A and FIG. 9B are cross-sectional views along the dashed-dotted line X1-X2 in FIG. 1A.

As illustrated in FIG. 9A, the protective layer 131 may be provided to cover the top surfaces of the lenses 138 and part of the top surface of the common electrode 115, and the protective layer 131 and the substrate 120 provided with the coloring layers may be attached to each other with the resin layer 122.

As illustrated in FIG. 9B, the substrate 120 provided with the coloring layers may be attached to the protective layer 131 with the resin layer 122.

When the coloring layers are provided on the substrate 120 as illustrated in FIG. 9A and FIG. 9B, the heat treatment temperature in the process of forming the coloring layers can be increased.

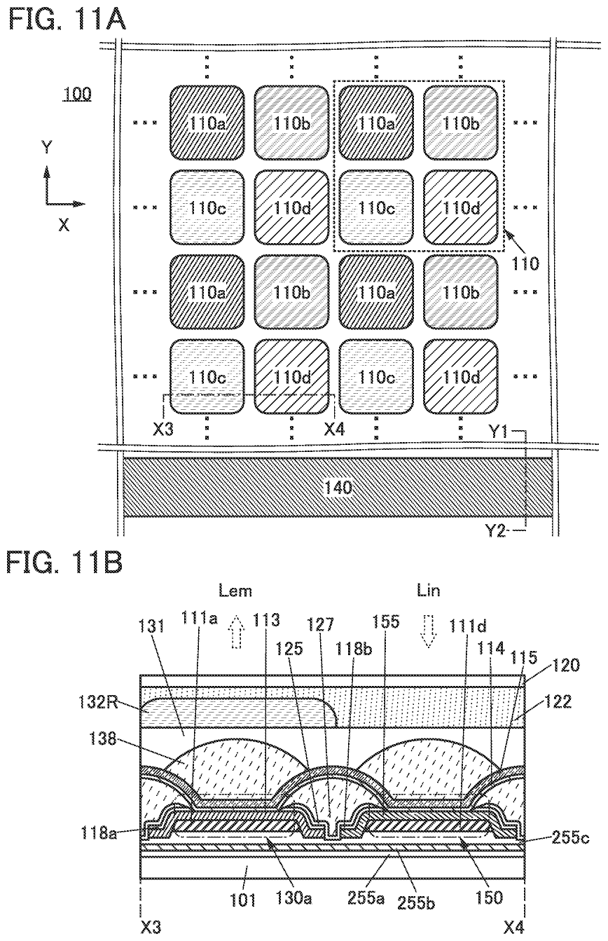

FIG. 11A is a top view of the display device 100 different from that in FIG. 1A. The pixels 110 in FIG. 11A employing matrix arrangement are each composed of four subpixels: the subpixel 110a, the subpixel 110b, the subpixel 110c, and a subpixel 110d.

The subpixel 110a, the subpixel 110b, the subpixel 110c, and the subpixel 110d can include light-emitting devices that emit light of different colors. As examples of the subpixel 110a, the subpixel 110b, the subpixel 110c, and the subpixel 110d, subpixels of four colors of R, G, B, and W, four subpixels of four colors of R, G, B, and Y, and the like can be given.

The display device of one embodiment of the present invention may include a light-receiving device in the pixel.

Three of the four subpixels included in the pixel 110 illustrated in FIG. 11A may each include a light-emitting device and the other one may include a light-receiving device.

For example, a pn or pin photodiode can be used as the light-receiving device. The light-receiving device functions as a photoelectric conversion device (also referred to as a photoelectric conversion element) that detects light entering the light-receiving device and generates electric charge. The amount of electric charge generated from the light-receiving device depends on the amount of light entering the light-receiving device.

The light-receiving device can detect one or both of visible light and infrared light. In the case where visible light is detected, one or more of blue light, violet light, bluish violet light, green light, yellowish green light, yellow light, orange light, red light, and the like can be detected, for example. Infrared light is preferably detected, in which case an object can be detected even in a dark place.

It is particularly preferable to use an organic photodiode that includes a layer containing an organic compound, as the light-receiving device. An organic photodiode, which is easily made thin, lightweight, and large in area and has a high degree of freedom for shape and design, can be used in a variety of display devices.

In one embodiment of the present invention, an organic EL device is used as the light-emitting device, and an organic photodiode is used as the light-receiving device. The organic EL device and the organic photodiode can be formed over the same substrate. Thus, the organic photodiode can be incorporated in the display device that includes the organic EL device.

When the light-receiving device is driven by application of reverse bias between the pixel electrode and the common electrode, light entering the light-receiving device can be detected and electric charge can be generated and extracted as current.

A manufacturing method similar to that of the light-emitting device can be employed for the light-receiving device. An island-shaped active layer (also referred to as a photoelectric conversion layer) included in the light-receiving device is formed by processing a film that is to be the active layer and formed over the entire surface, not by using a fine metal mask; thus, the island-shaped active layer can be formed to have a uniform thickness. In addition, a mask layer provided over the active layer can reduce damage to the active layer in the fabrication process of the display device, increasing the reliability of the light-receiving device.

Embodiment 6 can be referred to for the structure and materials of the light-receiving device.

FIG. 11B is a cross-sectional view along the dashed-dotted line X3-X4 in FIG. 11A. FIG. 10A or FIG. 10B can be referred to for a cross-sectional view along the dashed-dotted line Y1-Y2 in FIG. 11A.

As illustrated in FIG. 11B, in the display device 100, the insulating layers (the insulating layer 255a, the insulating layer 255b, and the insulating layer 255c) are provided over the layer 101 including transistors. The light-emitting device 130a and a light-receiving device 150 are provided over the insulating layers. The lens 138 is provided over the light-emitting device 130a to include a region overlapping with at least the light-emitting device 130a, and the lens 138 is provided over the light-receiving device 150 to include a region overlapping with at least the light-receiving device 150. The protective layer 131 is provided to cover the lenses 138, and the coloring layer 132R overlapping with the light-emitting device 130a is provided over the protective layer 131. The coloring layer is attached to the substrate 120 with the resin layer 122. In a region between the light-emitting device and the light-receiving device that are adjacent to each other, the insulating layer 125 and the insulating layer 127 over the insulating layer 125 are provided.

In FIG. 11B, the light-emitting device adjacent to the light-receiving device 150 is the light-emitting device 130a, but not limited thereto. In the display device of one embodiment of the present invention, the light-emitting device adjacent to the light-receiving device 150 may be the light-emitting device 130b or the light-emitting device 130c.

In the example illustrated in FIG. 11B, the light-emitting device 130a emits light to the substrate 120 side and light enters the light-receiving device 150 from the substrate 120 side (see light Lem and light Lin).

In FIG. 11B, the lens 138 is provided over the light-receiving device 150 to include a region overlapping with at least the light-receiving device. When the display device 100 has such a structure, the light Lin condensed through the lens 138 enters the light-receiving device 150. Thus, the light Lin can enter the light-receiving device 150 more efficiently than in the case where the lens 138 is not provided. That is, the light detection performance of the display device of one embodiment of the present invention can be increased as compared with the case where the lens 138 is not provided over the light-receiving device 150.

In the display device of one embodiment of the present invention, the lens 138 is provided over each of the light-emitting device and the light-receiving device. Thus, in the display device of one embodiment of the present invention, owing to the effect of the lenses 138, the light Lem can be emitted to the outside more efficiently and the light Lin can enter the light-receiving device 150 more efficiently than in the case where the lenses are not provided. That is, the display device of one embodiment of the present invention can include both a light-emitting device having high luminance and a light-receiving device having high light detection performance.

The structure of the light-emitting device 130a is as described above.

The light-receiving device 150 includes a pixel electrode 111d over the insulating layer 255c, a second layer 155 over the pixel electrode 111d, the common layer 114 over the second layer 155, and the common electrode 115 over the common layer 114. The second layer 155 includes at least an active layer.

The second layer 155 is provided in the light-receiving device 150, and not provided in the light-emitting devices. Meanwhile, the common layer 114 is a continuous layer shared by the light-emitting devices and the light-receiving device.

Here, a layer common to the light-receiving device and the light-emitting device may have different functions in the light-emitting device and the light-receiving device. In this specification, the name of a component is based on its function in the light-emitting device in some cases. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. A layer common to the light-receiving device and the light-emitting device may have the same function in both the light-emitting device and the light-receiving device. For example, the hole-transport layer functions as a hole-transport layer in both the light-emitting device and the light-receiving device, and the electron-transport layer functions as an electron-transport layer in both the light-emitting device and the light-receiving device.

The mask layer 118a is positioned between the first layer 113 and the insulating layer 125, and a mask layer 118b is positioned between the second layer 155 and the insulating layer 125. The mask layer 118a is a remaining portion of the mask layer provided over the first layer 113 when the first layer 113 is processed. The mask layer 118b is a remaining portion of a mask layer provided in contact with the top surface of the second layer 155 at the time of processing the second layer 155, which includes the active layer. The mask layer 118a and the mask layer 118b may contain the same material or different materials.

Although FIG. 11A illustrates an example where the subpixel 110a, the subpixel 110b, the subpixel 110c, and the subpixel 110d have substantially the same aperture ratio (also referred to as size or size of a light-emitting region or a light-receiving region), one embodiment of the present invention is not limited thereto. The aperture ratio of each of the subpixel 110a, the subpixel 110b, the subpixel 110c, and the subpixel 110d can be determined as appropriate. The subpixel 110a, the subpixel 110b, the subpixel 110c, and the subpixel 110d may have different aperture ratios, or two or more of the subpixel 110a, the subpixel 110b, the subpixel 110c, and the subpixel 110d may have the same or substantially the same aperture ratio.

The subpixel 110d may have a higher aperture ratio than at least one of the subpixel 110a, the subpixel 110b, and the subpixel 110c. In the case where the subpixel 110d includes a light-receiving device, for example, a large light-receiving area of the subpixel 110d can make it easy to detect an object in some cases. For example, in some cases, the aperture ratio of the subpixel 110d is higher than that of the other subpixels depending on the resolution of the display device and the circuit structure or the like of the subpixel.

The subpixel 110d may have a lower aperture ratio than at least one of the subpixel 110a, the subpixel 110b, and the subpixel 110c. In the case where the subpixel 110d includes a light-receiving device, for example, a smaller light-receiving area of the subpixel 110d leads to a narrower image-capturing range, inhibits a blur in a captured image, and improves the definition. Accordingly, high-resolution or high-definition image capturing can be performed, which is preferable.

As described above, the subpixel 110d can have a detection wavelength, a resolution, and an aperture ratio that are suitable for the intended use.

In the display device of one embodiment of the present invention, each light-emitting device includes an island-shaped EL layer, which can inhibit generation of leakage current between the subpixels. This can prevent crosstalk due to unintended light emission, so that a display device with extremely high contrast can be obtained. The insulating layer having a tapered end portion and being provided between adjacent island-shaped EL layers can inhibit occurrence of disconnection and prevent formation of a locally thinned portion in the common electrode at the time of forming the common electrode. Thus, a connection defect between the light-emitting devices due to a disconnected portion and an increase in electric resistance due to a locally thinned portion can be inhibited from being caused in the common layer and the common electrode. Consequently, the display device of one embodiment of the present invention achieves both high resolution and high display quality.

In the display device of one embodiment of the present invention, the lens 138 is provided over each light-emitting device so as to include a region overlapping with at least the light-emitting device, whereby light emitted from the light-emitting devices can be extracted toward the coloring layers more efficiently than in the case where the lenses 138 are not provided. Furthermore, the lenses 138 can increase the amount of light emitted toward the coloring layers and thus, the amount of current injected to the EL layers to make the light-emitting devices emit light can be reduced as compared with the case where the lenses 138 are not provided, inhibiting deterioration of the EL layers. Consequently, the display device of one embodiment of the present invention achieves both high luminance and high reliability.

In the display device of one embodiment of the present invention, the lens 138 is also provided over the light-receiving device. Thus, in the display device of one embodiment of the present invention, external light can enter the light-receiving device more efficiently than in the case where the lens 138 is not provided. Accordingly, the light-receiving device included in the display device of one embodiment of the present invention can have high light detection performance.

This embodiment can be combined with any of the other embodiments as appropriate. In this specification, in the case where a plurality of structure examples are described in one embodiment, the structure examples can be combined as appropriate.

### Embodiment 2

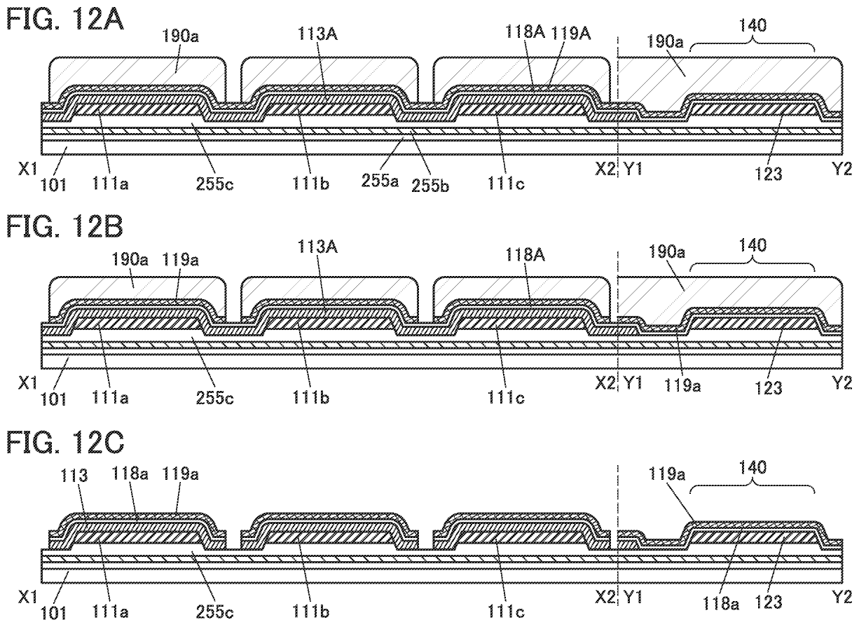

In this embodiment, a method for manufacturing a display device of one embodiment of the present invention is described with reference to FIG. 12 to FIG. 19. Note that as for a material and a formation method of each component, portions similar to those described in Embodiment 1 above are not described in some cases. Details of the structure of the light-emitting device will be described in Embodiment 5.

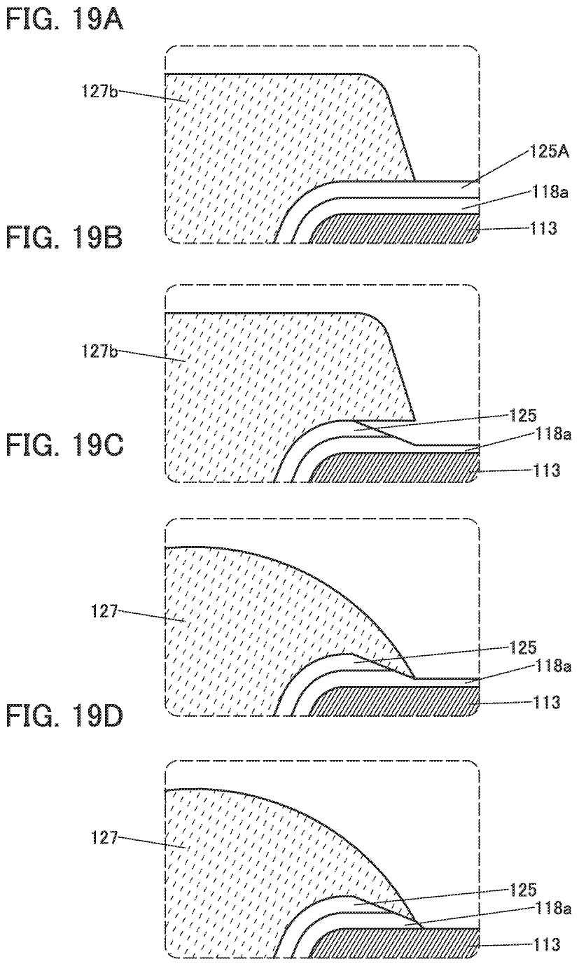

FIG. 12 to FIG. 18 each illustrate a cross-sectional view along the dashed-dotted line X1-X2 and a cross-sectional view along the dashed-dotted line Y1-Y2 in FIG. 1A side by side. FIG. 19 shows enlarged views of an end portion of the insulating layer 127 and the vicinity thereof.

Thin films included in the display device (an insulating film, a semiconductor film, a conductive film, and the like) can be formed by a sputtering method, a chemical vapor deposition (CVD) method, a vacuum evaporation method, a pulsed laser deposition (PLD) method, an ALD method, or the like. Examples of the CVD method include a plasma-enhanced chemical vapor deposition (PECVD: Plasma Enhanced CVD) method and a thermal CVD method. As an example of the thermal CVD method, a metal organic chemical vapor deposition (MOCVD) method can be given.

Alternatively, thin films (an insulating film, a semiconductor film, a conductive film, and the like) included in the display device can be formed by a wet film-formation method such as spin coating, dipping, spray coating, ink-jetting, dispensing, screen printing, offset printing, a doctor knife method, slit coating, roll coating, curtain coating, or knife coating.

Specifically, for fabrication of the light-emitting device, a vacuum process such as an evaporation method and a solution process such as a spin coating method or an ink-jet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by an evaporation method (e.g., a vacuum evaporation method), a coating method (e.g., a dip coating method, a die coating method, a bar coating method, a spin coating method, or a spray coating method), a printing method (e.g., an ink-jet method, a screen printing (stencil) method, an offset printing (planography) method, a flexography (relief printing) method, a gravure printing method, or a micro-contact printing method), or the like.

The thin films included in the display device can be processed by a photolithography method or the like. Alternatively, thin films may be processed by a nanoimprinting method, a sandblasting method, a lift-off method, or the like. Alternatively, island-shaped thin films may be directly formed by a film formation method using a shielding mask such as a metal mask.

There are the following two typical examples of a photolithography method. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As the light used for light exposure in the photolithography method, for example, the i-line (wavelength: 365 nm), the g-line (wavelength: 436 nm), the h-line (wavelength: 405 nm), or combined light of any of them can be used. Alternatively, ultraviolet rays, KrF laser light, ArF laser light, or the like can be used. In addition, light exposure may be performed by liquid immersion exposure technique. As the light for light exposure, extreme ultraviolet (EUV) light or X-rays may be used. Instead of the light used for the light exposure, an electron beam can be used. Extreme ultraviolet light, X-rays, or an electron beam is preferably used to enable extremely minute processing. Note that in the case of performing light exposure by scanning of a beam such as an electron beam, a photomask is not needed.

For etching of thin films, a dry etching method, a wet etching method, a sandblast method, or the like can be used.

### Manufacturing Method Example

In Manufacturing method example, a method for manufacturing the display device 100 illustrated in FIG. 1A, FIG. 1B, and FIG. 10A will be described. First, the insulating layer 255a, the insulating layer 255b, and the insulating layer 255c are formed in this order over the layer 101 including transistors. Next, the pixel electrode 111a, the pixel electrode 111b, the pixel electrode 111c, and the conductive layer 123 are formed over the insulating layer 255c (FIG. 12A). The pixel electrodes and the conductive layer 123 can be formed by a sputtering method or a vacuum evaporation method, for example.

Then, the pixel electrode is preferably subjected to hydrophobization treatment. The hydrophobization treatment for the pixel electrode can improve adhesion between the pixel electrode and a film to be formed in a later step (here, a film 113A), thereby inhibiting peeling of the film. Note that the hydrophobization treatment is not necessarily performed.

The hydrophobization treatment can be performed by fluorine modification of the pixel electrode, for example. The fluorine modification can be performed by, for example, treatment or heat treatment using a fluorine-containing gas, plasma treatment in an atmosphere of a fluorine-containing gas, or the like. A fluorine gas can be used as the fluorine-containing gas, and for example, a fluorocarbon gas can be used. As the fluorocarbon gas, a low carbon fluoride gas such as a carbon tetrafluoride (CF₄) gas, a C₄F₆ gas, a C₂F₆ gas, a C₄F₈ gas, or a C₅F₈ gas can be used, for example. Moreover, as the fluorine-containing gas, an SF₆ gas, an NF₃ gas, a CHF₃ gas, or the like can be used, for example. Alternatively, a helium gas, an argon gas, a hydrogen gas, or the like can be added to any of the above gases as appropriate.

A surface of the pixel electrode can be made hydrophobic by being subjected to plasma treatment in a gas atmosphere containing a Group 18 element such as argon and subsequent treatment using a silylating agent. As the silylating agent, hexamethyldisilazane (HMDS), trimethylsilylimidazole (TMSI), or the like can be used. Alternatively, the surface of the pixel electrode can be made hydrophobic by being subjected to plasma treatment in a gas atmosphere containing a Group 18 element such as argon and subsequent treatment using a silane coupling agent.

Performing plasma treatment on the surface of the pixel electrode in a gas atmosphere containing a Group 18 element such as argon can apply damage to the surface of the pixel electrode. Accordingly, a methyl group included in the silylating agent such as HMDS is likely to bond to the surface of the pixel electrode. Moreover, silane coupling due to the silane coupling agent is likely to occur. As described above, the surface of the pixel electrode can be made hydrophobic by being subjected to the plasma treatment in the gas atmosphere containing a Group 18 element such as argon and the subsequent treatment using the silylating agent or the silane coupling agent.

The treatment using the silylating agent, the silane coupling agent, or the like can be performed by application of the silylating agent, the silane coupling agent, or the like by a spin coating method or a dipping method, for example. The treatment using the silylating agent, the silane coupling agent, or the like can also be performed by forming a film containing the silylating agent, a film containing the silane coupling agent, or the like over the pixel electrode and the like by a gas phase method, for example. In a gas phase method, first, a material containing the silylating agent, a material containing the silane coupling agent, or the like is volatilized, so that the silylating agent, the silane coupling agent, or the like is included in the atmosphere. Next, a substrate where the pixel electrode and the like are formed is put in the atmosphere. Accordingly, a film containing the silylating agent, the silane coupling agent, or the like can be formed over the pixel electrode, so that the surface of the pixel electrode can become hydrophobic.

Then, the film 113A to be the first layers 113 later is formed over the pixel electrodes (FIG. 12A).

As illustrated in FIG. 12A, the film 113A is not formed over the conductive layer 123 in the cross-sectional view along the dashed-dotted line Y1-Y2. For example, by using a mask for defining a film formation area (also referred to as an area mask, a rough metal mask, or the like to be distinguished from a fine metal mask), the film 113A can be formed only in a desired region. The light-emitting device can be fabricated through a relatively simple process, by employing a film formation step using an area mask and a processing step using a resist mask.

The film 113A can be formed by an evaporation method, specifically a vacuum evaporation method, for example. The film 113A may be formed by a transfer method, a printing method, an ink-jet method, a coating method, or the like.

Next, a mask film 118A to be the mask layers 118a later and a mask film 119A to be mask layers 119a later are formed in this order over the film 113A and the conductive layer 123 (FIG. 12A).

Although this embodiment describes an example where the mask film is formed to have a two-layer structure of the mask film 118A and the mask film 119A, the mask film may have a single-layer structure or a stacked-layer structure of three or more layers.

Providing a mask layer over the film 113A can reduce damage to the film 113A in the fabrication process of the display device and increase the reliability of the light-emitting devices.

As the mask film 118A, a film highly resistant to the processing conditions of the film 113A, i.e., a film having high etching selectivity to the film 113A, is used. As the mask film 119A, a film having high etching selectivity to the mask film 118A is used.

The mask film 118A and the mask film 119A are formed at a temperature lower than the upper temperature limit of the film 113A. The typical substrate temperatures in formation of the mask film 118A and the mask film 119A are each lower than or equal to 200° C., preferably lower than or equal to 150° C., further preferably lower than or equal to 120° C., still further preferably lower than or equal to 100° C., yet still further preferably lower than or equal to 80° C.

Examples of indicators of the upper temperature limit are the glass transition point, the softening point, the melting point, the thermal decomposition temperature, and the 5% weight loss temperature. The upper temperature limit of the film 113A (i.e., the film to be the first layers 113 later) can be any of the above temperatures, preferably the lowest one among the temperatures.

As the mask film 118A and the mask film 119A, films that can be removed by a wet etching method are preferably used. Using a wet etching method can reduce damage to the film 113A in processing of the mask film 118A and the mask film 119A, compared to the case of using a dry etching method.

The mask film 118A and the mask film 119A can be formed by a sputtering method, an ALD method (a thermal ALD method or a PEALD method), a CVD method, or a vacuum evaporation method, for example. Alternatively, the mask film 118A and the mask film 119A may be formed by the above-described wet film-formation method.

The mask film 118A, which is formed over and in contact with the film 113A, is preferably formed by a formation method that causes less damage to the film 113A than a formation method of the mask film 119A. For example, the mask film 118A is preferably formed by an ALD method or a vacuum evaporation method rather than a sputtering method.

As each of the mask film 118A and the mask film 119A, one or more of a metal film, an alloy film, a metal oxide film, a semiconductor film, an organic insulating film, and an inorganic insulating film can be used, for example.

For the mask film 118A and the mask film 119A, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. A metal material capable of blocking ultraviolet light is preferably used for one or both of the mask film 118A and the mask film 119A, in which case the film 113A can be inhibited from being irradiated with ultraviolet light and deteriorating.

The mask film 118A and the mask film 119A can each be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In addition, in place of gallium described above, an element M (M is one or more selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used. Specifically, M is preferably one or more selected from gallium, aluminum, and yttrium.

As the mask film, a film containing a material having a light-blocking property, particularly with respect to ultraviolet light, can be used. For example, a film having a reflecting property with respect to ultraviolet light or a film absorbing ultraviolet light can be used. Although any of a variety of materials such as a metal, an insulator, a semiconductor, and a metalloid that have a light-blocking property with respect to ultraviolet light can be used as the material having a light-blocking property, the mask film is preferably a film capable of being processed by etching and is particularly preferably a film having good processability because part or the whole of the mask film is removed in a later step.

For example, a semiconductor material such as silicon or germanium can be used as a material with excellent compatibility with the semiconductor manufacturing process. Alternatively, an oxide or a nitride of the semiconductor material can be used. Alternatively, a non-metallic (metalloid) material, such as carbon, or a compound thereof can be used. Alternatively, a metal such as titanium, tantalum, tungsten, chromium, or aluminum, or an alloy containing one or more of these metals can be used. Alternatively, an oxide containing the above-described metal, such as titanium oxide or chromium oxide, or a nitride such as titanium nitride, chromium nitride, or tantalum nitride can be used.

When a film containing a material having a light-blocking property with respect to ultraviolet light is used as the mask film, the EL layer can be inhibited from being irradiated with ultraviolet light in a light exposure step, for example. When the EL layer is inhibited from being damaged by ultraviolet light, the reliability of the light-emitting device can be improved.

Note that the same effect is obtained when a film containing a material having a light-blocking property with respect to ultraviolet light is used for an insulating film 125A to be described later.

As the mask film 118A and the mask film 119A, any of a variety of inorganic insulating films that can be used as the protective layer 131 can be used. In particular, an oxide insulating film is preferable because it has higher adhesion to the film 113A than a nitride insulating film. For example, an inorganic insulating material such as aluminum oxide, hafnium oxide, or silicon oxide can be used for the mask film 118A and the mask film 119A. As the mask film 118A and the mask film 119A, an aluminum oxide film formed by an ALD method can be used, for example. An ALD method is preferably used, in which case damage to a base (in particular, the EL layer) can be reduced.

For example, an inorganic insulating film (e.g., an aluminum oxide film) formed by an ALD method can be used as the mask film 118A, and an inorganic film (e.g., an In—Ga—Zn oxide film, an aluminum film, or a tungsten film) formed by a sputtering method can be used as the mask film 119A.

Note that the same inorganic insulating film can be used for both the mask film 118A and the insulating layer 125 that is to be formed later. For example, an aluminum oxide film formed by an ALD method can be used for both the mask film 118A and the insulating layer 125. Here, for the mask film 118A and the insulating layer 125, the same film-formation condition may be used or different film-formation conditions may be used. For example, when the mask film 118A is formed under conditions similar to those for the insulating layer 125, the mask film 118A can be an insulating film having a high barrier property against at least one of water and oxygen. Meanwhile, since the mask film 118A is a film a large part or the whole of which is to be removed in a later step, the mask film 118A is preferably easy to process. Therefore, the mask film 118A is preferably formed at a substrate temperature lower than that for the insulating layer 125.

An organic material may be used for one or both of the mask film 118A and the mask film 119A. For example, a material that can be dissolved in a solvent chemically stable with respect to at least the uppermost film of the film 113A may be used as the organic material. Specifically, a material that will be dissolved in water or alcohol is preferably used. In formation of a film of such a material, it is preferable to apply the material dissolved in a solvent such as water or alcohol by a wet film-formation method and then perform heat treatment for evaporating the solvent. At this time, the heat treatment is preferably performed in a reduced-pressure atmosphere, in which case the solvent can be removed at a low temperature in a short time and thermal damage to the film 113A can be reduced accordingly.

The mask film 118A and the mask film 119A may each be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluorine resin like a perfluoropolymer.

For example, an organic film (e.g., a PVA film) formed by an evaporation method or the above wet film-formation method can be used as the mask film 118A, and an inorganic film (e.g., a silicon nitride film) formed by a sputtering method can be used as the mask film 119A.

Note that as described in Embodiment 1, part of the mask film sometimes remains as a mask layer in the display device of one embodiment of the present invention.

Then, resist masks 190a are formed over the mask film 119A (FIG. 12A). The resist masks 190a can be formed by application of a photosensitive resin (photoresist), light exposure, and development.

The resist masks 190a may be formed using either a positive resist material or a negative resist material.

The resist masks 190a are provided at positions overlapping with the pixel electrode 111a, the pixel electrode 111b, and the pixel electrode 111c. The resist mask 190a is preferably provided also at a position overlapping with the conductive layer 123. This can inhibit the conductive layer 123 from being damaged in the fabrication process of the display device. Note that the resist mask 190a is not necessarily provided over the conductive layer 123.

As illustrated in the cross-sectional view along Y1-Y2 in FIG. 12A, the resist mask 190a is preferably provided to cover a region from an end portion of the film 113A to an end portion of the conductive layer 123 (an end portion on the film 113A side). In that case, end portions of the mask layer 118a and the mask layer 119a overlap with the end portion of the first layer 113 even after the mask film 118A and the mask film 119A are processed. Since the mask layer 118a and the mask layer 119a are provided to cover a region from the end portion of the first layer 113 to the end portion of the conductive layer 123 (the end portion on the first layer 113 side), the insulating layer 255c can be inhibited from being exposed (see the cross-sectional view along Y1-Y2 in FIG. 12C). This can prevent removal of the insulating layer 255a to the insulating layer 255c and part of the insulating layer included in the layer 101 including transistors by etching or the like, and can prevent exposure of the conductive layer included in the layer 101 including transistors. Thus, unintentional electrical connection between the conductive layer and another conductive layer can be inhibited. For example, a short circuit between the conductive layer and the common electrode 115 can be inhibited.

Next, part of the mask film 119A is removed using the resist masks 190a, so that the mask layers 119a are formed (FIG. 12B). The mask layers 119a remain over the pixel electrode 111a, the pixel electrode 111b, and the pixel electrode 111c and over the conductive layer 123. After that, the resist masks 190a are removed. Then, part of the mask film 118A is removed using the mask layers 119a as masks (also referred to as hard masks), whereby the mask layers 118a are formed (FIG. 12C).

The mask film 118A and the mask film 119A can each be processed by a wet etching method or a dry etching method. The mask film 118A and the mask film 119A are preferably processed by anisotropic etching.

Using a wet etching method can reduce damage to the film 113A in processing of the mask film 118A and the mask film 119A, compared to the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, or a chemical solution containing a mixed solution of any of these acids, for example.

Since the film 113A is not exposed in the processing of the mask film 119A, the range of choices for a processing method for the mask film 119A is wider than that for the mask film 118A. For example, a gas containing oxygen can be used as an etching gas in the processing of the mask film 119A. As illustrated in FIG. 12A, a surface of the film 113A is covered with the mask film 118A during the processing of the mask film 119A. Thus, even when a gas containing oxygen is used for the processing of the mask film 119A, the film 113A is not exposed to oxygen directly. As a result, deterioration of the film 113A due to the influence of oxygen can be inhibited.

In the case of using a dry etching method for processing the mask film 118A, deterioration of the film 113A can be inhibited by not using a gas containing oxygen as the etching gas. In the case of using a dry etching method, it is preferable to use a gas containing CF₄, C₄F₈, SF₆, CHF₃, Cl₂, H₂O, or BCL₃ or a noble gas (also referred to as a rare gas) such as He as the etching gas, for example.

For example, in the case where an aluminum oxide film formed by an ALD method is used as the mask film 118A, the mask film 118A can be processed by a dry etching method using a combination of CHF₃ and He or a combination of CHF₃, He, and CH₄. In the case where an In—Ga—Zn oxide film formed by a sputtering method is used as the mask film 119A, the mask film 119A can be processed by a wet etching method using dilute phosphoric acid. Alternatively, the mask film 119A may be processed by a dry etching method using CH₄ and Ar. When a tungsten film formed by a sputtering method is used as the mask film 119A, the mask film 119A can be processed by a dry etching method using a combination of SF₆, CF₄, and O₂ or a combination of CF₄, Cl₂, and O₂.

The resist masks 190a can be removed by ashing using oxygen plasma, for example. Alternatively, an oxygen gas and any of CF₄, C₄F₈, SF₆, CHF₃, Cl₂, H₂O, BCl₃, or a noble gas such as He may be used. Alternatively, the resist masks 190a may be removed by wet etching. At this time, the mask film 118A or the mask layers 119a are positioned on the outermost surface and the film 113A is not exposed; thus, the film 113A can be inhibited from being damaged in the step of removing the resist masks 190a. In addition, the range of choices for the method for removing the resist masks 190a can be widened.

Then, the film 113A is processed, so that the first layers 113 are formed. For example, part of the film 113A is removed using the mask layers 119a and the mask layers 118a as hard masks, so that the first layers 113 are formed (FIG. 12C).

Thus, as illustrated in FIG. 12C, a stacked-layer structure of the first layer 113, the mask layer 118a, and the mask layer 119a remains over each of the pixel electrode 111a, the pixel electrode 111b, and the pixel electrode 111c.

As illustrated in FIG. 12C, a plurality of the first layers 113 can be formed by processing the film 113A. That is, the film 113A can be divided into the plurality of first layers 113. In this manner, the island-shaped first layer 113 is provided in each subpixel. Since the first layers 113 are formed by dividing the film 113A, the first layers 113 can be formed of the same material to have the same thickness. Furthermore, the island-shaped first layers 113 of adjacent subpixels can be inhibited from being in contact with each other. As a result, generation of a leakage current between the subpixels can be inhibited. Accordingly, degradation of the display quality of the display device can be inhibited. In addition, the display device can have both high resolution and high display quality.

The distance between two adjacent layers among the plurality of first layers 113, which are formed by a photolithography method as described above, can be shortened to less than or equal to 8 μm, less than or equal to 5 μm, less than or equal to 3 μm, less than or equal to 2 μm, or less than or equal to 1 μm. Here, the distance can be specified by, for example, the distance between facing end portions of two adjacent layers among the plurality of first layers 113. When the distance between island-shaped EL layers is shortened in this manner, a display device with high resolution and a high aperture ratio can be provided.

Note that the side surfaces of the first layers 113 are preferably perpendicular or substantially perpendicular to their formation surfaces. For example, the angle formed by the formation surfaces and these side surfaces is preferably greater than or equal to 600 and less than or equal to 90°.

FIG. 12C illustrates an example where the end portion of the first layer 113 is positioned outward from the end portion of the pixel electrode. Such a structure can increase the aperture ratio of the pixel. Although not illustrated in FIG. 12C, a depressed portion is sometimes formed by the etching treatment in a region of the insulating layer 255c not overlapping with the first layer 113.

The first layer 113 covers the top surface and the side surface of the pixel electrode and thus, the subsequent steps can be performed without exposure of the pixel electrode. When the end portion of the pixel electrode is exposed, corrosion might occur in the etching step or the like. A product generated by corrosion of the pixel electrode might be unstable; for example, the product might be dissolved in a solution in wet etching and might be scattered in an atmosphere in dry etching. The product dissolved in a solution or scattered in an atmosphere might be attached to a surface to be processed, the side surface of the first layer 113, and the like, which adversely affects the characteristics of the light-emitting device or forms a leakage path between the light-emitting devices in some cases. In a region where the end portion of the pixel electrode is exposed, adhesion between layers might be lowered, which might be likely to cause peeling of the first layer 113 or the pixel electrode.

Thus, with the structure where the first layers 113 cover the top surfaces and the side surfaces of the pixel electrode 111a, the pixel electrode 111b, and the pixel electrode 111c, the yield and characteristics of the light-emitting devices can be improved, for example.

In a region corresponding to the connection portion 140, a stacked-layer structure of the mask layer 118a and the mask layer 119a remains over the conductive layer 123 (FIG. 12C).

As described above, in the cross-sectional view along Y1-Y2 in FIG. 12C, the mask layer 118a and the mask layer 119a are provided to cover the end portion of the first layer 113 and the end portion of the conductive layer 123, and the insulating layer 255c is not exposed. This can prevent removal of the insulating layer 255a to the insulating layer 255c and part of the insulating layer included in the layer 101 including transistors by etching or the like, and can prevent exposure of the conductive layer included in the layer 101 including transistors. Thus, unintentional electrical connection between the conductive layer and another conductive layer can be inhibited.

The film 113A is preferably processed by anisotropic etching. In particular, anisotropic dry etching is preferably employed. Alternatively, wet etching may be employed.

In the case of using a dry etching method, deterioration of the film 113A can be inhibited by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Thus, damage to the film 113A can be inhibited. Furthermore, a defect such as attachment of a reaction product generated in the etching can be inhibited.

In the case of using a dry etching method, it is preferable to use a gas containing at least one of H₂, CF₄, C₄F₈, SF₆, CHF₃, Cl₂, H₂O, BCl₃, and noble gases such as He and Ar as the etching gas, for example. Alternatively, a gas containing oxygen and at least one of the above is preferably used as the etching gas. Alternatively, an oxygen gas may be used as the etching gas. Specifically, for example, a gas containing H₂ and Ar or a gas containing CF₄ and He can be used as the etching gas. For another example, a gas containing CF₄, He, and oxygen can be used as the etching gas. For another example, a gas containing H₂ and Ar and a gas containing oxygen can be used as the etching gas.

As described above, in one embodiment of the present invention, the mask layers 119a are formed in the following manner: the resist masks 190a are formed over the mask film 119A; and part of the mask film 119A is removed using the resist masks 190a. After that, part of the film 113A is removed using the mask layers 119a as hard masks, so that the first layers 113 are formed. In other words, the first layers 113 are formed by processing the film 113A by a photolithography method. Note that part of the film 113A may be removed using the resist masks 190a. Then, the resist masks 190a may be removed.

In the case of fabricating a display device that includes both the light-emitting device and the light-receiving device as illustrated in FIG. 11A and FIG. 11B, the second layer 155 included in the light-receiving device is formed in a manner similar to that for the first layer 113. There is no particular limitation on the formation order of the first layer 113 and the second layer 155. For example, when a layer with high adhesion to the pixel electrode is formed earlier, peeling in the process can be inhibited. For example, in the case where the first layer 113 has higher adhesion to the pixel electrode than the second layer 155, the first layer 113 is preferably formed earlier. The thickness of the layer formed earlier sometimes affects the distance between the substrate and a mask for defining a film formation area in the subsequent steps of forming the other layers. Forming a thinner layer earlier can inhibit shadowing (formation of a layer in a shadow portion). For example, in the case where a light-emitting device with a tandem structure is formed, the first layer 113 is often thicker than the second layer 155; thus, it is preferable to form the second layer 155 earlier. In the case where a film is formed by a wet method using a high molecular material, it is preferable to form the film earlier. For example, in the case where the active layer is formed using a high molecular material, the second layer 155 is preferably formed earlier. As described above, the formation order is determined depending on the materials and film formation methods, whereby the fabrication yield of the display device can be increased.

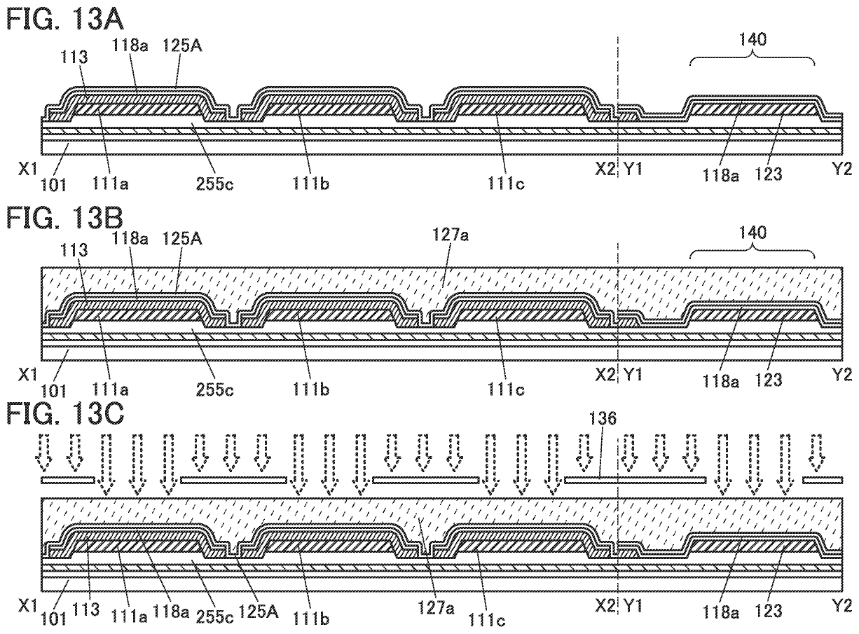

Next, the mask layers 119a are preferably removed (FIG. 13A). The mask layers 118a and the mask layers 119a remain in the display device in some cases, depending on the later steps. Removing the mask layers 119a at this stage can inhibit the mask layers 119a from remaining in the display device. For example, in the case where a conductive material is used for the mask layers 119a, removing the mask layers 119a in advance can inhibit generation of a leakage current, formation of a capacitor, or the like due to the remaining mask layers 119a.

Although this embodiment describes an example where the mask layers 119a are removed, the mask layers 119a are not necessarily removed. For example, in the case where the mask layers 119a contain the aforementioned material having a light-blocking property with respect to ultraviolet light, the process preferably proceeds to the next step without removing the mask layers, in which case the EL layers can be protected from ultraviolet light.

The step of removing the mask layers can be performed by a method similar to that for the step of processing the mask layers. In particular, using a wet etching method can reduce damage to the first layers 113 in removal of the mask layers, as compared to the case of using a dry etching method.

The mask layers may be removed by being dissolved in a solvent such as water or alcohol. Examples of alcohol include ethyl alcohol, methyl alcohol, isopropyl alcohol (IPA), and glycerin.

After the mask layers are removed, drying treatment may be performed to remove water contained in the first layers 113 and water adsorbed on surfaces of the first layers 113. For example, heat treatment in an inert gas atmosphere or a reduced-pressure atmosphere may be performed. It is desirable that the heat treatment be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, the insulating film 125A to be the insulating layer 125 later is formed to cover the pixel electrode 111a, the pixel electrode 111b, the pixel electrode 111c, the first layers 113, and the mask layers 118a (FIG. 13A).

Then, the insulating film 127a is formed over the insulating film 125A (FIG. 13B).

The insulating film 125A and the insulating film 127a are preferably formed by a formation method that causes less damage to the first layers 113. In particular, the insulating film 125A, which is formed in contact with the side surfaces of the first layers 113, is preferably formed by a formation method that causes less damage to the first layers 113 than the method for forming the insulating film 127a.

The insulating film 125A and the insulating film 127a are each formed at a temperature lower than the upper temperature limit of the first layers 113. When the insulating film 125A is formed at a high substrate temperature, the formed insulating film 125A, even with a small thickness, can have a low impurity concentration and a high barrier property against at least one of water and oxygen.

The insulating film 125A and the insulating film 127a are preferably formed at a substrate temperature higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the insulating film 125A, an insulating film is preferably formed within the above substrate temperature range to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating film 125A is preferably formed by an ALD method, for example. An ALD method is preferably used, in which case film formation damage to the formation surface can be reduced and a film with good coverage can be formed. As the insulating film 125A, an aluminum oxide film is preferably formed by an ALD method, for example.

Alternatively, the insulating film 125A may be formed by a sputtering method, a CVD method, or a PECVD method, each of which has a higher film formation rate than an ALD method. In that case, a highly reliable display device can be fabricated with high productivity.

The insulating film 127a is preferably formed by the aforementioned wet film-formation method. For example, the insulating film 127a is preferably formed by spin coating using a photosensitive resin, specifically, a photosensitive acrylic resin.

Heat treatment (also referred to as pre-baking) is preferably performed after the formation of the insulating film 127a. The heat treatment is performed at a temperature lower than the upper temperature limit of the first layers 113. The substrate temperature during the heat treatment is preferably higher than or equal to 50° C. and lower than or equal to 200° C., further preferably higher than or equal to 60° C. and lower than or equal to 150° C., and still further preferably higher than or equal to 70° C. and lower than or equal to 120° C. Accordingly, a solvent contained in the insulating film 127a can be removed.

Then, as illustrated in FIG. 13C, light exposure is performed to expose part of the insulating film 127a to visible light or ultraviolet rays. In the case where a positive acrylic resin is used for the insulating film 127a, a region where the insulating layer 127 is not formed in a later step is irradiated with visible light or ultraviolet rays using a mask 136. The insulating layer 127 is formed in regions interposed between adjacent two pixel electrodes among the pixel electrode 111a, the pixel electrode 111b, and the pixel electrode 111c, and around the conductive layer 123 as illustrated in FIG. 1B and FIG. 10A. Thus, as illustrated in FIG. 13C, irradiation with visible light or ultraviolet rays is performed above the pixel electrode 111a, the pixel electrode 111b, the pixel electrode 111c, and the conductive layer 123 using the mask 136.

Note that the width of the insulating layer 127 to be formed later can be controlled by the region exposed to light here. In this embodiment, processing is performed such that the insulating layer 127 includes a portion overlapping with the top surface of the pixel electrode (FIG. 4A and FIG. 4B). As illustrated in FIG. 8A or FIG. 8B, the insulating layer 127 does not necessarily include a portion overlapping with the top surface of the pixel electrode.

Light used for the light exposure preferably includes the i-line (wavelength: 365 nm). Furthermore, light used for the light exposure may include at least one of the g-line (wavelength: 436 nm) and the h-line (wavelength: 405 nm).

Although FIG. 13C illustrates an example where a positive photosensitive resin is used for the insulating film 127a and a region where the insulating layer 127 is not formed is irradiated with visible light or ultraviolet rays, the present invention is not limited thereto. For example, a negative photosensitive resin may be used for the insulating film 127a. In that case, a region where the insulating layer 127 is formed is irradiated with visible light or ultraviolet rays.

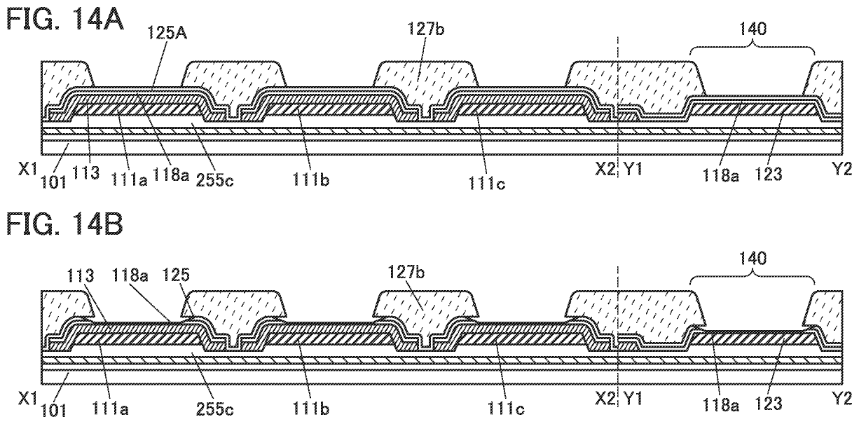

Next, as illustrated in FIG. 14A and FIG. 19A, development is performed to remove the region of the insulating film 127a exposed to light, so that an insulating layer 127b is formed. FIG. 19A is an enlarged view of the end portions of the first layer 113 and the insulating layer 127b illustrated in FIG. 14A and their vicinities. The insulating layer 127b is formed in regions interposed between adjacent two pixel electrodes among the pixel electrode 111a, the pixel electrode 111b, and the pixel electrode 111c, and in a region surrounding the conductive layer 123. In the case where an acrylic resin is used for the insulating film 127a, an alkaline solution is preferably used as a developer, and for example, an aqueous solution of tetramethylammonium hydroxide (TMAH) can be used.

Then, a residue (what is called scum) due to the development may be removed. For example, the residue can be removed by ashing using oxygen plasma.

Etching may be performed to adjust the surface level of the insulating layer 127b. The insulating layer 127b may be processed by ashing using oxygen plasma, for example. In the case where a non-photosensitive material is used for the insulating film 127a, the surface level of the insulating film 127a can be adjusted by the ashing or the like.

Next, light exposure may be performed on the entire substrate so that the insulating layer 127b is irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes lower the substrate temperature required for subsequent heat treatment for changing the shape of the insulating layer 127b into a tapered shape.

Meanwhile, as described later, when light exposure is not performed on the insulating layer 127b, it sometimes becomes easy to change the shape of the insulating layer 127b or change the shape of the insulating layer 127b to a tapered shape in a later step. Thus, sometimes it is preferable not to perform light expose on the insulating layer 127b after the development.

For example, in the case where a photocurable resin is used as a material of the insulating layer 127b, performing light exposure on the insulating layer 127b can start polymerization and cure the insulating layer 127b. Note that without performing light exposure on the insulating layer 127b at this stage, at least one of later-described first etching treatment, post-baking, and second etching treatment may be performed while the insulating layer 127b remains in a state where its shape is relatively easily changed. In that case, generation of unevenness in the formation surface of the common layer 114 and the common electrode 115 can be inhibited and accordingly disconnection of the common layer 114 and the common electrode 115 can be inhibited. After any of the later-described first etching treatment, post-baking, and second etching treatment, light exposure may be performed on the insulating layer 127b (or the insulating layer 127).

Next, as illustrated in FIG. 14B and FIG. 19B, etching treatment is performed using the insulating layer 127b as a mask to remove part of the insulating film 125A and reduce the thicknesses of parts of the mask layers 118a. Accordingly, the insulating layer 125 is formed below the insulating layer 127b. In addition, surfaces of the thin portions of the mask layers 118a are exposed. FIG. 19B is an enlarged view of the end portions of the first layer 113 and the insulating layer 127b illustrated in FIG. 14B and their vicinities. Note that the etching treatment using the insulating layer 127b as a mask may be hereinafter referred to as first etching treatment.

The first etching treatment can be performed by dry etching or wet etching. Note that the insulating film 125A is preferably formed using a material similar to that for the mask layers 118a, in which case the first etching treatment can be performed collectively.

As illustrated in FIG. 19B, etching is performed using the insulating layer 127b with a tapered side surface as a mask, so that the side surface of the insulating layer 125 and upper end portions of the side surfaces of the mask layers 118a can be tapered relatively easily.

In the case of performing dry etching, a chlorine-based gas is preferably used. As the chlorine-based gas, Cl₂, BCl₃, SiCl₄, CCl₄, or the like can be used alone or two or more of the gases can be mixed and used. Moreover, an oxygen gas, a hydrogen gas, a helium gas, an argon gas, or the like or a mixture of two or more of the gases can be added to the chlorine-based gas as appropriate. By employing dry etching, the thin regions of the mask layers 118a can be formed with a favorable in-plane uniformity.

As a dry etching apparatus, a dry etching apparatus including a high-density plasma source can be used. As the dry etching apparatus including a high-density plasma source, an inductively coupled plasma (ICP) etching apparatus or the like can be used, for example. Alternatively, a capacitively coupled plasma (CCP) etching apparatus including parallel plate electrodes can be used. The capacitively coupled plasma etching apparatus including parallel plate electrodes may have a structure where a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes.

In the case of performing dry etching, a by-product or the like generated by the dry etching is sometimes deposited on the top surface and the side surface of the insulating layer 127b, for example. Thus, a component contained in the etching gas, a component contained in the insulating film 125A, components contained in the mask layers 118a, or the like might be contained in the insulating layer 127 after the display device is completed.

The first etching treatment is preferably performed by wet etching. Using a wet etching method can reduce damage to the first layers 113, as compared to the case of using a dry etching method. The wet etching can be performed using an alkaline solution or the like. For example, wet etching of an aluminum oxide film is preferably performed using an aqueous solution of tetramethylammonium hydroxide (TMAH) that is an alkaline solution. In that case, puddle wet etching can be performed. Note that the insulating film 125A is preferably formed using a material similar to that for the mask layers 118a, in which case the etching treatment can be performed collectively.

As illustrated in FIG. 14B and FIG. 19B, in the first etching treatment, the etching treatment is stopped when the thicknesses of the mask layers 118a are reduced, before the mask layers are completely removed. In this manner, the mask layers 118a are made to remain over the first layers 113, so that the first layers 113 can be prevented from being damaged by treatment in a later step.

Although the thicknesses of the mask layers 118a are reduced in FIG. 14B and FIG. 19B, the present invention is not limited thereto. For example, depending on the thickness of the insulating film 125A and the thicknesses of the mask layers 118a, the first etching treatment might be stopped before the insulating film 125A is processed into the insulating layer 125. Specifically, the first etching treatment might be stopped after reducing the thickness of only part of the insulating film 125A. In the case where the insulating film 125A is formed using a material similar to that for the mask layers 118a and accordingly boundaries between the insulating film 125A and the mask layers 118a are unclear, whether the insulating layer 125 is formed or whether the thicknesses of the mask layers 118a are reduced cannot be determined in some cases.

Although FIG. 14B and FIG. 19B illustrate an example where the shape of the insulating layer 127b is not changed from that in FIG. 14A and FIG. 19A, the present invention is not limited thereto. For example, the end portion of the insulating layer 127b droops to cover the end portion of the insulating layer 125 in some cases. In another case, the end portion of the insulating layer 127b is in contact with the top surface of the mask layer 118a, for example. As described above, in the case where light exposure is not performed on the insulating layer 127b after the development, the shape of the insulating layer 127b is likely to change in some cases.

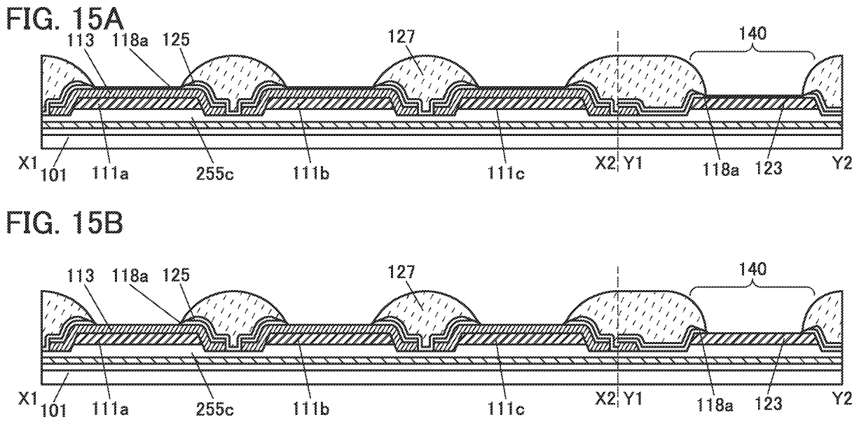

Then, as illustrated in FIG. 15A and FIG. 19C, heat treatment (also referred to as post-baking) is performed. As illustrated in FIG. 15A and FIG. 19C, the heat treatment can change the insulating layer 127b into the insulating layer 127 with a tapered side surface. As described above, in some cases, the insulating layer 127b is already changed in shape and has a tapered side surface at the time when the first etching treatment is finished. The heat treatment is performed at a temperature lower than the upper temperature limit of the EL layers. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. The heat treatment is preferably performed in a reduced-pressure atmosphere, in which case drying at a lower temperature is possible. The heat treatment in this step is preferably performed at a higher substrate temperature than the heat treatment (pre-baking) after the formation of the insulating film 127a. Accordingly, adhesion between the insulating layer 127 and the insulating layer 125 can be improved, and corrosion resistance of the insulating layer 127 can be increased. FIG. 19C is an enlarged view of the end portions of the first layer 113 and the insulating layer 127 illustrated in FIG. 15A and their vicinities.

When the mask layers 118a are not completely removed by the first etching treatment and the mask layers 118a with reduced thicknesses remain, the first layers 113 can be prevented from being damaged by the heat treatment and deteriorating. This improves the reliability of the light-emitting devices.

As illustrated in FIG. 6A and FIG. 6B, the side surface of the insulating layer 127 might have a concave curved shape depending on the material of the insulating layer 127, and the temperature, time, and atmosphere of the post-baking. For example, the insulating layer 127 is more likely to be changed in shape to have a concave curved shape as the post-baking is performed at higher temperature or for a longer time. In addition, as described above, the insulating layer 127 is sometimes likely to be changed in shape at the time of the post-baking, in the case where light exposure is not performed on the insulating layer 127b after the development.

Next, as illustrated in FIG. 15B and FIG. 19D, etching treatment is performed using the insulating layer 127 as a mask to remove parts of the mask layers 118a. Note that part of the insulating layer 125 is also removed in some cases. Consequently, openings are formed in the mask layers 118a, and the top surfaces of the first layers 113 and the conductive layer 123 are exposed. Note that FIG. 19D is an enlarged view of the end portions of the first layer 113 and the insulating layer 127 illustrated in FIG. 15B and their vicinities. Note that the etching treatment using the insulating layer 127 as a mask may be hereinafter referred to as second etching treatment.

The end portion of the insulating layer 125 is covered with the insulating layer 127. FIG. 15B and FIG. 19D illustrate an example where part of the end portion of the mask layer 118a (specifically, a tapered portion formed by the first etching treatment) is covered with the insulating layer 127 and the tapered portion formed by the second etching treatment is exposed. That is, the structure in FIG. 15B and FIG. 19D corresponds to that in FIG. 4A and FIG. 4B.

If the first etching treatment is not performed and the insulating layer 125 and the mask layer 118a are collectively etched after the post-baking, the insulating layer 125 and the mask layer 118a under the end portion of the insulating layer 127 may be eliminated by side etching and a cavity may be formed. The cavity causes unevenness in the formation surface of the common layer 114 and the common electrode 115, so that disconnection is likely to occur in the common layer 114 and the common electrode 115. Meanwhile, even when a cavity is formed owing to side etching of the insulating layer 125 and the mask layer 118a by the first etching treatment, the post-baking performed subsequently can make the insulating layer 127 fill the cavity. After that, the mask layer 118a having a smaller thickness is etched by the second etching treatment; thus, the amount of side etching decreases, a cavity is less likely to be formed, and even if a cavity is formed, it can be extremely small. Therefore, the formation surface of the common layer 114 and the common electrode 115 can be flatter than that in the case where the insulating layer 125 and the mask layer 118a are collectively etched.

Note that as illustrated in FIG. 5A, FIG. 5B, FIG. 7A, and FIG. 7B, the insulating layer 127 may cover the entire end portion of the mask layer 118a. For example, the end portion of the insulating layer 127 droops to cover the end portion of the mask layer 118a in some cases. For another example, the end portion of the insulating layer 127 may be in contact with the top surface of the first layer 113. As described above, in the case where light exposure is not performed on the insulating layer 127b after the development, the shape of the insulating layer 127 is likely to change in some cases.

The second etching treatment is preferably performed by wet etching. Using a wet etching method can reduce damage to the first layers 113, as compared to the case of using a dry etching method. The wet etching can be performed using an alkaline solution or the like.

As described above, by providing the insulating layer 127, the insulating layer 125, and the mask layers 118a, a connection defect between the light-emitting devices due to disconnected portions of the common layer 114 and the common electrode 115 and an increase in electric resistance due to locally thinned portions of the common layer 114 and the common electrode 115 can be inhibited from occurring between the light-emitting devices. Thus, the display device of one embodiment of the present invention can have improved display quality.

Heat treatment may be performed after parts of the first layers 113 are exposed. The heat treatment can remove water contained in the EL layers, water adsorbed onto surfaces of the EL layers, and the like. The shape of the insulating layer 127 may be changed by the heat treatment. Specifically, the insulating layer 127 may be extended to cover at least one of the end portion of the insulating layer 125, the end portions of the mask layers 118a, and the top surfaces of the first layers 113. For example, the insulating layer 127 may have a shape illustrated in FIG. 5A and FIG. 5B. The heat treatment can be performed in an inert gas atmosphere or a reduced-pressure atmosphere, for example. It is desirable that the heat treatment be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case dehydration at a lower temperature is possible. Note that the temperature range of the heat treatment is preferably set as appropriate in consideration of the upper temperature limit of the EL layers. In consideration of the upper temperature limit of the EL layers, temperatures from 70° C. to 120° C. inclusive are particularly preferable in the above temperature range.

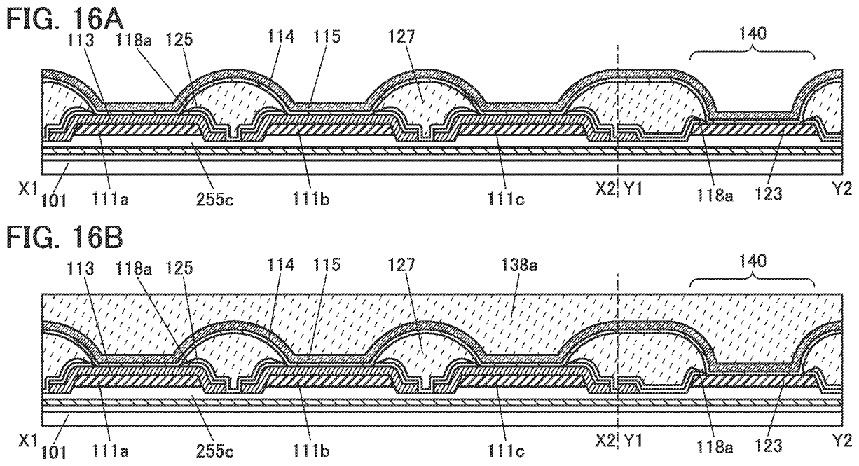

Next, the common layer 114 and the common electrode 115 are formed over the insulating layer 127 and the first layers 113 (FIG. 16A).

The common layer 114 can be formed by an evaporation method (including a vacuum evaporation method), a transfer method, a printing method, an ink-jet method, a coating method, or the like.

The common electrode 115 can be formed by a sputtering method or a vacuum evaporation method, for example. Alternatively, a film formed by an evaporation method and a film formed by a sputtering method may be stacked.

Next, an insulating film 138a is formed over the common electrode 115 (FIG. 16B). The insulating film 138a is formed using a material having a higher refractive index than the common electrode 115. The insulating film 138a can be formed using a material and a process similar to those for the insulating film 127a illustrated in FIG. 13B. When the insulating film 138a and the insulating film 127a are formed using the same material, i.e., the insulating film 138a and the insulating film 127a contain the same material, the manufacturing cost can be reduced. When the insulating film 138a and the insulating film 127a contain the same material, the shrinkage of the material (e.g., an organic resin material) due to heat treatment performed in a later step can be caused in the same manner in the insulating film 138a and the insulating film 127a. It is preferable that the materials used for the insulating film 138a and the insulating film 127a shrink in the same manner or have the same shrinkage rate because in that case, stress or the like of the whole display device easy to control.

The insulating film 138a is formed at a temperature lower than the upper temperature limit of the first layers 113. The insulating film 138a is preferably formed at a substrate temperature higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

The insulating film 138a is preferably formed by the aforementioned wet film-formation method. For example, the insulating film 138a is preferably formed by spin coating using a photosensitive resin, specifically, a photosensitive acrylic resin.

Heat treatment (pre-baking) is preferably performed after the formation of the insulating film 138a. The heat treatment is performed at a temperature lower than the upper temperature limit of the first layers 113. The substrate temperature during the heat treatment is preferably higher than or equal to 50° C. and lower than or equal to 200° C., further preferably higher than or equal to 60° C. and lower than or equal to 150° C., and still further preferably higher than or equal to 70° C. and lower than or equal to 120° C. Accordingly, a solvent contained in the insulating film 138a can be removed.

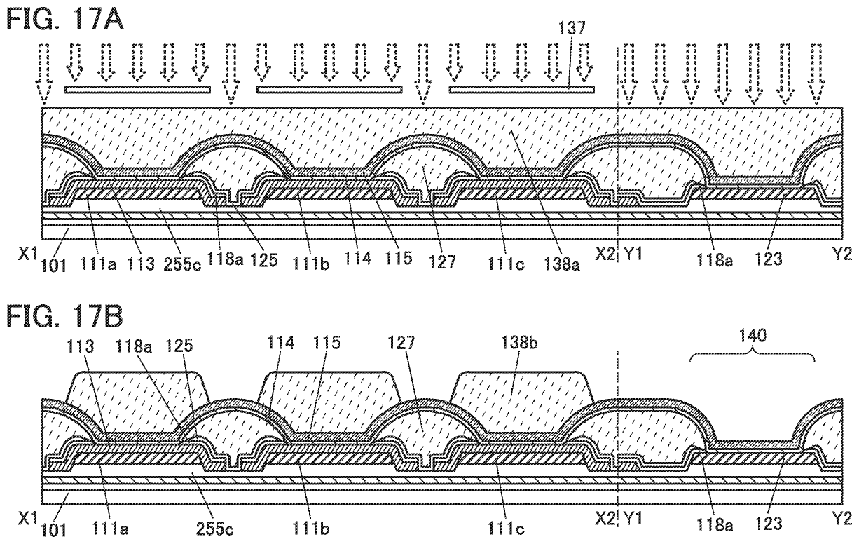

Then, as illustrated in FIG. 17A, light exposure is performed to expose part of the insulating film 138a to visible light or ultraviolet rays. Here, in the case where a positive acrylic resin is used for the insulating film 138a, a region where the lens 138 is not formed in a later step is irradiated with visible light or ultraviolet rays using a mask 137. As illustrated in FIG. 1B, the lenses 138 are formed in regions overlapping with the pixel electrode 111a, the pixel electrode 111b, and the pixel electrode 111c (regions each interposed between adjacent insulating layers 127). Thus, as illustrated in FIG. 17A, at least part of a region overlapping with the insulating layer 127 is irradiated with visible light or ultraviolet rays with the use of the mask 137.

Note that the width of the lens 138 to be formed later can be controlled by the region exposed to light here. In this embodiment, processing is performed such that the lens 138 includes a portion overlapping with at least the top surface of the pixel electrode (FIG. 1B, FIG. 3A, and FIG. 3B).

Light used for the light exposure preferably includes the i-line (wavelength: 365 nm). Furthermore, light used for the light exposure may include at least one of the g-line (wavelength: 436 nm) and the h-line (wavelength: 405 nm).

Although FIG. 17A illustrates an example where a positive photosensitive resin is used for the insulating film 138a and a region where the lens 138 is not formed is irradiated with visible light or ultraviolet rays, the present invention is not limited thereto. For example, a negative photosensitive resin may be used for the insulating film 138a. In that case, a region where the lens 138 is formed is irradiated with visible light or ultraviolet rays.

Next, as illustrated in FIG. 17B, development is performed to remove the region of the insulating film 138a exposed to light, so that insulating layers 138b are formed. The insulating layers 138b are formed in regions overlapping with the pixel electrode 111a, the pixel electrode 111b, and the pixel electrode 111c (regions each interposed between adjacent insulating layers 127). In the case where an acrylic resin is used for the insulating film 138a, an alkaline solution is preferably used as a developer, and for example, an aqueous solution of tetramethylammonium hydroxide (TMAH) can be used.

Then, a residue (scum) due to the development may be removed. For example, the residue can be removed by ashing using oxygen plasma.

Etching may be performed to adjust the surface levels of the insulating layers 138b. The insulating layers 138b may be processed by ashing using oxygen plasma, for example. In the case where a non-photosensitive material is used for the insulating film 138a, the surface level of the insulating film 138a can be adjusted by the ashing or the like.

Next, light exposure may be performed on the entire substrate so that the insulating layers 138b are irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can improve the transparency of the insulating layers 138b in some cases. In addition, it is sometimes possible to lower the substrate temperature required for subsequent heat treatment for changing the shape of each of the insulating layers 138b into a tapered shape.

For example, in the case where a photocurable resin is used as a material of the insulating layers 138b, performing light exposure on the insulating layers 138b can start polymerization and cure the insulating layers 138b. Note that without performing light exposure on the insulating layers 138b at this stage, later-described post-baking may be performed while the insulating layers 138b remain in a state where their shapes are relatively easily changed. After the later-described post-baking, light exposure may be performed on the lenses 138.

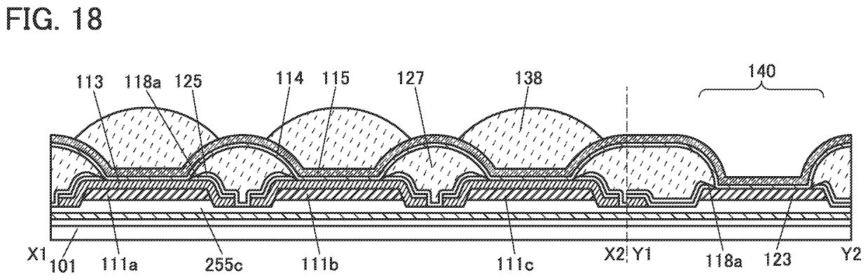

Then, heat treatment (post-baking) is performed as illustrated in FIG. 18. By performing the heat treatment, the insulating layers 138b can be changed in shape to become the plano-convex lenses 138 as illustrated in FIG. 18. The heat treatment is performed at a temperature lower than the upper temperature limit of the EL layers. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. The heat treatment is preferably performed in a reduced-pressure atmosphere, in which case drying at a lower temperature is possible. The heat treatment in this step is preferably performed at a higher substrate temperature than the heat treatment (pre-baking) after the formation of the insulating film 138a. Accordingly, adhesion between the lenses 138 and the common electrode 115 can be improved, and corrosion resistance of the lenses 138 can be increased.

Next, the protective layer 131 is formed over the common electrode 115 and the lenses 138. The protective layer 131 is formed using a material having a lower refractive index than the lenses 138. Subsequently, the coloring layer 132R, the coloring layer 132G, and the coloring layer 132B are formed over the protective layer 131. Furthermore, the substrate 120 is attached onto the protective layer 131 and the coloring layers with the resin layer 122, whereby the display device 100 can be fabricated (FIG. 1).

Examples of the method for forming the protective layer 131 include a vacuum evaporation method, a sputtering method, a CVD method, and an ALD method.

As described above, in the method for manufacturing a display device of this embodiment, the island-shaped EL layers are formed not by using a fine metal mask but by processing an EL layer formed over the entire surface. Thus, the size of the EL layer can be made smaller than the size of the EL layer formed using a fine metal mask. Accordingly, a high-resolution display device or a display device with a high aperture ratio, which has been difficult to achieve, can be manufactured. Furthermore, even when the resolution or the aperture ratio is high owing to an extremely short distance between subpixels, contact between the island-shaped EL layers of the adjacent subpixels can be inhibited. As a result, generation of a leakage current between the subpixels can be inhibited. Accordingly, degradation of the display quality of the display device can be inhibited. In addition, both the high resolution and high display quality of the display device can be achieved.

The insulating layer 127 having a tapered end portion and being provided between adjacent island-shaped EL layers can inhibit occurrence of disconnection in the common layer 114 and the common electrode 115 and prevent formation of a locally thinned portion in the common layer 114 and the common electrode 115. Thus, a connection defect between the light-emitting devices due to a disconnected portion and an increase in electric resistance due to a locally thinned portion can be inhibited from being caused in the common layer 114 and the common electrode 115.

Furthermore, the lens 138 is provided over each of the light-emitting devices (the light-emitting device 130a, the light-emitting device 130b, and the light-emitting device 130c) so as to include a region overlapping with at least the light-emitting device, so that light emitted from the light-emitting devices can be extracted toward the coloring layers (the coloring layer 132R, the coloring layer 132G, and the coloring layer 132B) more efficiently than when the lenses 138 are not provided. Accordingly, both the luminance and the reliability of the display device can be increased.

This embodiment can be combined with any of the other embodiments as appropriate.

### Embodiment 3

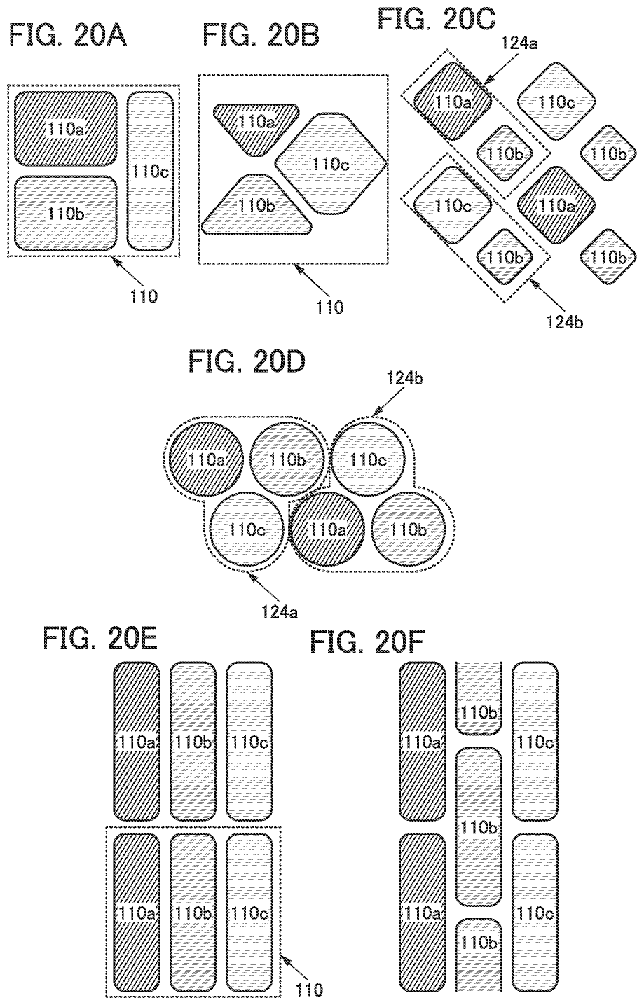

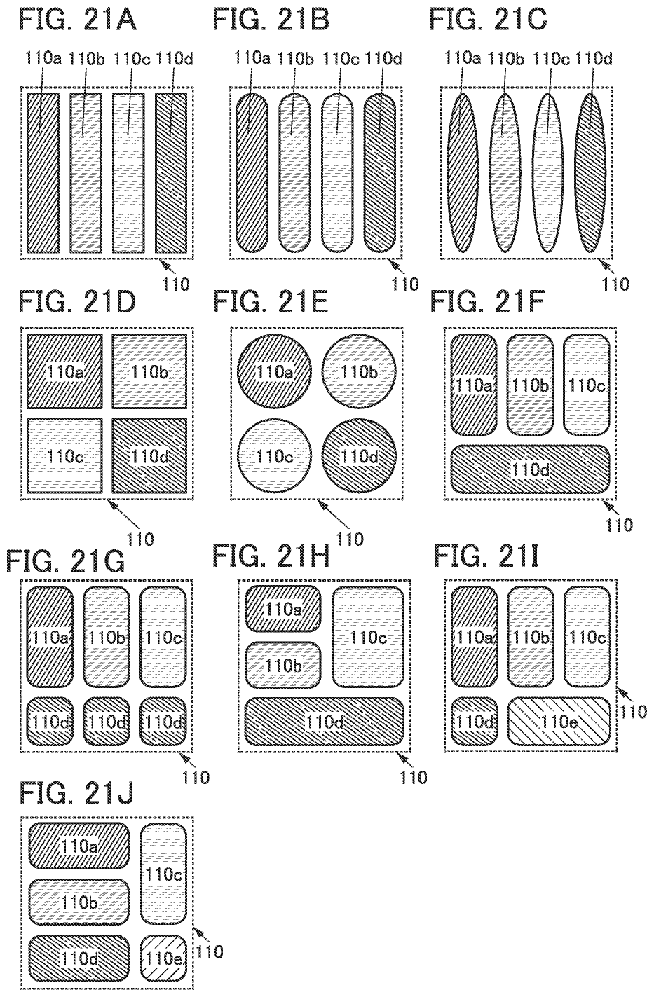

In this embodiment, display devices of embodiments of the present invention are described with reference to FIG. 20 and FIG. 21.

### [Pixel Layout]

Pixel layouts different from the layout in FIG. 1A will be mainly described in this embodiment. There is no particular limitation on the arrangement of subpixels, and any of a variety of methods can be employed. Examples of the arrangement of subpixels include stripe arrangement, S-stripe arrangement, matrix arrangement, delta arrangement, Bayer arrangement, and PenTile arrangement.

The top surface shape of the subpixel illustrated in a diagram in this embodiment corresponds to the top surface shape of a light-emitting region (or a light-receiving region).

Examples of the top surface shape of the subpixel include polygons such as a triangle, a tetragon (including a rectangle and a square), and a pentagon; polygons with rounded corners; an ellipse; and a circle.

The range of the circuit layout for forming the subpixels is not limited to the range of the subpixels illustrated in a diagram and may be placed outside the subpixels.

The pixel 110 illustrated in FIG. 20A employs S stripe arrangement. The pixel 110 illustrated in FIG. 20A is composed of three subpixels: the subpixel 110a, the subpixel 110b, and the subpixel 110c.

The pixel 110 illustrated in FIG. 20B includes the subpixel 110a whose top surface has a rough triangle or rough trapezoidal shape with rounded corners, the subpixel 110b whose top surface has a rough triangle or rough trapezoidal shape with rounded corners, and the subpixel 110c whose top surface has a rough tetragonal or rough hexagonal shape with rounded corners. The subpixel 110b has a larger light-emitting area than the subpixel 110a. In this manner, the shapes and sizes of the subpixels can be determined independently. For example, the size of a subpixel including a light-emitting device with higher reliability can be smaller.

The pixel 124a and the pixel 124b illustrated in FIG. 20C employ PenTile arrangement. FIG. 20C illustrates an example where the pixels 124a including the subpixel 110a and the subpixel 110b and the pixels 124b including the subpixel 110b and the subpixel 110c are alternately arranged.

The pixel 124a and the pixel 124b illustrated in FIG. 20D employ delta arrangement. The pixel 124a includes two subpixels (the subpixel 110a and the subpixel 110b) in the upper row (first row) and one subpixel (the subpixel 110c) in the lower row (second row). The pixel 124b includes one subpixel (the subpixel 110c) in the upper row (first row) and two subpixels (the subpixel 110a and the subpixel 110b) in the lower row (second row).

While FIG. 1A illustrates an example where the top surface of each subpixel has a rough tetragonal shape with rounded corners, FIG. 20D illustrates an example where the top surface of each subpixel has a circular shape.

FIG. 20E illustrates an example of using the pixel 110 in which the subpixel 110a, the subpixel 110b, and the subpixel 110c are arranged in a stripe pattern.

FIG. 20F illustrates an example where subpixels of different colors are arranged in a zigzag manner. Specifically, the positions of the top sides of two subpixels arranged in the column direction (e.g., the subpixel 110a and the subpixel 110b or the subpixel 110b and the subpixel 110c) are not aligned in a top view.

For example, in each pixel illustrated in FIG. 20A to FIG. 20F, it is preferable that the subpixel 110a be a subpixel R emitting red light, the subpixel 110b be a subpixel G emitting green light, and the subpixel 110c be a subpixel B emitting blue light. Note that the structure of the subpixels is not limited to this, and the colors and arrangement order of the subpixels can be determined as appropriate. For example, the subpixel 110b may be the subpixel R emitting red light and the subpixel 110a may be the subpixel G emitting green light.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel may have a polygonal shape with rounded corners, an elliptical shape, a circular shape, or the like.

Furthermore, in the method for manufacturing a display device of one embodiment of the present invention, the EL layer is processed into an island shape using a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape after being processed. As a result, the top surface of the EL layer may have a polygonal shape with rounded corners, an elliptical shape, a circular shape, or the like. For example, when a resist mask whose top surface has a square shape is intended to be formed, a resist mask whose top surface has a circular shape may be formed, and the top surface of the EL layer may have a circular shape.

Note that to obtain a desired top surface shape of the EL layer, a technique of correcting a mask pattern in advance so that a transferred pattern agrees with a design pattern (OPC (Optical Proximity Correction) technique) may be used. Specifically, with the OPC technique, a pattern for correction is added to a corner portion or the like of a figure on a mask pattern.

As illustrated in FIG. 21A to FIG. 21H, the pixel may include four types of subpixels.

The pixels 110 illustrated in FIG. 21A to FIG. 21C employ stripe arrangement.

FIG. 21A illustrates an example where each subpixel has a rectangular top surface shape, FIG. 21B illustrates an example where each subpixel has a top surface shape formed by combining two half circles and a rectangle, and FIG. 21C illustrates an example where each subpixel has an elliptical top surface shape.

The pixels 110 illustrated in FIG. 21D and FIG. 21E employ matrix arrangement.

While FIG. 11A illustrates an example where the top surface of each subpixel has a rough square shape with rounded corners, FIG. 21D illustrates an example where the top surface of each subpixel has a square shape and FIG. 21E illustrates an example where the top surface of each subpixel has a circular shape.

FIG. 21F and FIG. 21G each illustrate an example where one pixel 110 is composed of two rows and three columns.

The pixel 110 illustrated in FIG. 21F includes three subpixels (the subpixel 110a, the subpixel 110b, and the subpixel 110c) in the upper row (first row) and one subpixel (the subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 illustrated in FIG. 21G includes three subpixels (the subpixel 110a, the subpixel 110b, and the subpixel 110c) in the upper row (first row) and three of the subpixels 110d in the lower row (second row). In other words, the pixel 110 includes the subpixel 110a and the subpixel 110d in the left column (first column), the subpixel 110b and the subpixel 110d in the center column (second column), and the subpixel 110c and the subpixel 110d in the right column (third column). Matching the positions of the subpixels in the upper row and the lower row as illustrated in FIG. 21G enables efficient removal of dust and the like that would be produced in the manufacturing process. Thus, a display device with high display quality can be provided.

FIG. 21H illustrates an example where one pixel 110 is composed of three rows and two columns.

The pixel 110 illustrated in FIG. 21H includes the subpixel 110a in the upper row (first row), the subpixel 110b in the center row (second row), the subpixel 110c across the first and second rows, and one subpixel (the subpixel 110d) in the lower row (third row). In other words, the pixel 110 includes the subpixel 110a and the subpixel 110b in the left column (first column), the subpixel 110c in the right column (second column), and the subpixel 110d across these two columns.

The pixels 110 illustrated in FIG. 21A to FIG. 21H are each composed of four subpixels: the subpixel 110a, the subpixel 110b, the subpixel 110c, and the subpixel 110d.

The subpixel 110a, the subpixel 110b, the subpixel 110c, and the subpixel 110d can include light-emitting devices emitting light of different colors. The subpixel 110a, the subpixel 110b, the subpixel 110c, and the subpixel 110d can be subpixels of four colors of R, G, B, and W, subpixels of four colors of R, G, B, and Y, or subpixels of four colors of R, G, B, and infrared light (IR), for example.

In the pixels 110 illustrated in FIG. 21A to FIG. 21H, it is preferable that the subpixel 110a be the subpixel R emitting red light, the subpixel 110b be the subpixel G emitting green light, the subpixel 110c be the subpixel B emitting blue light, and the subpixel 110d be any of a subpixel W emitting white light, a subpixel Y emitting yellow light, and a subpixel IR emitting near-infrared light, for example. In the case of such a structure, stripe arrangement is employed as the layout of R, G, and B in the pixels 110 illustrated in FIG. 21F and FIG. 21G, leading to higher display quality. In addition, what is called S-stripe arrangement is employed as the layout of R, G, and B in the pixel 110 illustrated in FIG. 21H, leading to higher display quality.

The pixel 110 may include a subpixel including a light-receiving device.

In the pixels 110 illustrated in FIG. 21A to FIG. 21H, any one of the subpixel 110a to the subpixel 110d may be a subpixel including a light-receiving device.

In the pixels 110 illustrated in FIG. 21A to FIG. 21H, for example, it is preferable that the subpixel 110a be the subpixel R emitting red light, the subpixel 110b be the subpixel G emitting green light, the subpixel 110c be the subpixel B emitting blue light, and the subpixel 110d be a subpixel S including a light-receiving device. In the case of such a structure, stripe arrangement is employed as the layout of R, G, and B in the pixels 110 illustrated in FIG. 21F and FIG. 21G, leading to higher display quality. In addition, what is called S-stripe arrangement is employed as the layout of R, G, and B in the pixel 110 illustrated in FIG. 21H, leading to higher display quality.

There is no particular limitation on the wavelength of light detected by the subpixel S including a light-receiving device. The subpixel S can have a structure capable of detecting one or both of visible light and infrared light.

As illustrated in FIG. 21I and FIG. 21J, the pixel may include five types of subpixels.

FIG. 21I illustrates an example where one pixel 110 is composed of two rows and three columns.

The pixel 110 illustrated in FIG. 21I includes three subpixels (the subpixel 110a, the subpixel 110b, and the subpixel 110c) in the upper row (first row) and two subpixels (the subpixel 110d and the subpixel 110e) in the lower row (second row). In other words, the pixel 110 includes the subpixel 110a and the subpixel 110d in the left column (first column), the subpixel 110b in the center column (second column), the subpixel 110c in the right column (third column), and the subpixel 110e across the second and third columns.

FIG. 21J illustrates an example where one pixel 110 is composed of three rows and two columns.

The pixel 110 illustrated in FIG. 21J includes the subpixel 110a in the upper row (first row), the subpixel 110b in the center row (second row), the subpixel 110c across the first and second rows, and two subpixels (the subpixel 110d and the subpixel 110e) in the lower row (third row). In other words, the pixel 110 includes the subpixel 110a, the subpixel 110b, and the subpixel 110d in the left column (first column), and the subpixel 110c and the subpixel 110e in the right column (second column).

In the pixels 110 illustrated in FIG. 21I and FIG. 21J, for example, it is preferable that the subpixel 110a be the subpixel R emitting red light, the subpixel 110b be the subpixel G emitting green light, and the subpixel 110c be the subpixel B emitting blue light. In the case of such a structure, stripe arrangement is employed as the layout of R, G, and B in the pixel 110 illustrated in FIG. 21I, leading to higher display quality. In addition, what is called S-stripe arrangement is employed as the layout of R, G, and B in the pixel 110 illustrated in FIG. 21J, leading to higher display quality.

In the pixels 110 illustrated in FIG. 21I and FIG. 21J, for example, it is preferable to use the subpixel S including a light-receiving device as at least one of the subpixel 110d and the subpixel 110e. In the case where light-receiving devices are used in both the subpixel 110d and the subpixel 110e, the light-receiving devices may have different structures. For example, the wavelength ranges of detected light may be different at least partly. Specifically, one of the subpixel 110d and the subpixel 110e may include a light-receiving device mainly detecting visible light and the other may include a light-receiving device mainly detecting infrared light.

In a preferred mode of the pixels 110 illustrated in FIG. 21I and FIG. 21J, for example, the subpixel S including a light-receiving device is used as one of the subpixel 110d and the subpixel 110e and a subpixel including a light-emitting device that can be used as a light source is used as the other. For example, it is preferable that one of the subpixel 110d and the subpixel 110e be the subpixel IR emitting infrared light and the other be the subpixel S including a light-receiving device detecting infrared light.

In a pixel including the subpixels R, G, B, IR, and S, while an image is displayed using the subpixels R, G, and B, reflected light of infrared light emitted by the subpixel IR that is used as a light source can be detected by the subpixel S.

As described above, the pixel composed of the subpixels each including the light-emitting device can employ any of a variety of layouts in the display device of one embodiment of the present invention. The display device of one embodiment of the present invention can have a structure where the pixel includes both a light-emitting device and a light-receiving device. Also in this case, any of a variety of layouts can be employed.

This embodiment can be combined with any of the other embodiments as appropriate.

### Embodiment 4

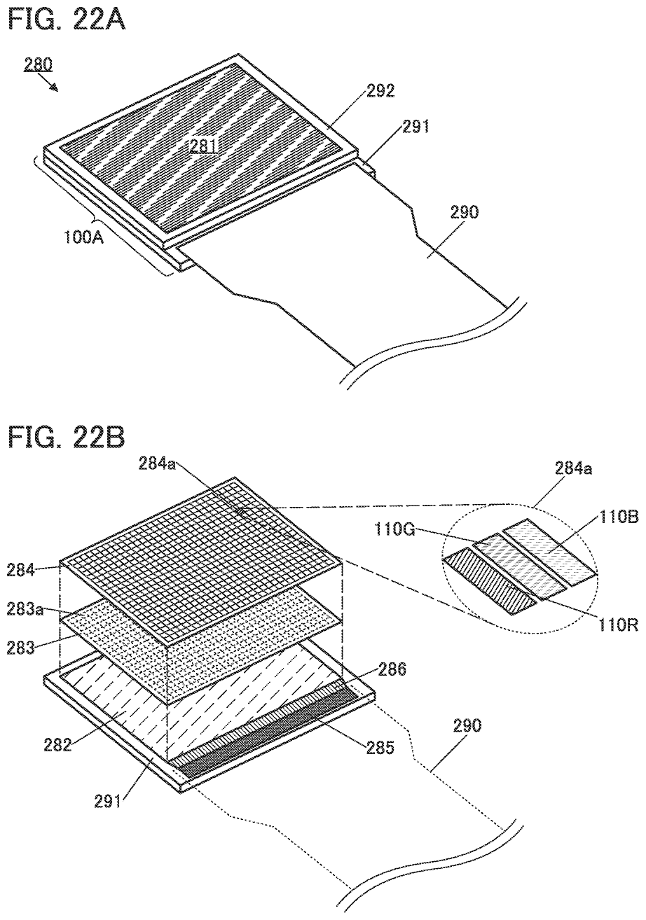

In this embodiment, display devices of embodiments of the present invention are described with reference to FIG. 22 to FIG. 32.

The display device of this embodiment can be a high-resolution display device. Accordingly, the display device in this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The display device of this embodiment can be a high-definition display device or a large-sized display device. Accordingly, the display device of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or notebook personal computer, a monitor of a computer and the like, digital signage, and a large game machine such as a pachinko machine.

### [Display Module]

FIG. 22A is a perspective view of a display module 280. The display module 280 includes a display device 100A and an FPC 290. Note that the display device included in the display module 280 is not limited to the display device 100A and may be any of a display device 100B to a display device 100F described later.

The display module 280 includes a substrate 291 and a substrate 292. The display module 280 includes a display portion 281. The display portion 281 is a region of the display module 280 where an image is displayed, and is a region where light from pixels provided in a pixel portion 284 described later can be seen.

FIG. 22B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 22B. The pixel 284a can employ any of the structures described in the above embodiments. FIG. 22B illustrates an example where a structure similar to that of the pixel 110 illustrated in FIG. 1A is employed.

The pixel circuit portion 283 includes a plurality of pixel circuits 283a arranged periodically.

One pixel circuit 283a is a circuit that controls driving of a plurality of elements included in one pixel 284a. One pixel circuit 283a can be provided with three circuits each controlling light emission of one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. Thus, an active-matrix display device is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; thus, the aperture ratio (the effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus, the display portion 281 can have an extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has an extremely high resolution, and thus can be suitably used for a VR device such as an HMD or a glasses-type AR device. For example, even with a structure where the display portion of the display module 280 is seen through a lens, pixels of the extremely-high-resolution display portion 281 included in the display module 280 are prevented from being seen when the display portion is enlarged by the lens, so that display providing a high sense of immersion can be performed. Without being limited thereto, the display module 280 can be suitably used for electronic devices including a relatively small display portion. For example, the display module 280 can be favorably used in a display portion of a wearable electronic device, such as a watch.

### [Display Device 100A]

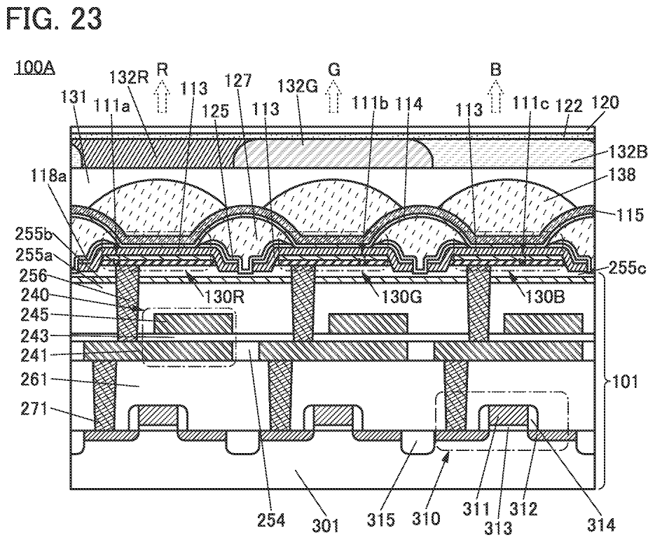

The display device 100A illustrated in FIG. 23 includes a substrate 301, a light-emitting device 130R, a light-emitting device 130G, a light-emitting device 130B, the coloring layer 132R, the coloring layer 132G, the coloring layer 132B, a capacitor 240, and a transistor 310.

The subpixel 110R illustrated in FIG. 22B includes the light-emitting device 130R and the coloring layer 132R, the subpixel HOG includes the light-emitting device 130G and the coloring layer 132G, and the subpixel 110B includes the light-emitting device 130B and the coloring layer 132B. In the subpixel 110R, light emitted from the light-emitting device 130R is extracted as red light to the outside of the display device 100A through the lens 138 and the coloring layer 132R. Similarly, in the subpixel 110G, light emitted from the light-emitting device 130G is extracted as green light to the outside of the display device 100A through the lens 138 and the coloring layer 132G. In the subpixel 110B, light emitted from the light-emitting device 130B is extracted as blue light to the outside of the display device 100A through the lens 138 and the coloring layer 132B.

The substrate 301 corresponds to the substrate 291 in FIG. 22A and FIG. 22B. A stacked-layer structure including the substrate 301 and the components thereover up to the insulating layer 255c corresponds to the layer 101 including transistors in Embodiment 1.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to the one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

The insulating layer 255a is provided to cover the capacitor 240, the insulating layer 255b is provided over the insulating layer 255a, and the insulating layer 255c is provided over the insulating layer 255b. The light-emitting device 130R, the light-emitting device 130G, and the light-emitting device 130B are provided over the insulating layer 255c. FIG. 23 illustrates an example where the light-emitting device 130R, the light-emitting device 130G, and the light-emitting device 130B each have the stacked-layer structure illustrated in FIG. 1B. An insulator is provided in a region between adjacent light-emitting devices. In FIG. 23 and the like, the insulating layer 125 and the insulating layer 127 over the insulating layer 125 are provided in this region.

The mask layer 118a is positioned over each of the first layers 113 included in the light-emitting device 130R, the light-emitting device 130G, and the light-emitting device 130B.

The pixel electrode 111a, the pixel electrode 111b, and the pixel electrode 111c are each electrically connected to the one of the source and the drain of the transistor 310 through a plug 256 embedded in the insulating layer 243, the insulating layer 255a, the insulating layer 255b, and the insulating layer 255c, the conductive layer 241 embedded in the insulating layer 254, and the plug 271 embedded in the insulating layer 261. The level of the top surface of the insulating layer 255c is equal to or substantially equal to the level of the top surface of the plug 256. A variety of conductive materials can be used for the plugs. FIG. 23 and the like illustrate an example where the pixel electrode 111a, the pixel electrode 111b, and the pixel electrode 111c each have a two-layer structure of a reflective electrode and a transparent electrode over the reflective electrode.

The lens 138 is provided over each of the light-emitting device 130R, the light-emitting device 130G, and the light-emitting device 130B so as to include a region overlapping with at least the light-emitting device. As described above, in the case where the lenses 138 are provided over the light-emitting devices, light emitted from the light-emitting devices can be extracted toward the coloring layers (the coloring layer 132R, the coloring layer 132G, and the coloring layer 132B) more efficiently than in the case where the lenses 138 are not provided. The protective layer 131 is provided over the lenses 138 to cover the lenses 138. Over the protective layer 131, the coloring layer 132R, the coloring layer 132G, and the coloring layer 132B overlapping with the light-emitting device 130R, the light-emitting device 130G, and the light-emitting device 130B, respectively, are provided. The substrate 120 is attached onto the coloring layers with the resin layer 122. Embodiment 1 can be referred to for details of the light-emitting devices and the components thereover up to the substrate 120. The substrate 120 corresponds to the substrate 292 in FIG. 22A.

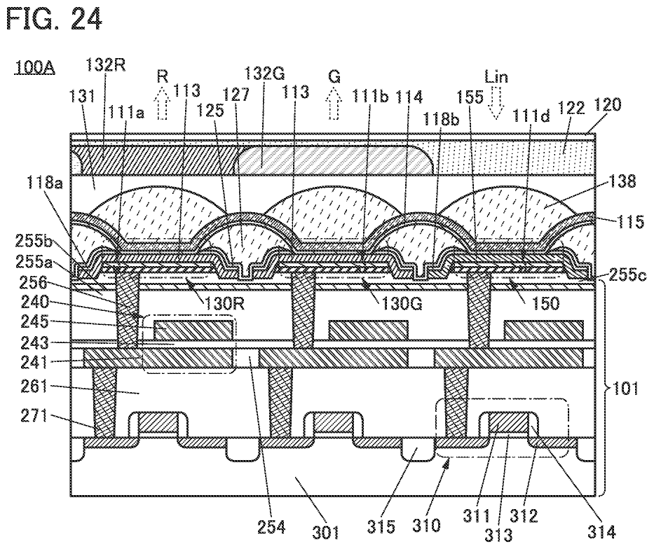

FIG. 24 illustrates an example where the display device includes the light-emitting device 130R, the light-emitting device 130G, and the light-receiving device 150. The light-receiving device 150 includes the pixel electrode 111d, the second layer 155, the common layer 114, and the common electrode 115 that are stacked. The lens 138 is provided over the light-receiving device 150 to include a region overlapping with at least the light-receiving device. As described above, in the case where the lens 138 is provided over the light-receiving device, light incident from the outside can enter the light-receiving device 150 more efficiently than in the case where the lens 138 is not provided. That is, the light-receiving device included in the display device of one embodiment of the present invention can have high light detection performance. Embodiment 1 and Embodiment 6 can be referred to for the details of the display device that includes the light-receiving device.

### [Display Device 100B]

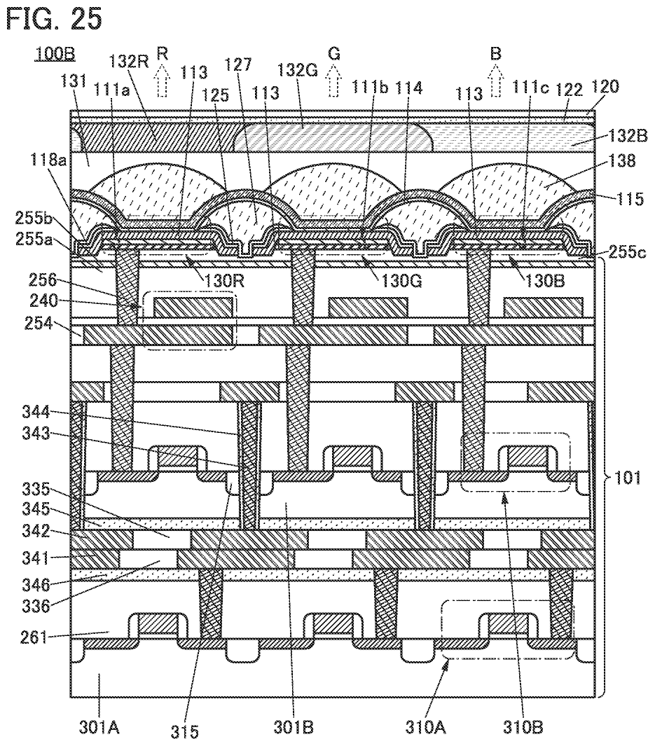

The display device 100B illustrated in FIG. 25 has a structure where a transistor 310A and a transistor 310B in each of which a channel is formed in a semiconductor substrate are stacked. Note that in the description of the display device below, portions similar to those of the above-mentioned display device are not described in some cases.

In the display device 100B, a substrate 301B provided with the transistor 310B, the capacitor 240, and the light-emitting devices is attached to a substrate 301A provided with the transistor 310A.

Here, an insulating layer 345 is preferably provided on the bottom surface of the substrate 301B. An insulating layer 346 is preferably provided over the insulating layer 261 provided over the substrate 301A. The insulating layer 345 and the insulating layer 346 are insulating layers functioning as protective layers and can inhibit diffusion of impurities into the substrate 301B and the substrate 301A. For each of the insulating layer 345 and the insulating layer 346, an inorganic insulating film that can be used for the protective layer 131 can be used.

The substrate 301B is provided with a plug 343 that penetrates the substrate 301B and the insulating layer 345. Here, an insulating layer 344 is preferably provided to cover the side surface of the plug 343. The insulating layer 344 functions as a protective layer and can inhibit diffusion of impurities from the plug 343 to the substrate 301B. For the insulating layer 344, an inorganic insulating film that can be used for the protective layer 131 can be used.

A conductive layer 342 is provided under the insulating layer 345 on the rear surface of the substrate 301B (the surface opposite to the substrate 120). The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343.

Over the substrate 301A, a conductive layer 341 is provided over the insulating layer 346. The conductive layer 341 is preferably provided to be embedded in an insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the planarity of a plane formed by the conductive layer 342 and the insulating layer 335 and a plane formed by the conductive layer 341 and the insulating layer 336 allows the conductive layer 341 and the conductive layer 342 to be bonded to each other favorably.

The conductive layer 341 and the conductive layer 342 are preferably formed using the same conductive material. For example, a metal film containing an element selected from Al, Cr, Cu, Ta, Ti, Mo, and W, a metal nitride film containing the above element as a component (a titanium nitride film, a molybdenum nitride film, or a tungsten nitride film), or the like can be used. Copper is particularly preferably used for the conductive layer 341 and the conductive layer 342. In that case, it is possible to employ Cu-to-Cu (copper-to-copper) direct bonding technique (a technique for achieving electrical continuity by connecting Cu (copper) pads).

### [Display Device 100C]

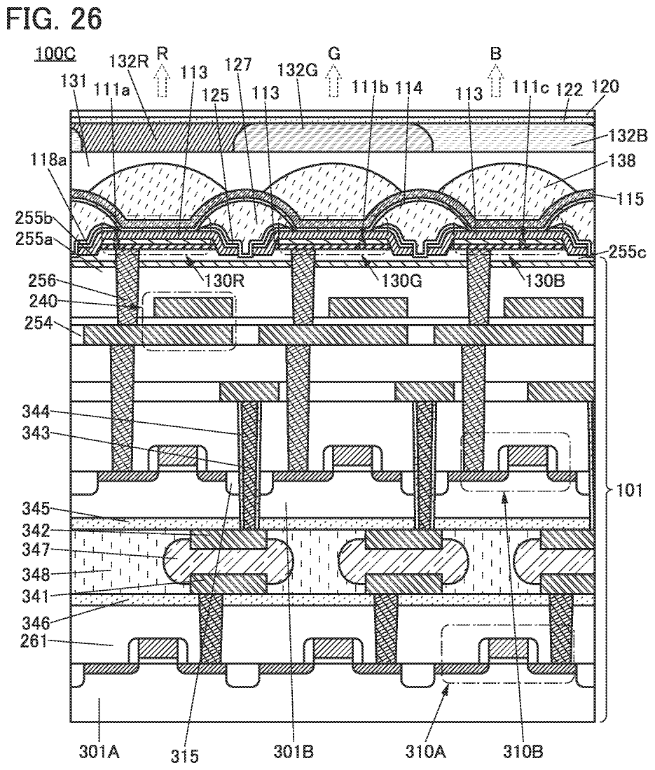

The display device 100C illustrated in FIG. 26 has a structure where the conductive layer 341 and the conductive layer 342 are bonded to each other through a bump 347.

As illustrated in FIG. 26, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. For another example, solder may be used for the bump 347. An adhesive layer 348 may be provided between the insulating layer 345 and the insulating layer 346. In the case where the bump 347 is provided, the insulating layer 335 and the insulating layer 336 illustrated in FIG. 25 may be omitted.

### [Display Device 100D]

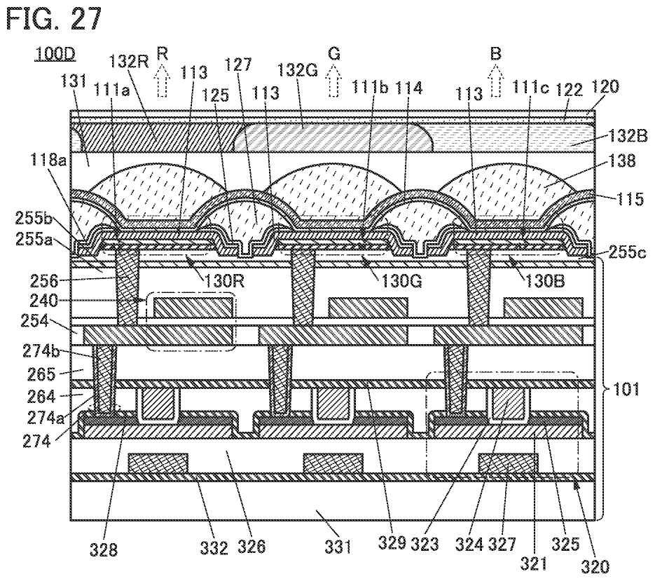

The display device 100D illustrated in FIG. 27 differs from the display device 100A mainly in a structure of a transistor.

A transistor 320 is a transistor that contains a metal oxide (also referred to as an oxide semiconductor) in a semiconductor layer where a channel is formed (i.e., an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 22A and FIG. 22B. A stacked-layer structure including the substrate 331 and components thereover up to the insulating layer 255c corresponds to the layer 101 including transistors in Embodiment 1. As the substrate 331, an insulating substrate or a semiconductor substrate can be used.

The insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer of the transistor 320. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide (also referred to as an oxide semiconductor) film having semiconductor characteristics. The pair of conductive layers 325 are provided over and in contact with the semiconductor layer 321 and function as a source electrode and a drain electrode of the transistor 320.

An insulating layer 328 is provided to cover the top surfaces and the side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water and hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325 and the top surface of the semiconductor layer 321, and the conductive layer 324 are embedded in the opening. The conductive layer 324 functions as a second gate electrode of the transistor 320, and the insulating layer 323 functions as a second gate insulating layer of the transistor 320.

The top surface of the conductive layer 324, the top surface of the insulating layer 323, and the top surface of the insulating layer 264 are subjected to planarization treatment so that their levels are equal to or substantially equal to each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water and hydrogen from the insulating layer 265 and the like into the transistor 320. As the insulating layer 329, an insulating film similar to the insulating layer 328 and the insulating layer 332 can be used.

A plug 274 electrically connected to one of the pair of conductive layers 325 is provided so as to be embedded in the insulating layer 265, the insulating layer 329, and the insulating layer 264. Here, the plug 274 preferably includes a conductive layer 274a that covers the side surface of an opening in the insulating layer 265, the insulating layer 329, the insulating layer 264, and the insulating layer 328 and part of the top surface of the conductive layer 325, and a conductive layer 274b in contact with the top surface of the conductive layer 274a. In that case, a conductive material in which hydrogen and oxygen are less likely to diffuse is preferably used for the conductive layer 274a.

### [Display Device 100E]

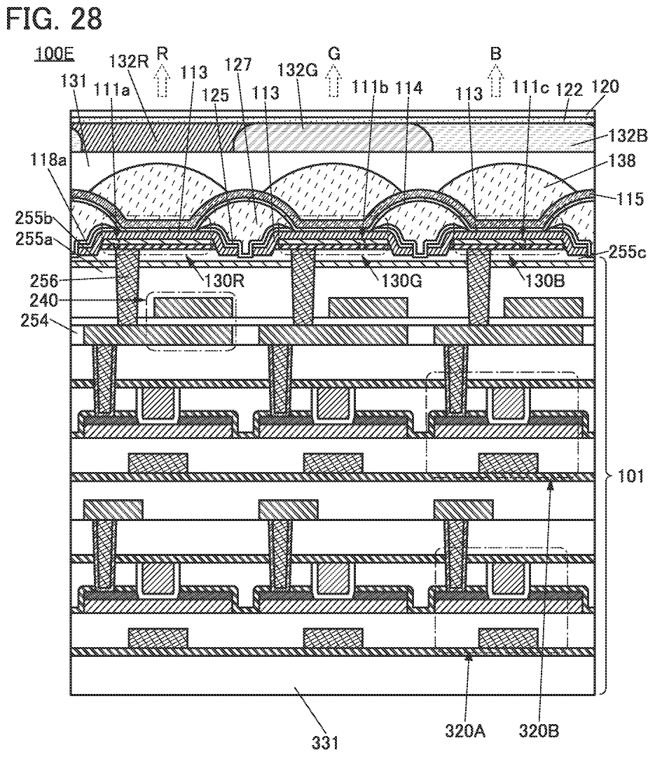

The display device 100E illustrated in FIG. 28 has a structure in which a transistor 320A and a transistor 320B each including an oxide semiconductor in a semiconductor where a channel is formed are stacked.

The description of the display device 100D can be referred to for the transistor 320A, the transistor 320B, and the components around them.

Although the structure where two transistors including an oxide semiconductor are stacked is described here, the present invention is not limited thereto. For example, three or more transistors may be stacked.

### [Display Device 100F]

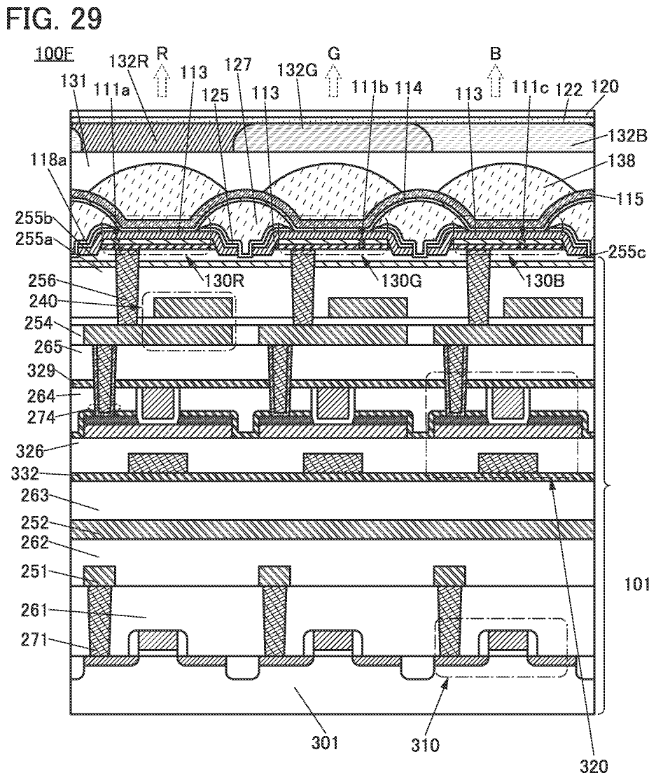

The display device 100F illustrated in FIG. 29 has a structure in which the transistor 310 whose channel is formed in the substrate 301 and the transistor 320 including a metal oxide in the semiconductor layer where the channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit (a gate line driver circuit or a source line driver circuit) for driving the pixel circuit. The transistor 310 and the transistor 320 can also be used as transistors included in a variety of circuits such as an arithmetic circuit and a memory circuit.

With such a structure, not only the pixel circuit but also the driver circuit and the like can be formed directly under the light-emitting devices; thus, the display device can be downsized as compared with the case where a driver circuit is provided around a display region.

### [Display Device 100G]

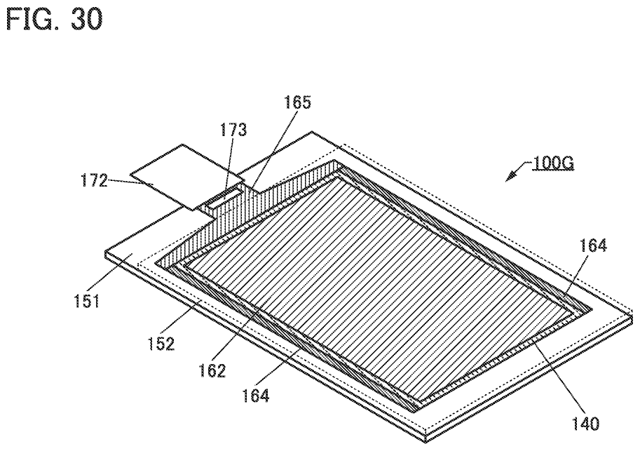

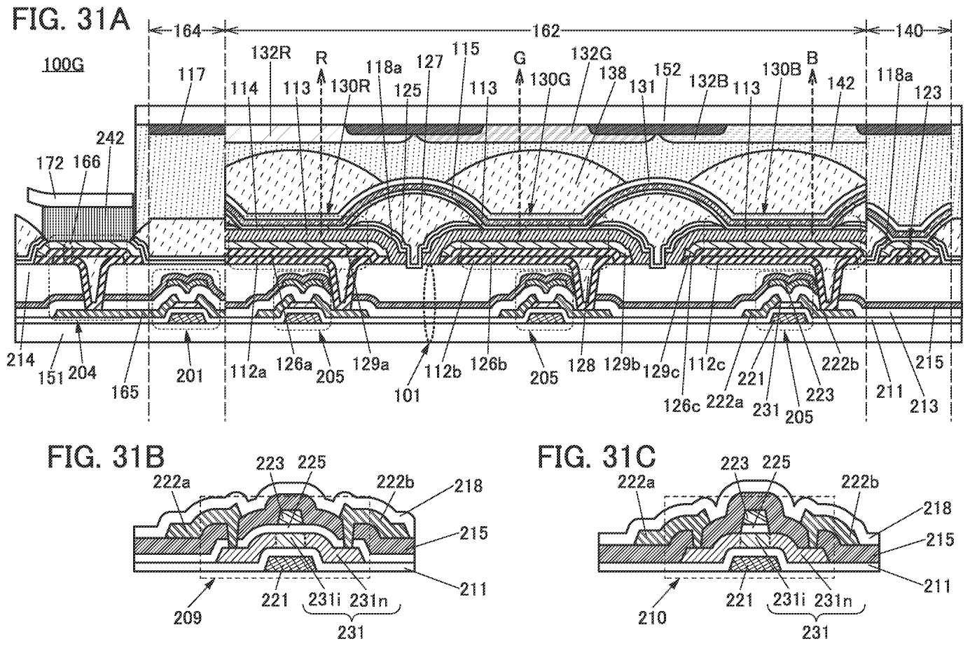

FIG. 30 is a perspective view of a display device 100G, and FIG. 31A is a cross-sectional view of the display device 100G.

In the display device 100G, a substrate 152 and a substrate 151 are attached to each other. In FIG. 30, the substrate 152 is denoted by a dashed line.

The display device 100G includes a display portion 162, the connection portion 140, a circuit 164, a wiring 165, and the like. FIG. 30 illustrates an example where an IC 173 and an FPC 172 are mounted on the display device 100G. Thus, the structure illustrated in FIG. 30 can be regarded as a display module including the display device 100G, the IC (integrated circuit), and the FPC.

The connection portion 140 is provided outside the display portion 162. The connection portion 140 can be provided along one or more sides of the display portion 162. The number of connection portions 140 can be one or more. FIG. 30 illustrates an example where the connection portion 140 is provided to surround the four sides of the display portion. A common electrode of a light-emitting device is electrically connected to a conductive layer in the connection portion 140, so that a potential can be supplied to the common electrode.

As the circuit 164, a scan line driver circuit can be used, for example.

The wiring 165 has a function of supplying a signal and power to the display portion 162 and the circuit 164. The signal and power are input to the wiring 165 from the outside through the FPC 172 or input to the wiring 165 from the IC 173.

FIG. 30 illustrates an example where the IC 173 is provided over the substrate 151 by a COG (Chip On Glass) method, a COF (Chip On Film) method, or the like. An IC including a scan line driver circuit, a signal line driver circuit, or the like can be used as the IC 173, for example. Note that the display device 100G and the display module are not necessarily provided with an IC. The IC may be mounted on the FPC by a COF method or the like.

FIG. 31A illustrates example cross sections of part of a region including the FPC 172, part of the circuit 164, part of the display portion 162, part of the connection portion 140, and part of a region including an end portion of the display device 100G.

In the display device 100G illustrated in FIG. 31A, a transistor 201, a transistor 205, the light-emitting device 130R emitting red light, the light-emitting device 130G emitting green light, the light-emitting device 130B emitting blue light, the lenses 138, the coloring layer 132R transmitting red light, the coloring layer 132G transmitting green light, the coloring layer 132B transmitting blue light, and the like are provided between the substrate 151 and the substrate 152.

The stacked-layer structure of each of the light-emitting device 130R, the light-emitting device 130G, and the light-emitting device 130B is the same as that illustrated in FIG. 1B except the structure of the pixel electrode. Embodiment 1 can be referred to for the details of the light-emitting devices.

The light-emitting device 130R includes a conductive layer 112a, a conductive layer 126a over the conductive layer 112a, and a conductive layer 129a over the conductive layer 126a. All of the conductive layer 112a, the conductive layer 126a, and the conductive layer 129a can be referred to as pixel electrodes, or one or two of them can be referred to as pixel electrodes.

The light-emitting device 130G includes the conductive layer 112b, the conductive layer 126b over the conductive layer 112b, and the conductive layer 129b over the conductive layer 126b.

The light-emitting device 130B includes a conductive layer 112c, a conductive layer 126c over the conductive layer 112c, and a conductive layer 129c over the conductive layer 126c.

The conductive layer 112a is connected to a conductive layer 222b included in the transistor 205 through an opening provided in the insulating layer 214. An end portion of the conductive layer 126a is positioned outward from an end portion of the conductive layer 112a. The end portion of the conductive layer 126a and an end portion of the conductive layer 129a are aligned or substantially aligned with each other. For example, a conductive layer functioning as a reflective electrode can be used as the conductive layer 112a and the conductive layer 126a, and a conductive layer functioning as a transparent electrode can be used as the conductive layer 129a.

Detailed description of the conductive layer 112b, the conductive layer 126b, and the conductive layer 129b of the light-emitting device 130G and the conductive layer 112c, the conductive layer 126c, and the conductive layer 129c of the light-emitting device 130B is omitted because these conductive layers are similar to the conductive layer 112a, the conductive layer 126a, and the conductive layer 129a of the light-emitting device 130R.

Depressed portions are formed in the conductive layer 112a, the conductive layer 112b, and the conductive layer 112c to cover the openings provided in the insulating layer 214. The layer 128 is embedded in the depression portions.

The layer 128 has a planarization function for the depressed portions of the conductive layer 112a, the conductive layer 112b, and the conductive layer 112c. The conductive layer 126a, the conductive layer 126b, and the conductive layer 126c electrically connected to the conductive layer 112a, the conductive layer 112b, and the conductive layer 112c, respectively, are provided over the conductive layer 112a, the conductive layer 112b, the conductive layer 112c, and the layer 128. Thus, regions overlapping with the depressed portions of the conductive layer 112a, the conductive layer 112b, and the conductive layer 112c can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 127 can be used, for example.

The top surfaces and the side surfaces of the conductive layer 126a, the conductive layer 126b, the conductive layer 126c, the conductive layer 129a, the conductive layer 129b, and the conductive layer 129c are covered with the first layers 113. Accordingly, regions provided with the conductive layer 126a, the conductive layer 126b, and the conductive layer 126c can be entirely used as the light-emitting regions of the light-emitting device 130R, the light-emitting device 130G, and the light-emitting device 130B, increasing the aperture ratio of the pixels.

The side surface and part of the top surface of the first layer 113 are covered with the insulating layer 125 and the insulating layer 127. The mask layer 118a is positioned between the first layer 113 and the insulating layer 125. The common layer 114 is provided over the first layer 113, the insulating layer 125, and the insulating layer 127, and the common electrode 115 is provided over the common layer 114. The common layer 114 and the common electrode 115 are each one continuous film provided to be shared by a plurality of light-emitting devices.

The protective layer 131 is provided over the light-emitting devices (the light-emitting device 130R, the light-emitting device 130G, and the light-emitting device 130B). The lenses 138 are provided over the protective layer 131 to include regions overlapping with at least the light-emitting devices. As described above, in the case where the lenses 138 are provided over the light-emitting devices, light emitted from the light-emitting devices can be extracted toward the coloring layers (the coloring layer 132R, the coloring layer 132G, and the coloring layer 132B) more efficiently than in the case where the lenses 138 are not provided. The coloring layer 132R, the coloring layer 132G, and the coloring layer 132B are provided on the surface of the substrate 152 that faces the substrate 151, and a light-blocking layer 117 is provided in a region overlapping with a portion between adjacent coloring layers. The substrate 152 is bonded onto the lenses 138 and the protective layer 131 with an adhesive layer 142 such that the coloring layer 132R, the coloring layer 132G, and the coloring layer 132B provided on the substrate face the light-emitting device 130R, the light-emitting device 130G, and the light-emitting device 130B, respectively. A solid sealing structure, a hollow sealing structure, or the like can be employed to seal the light-emitting devices. In FIG. 31A, a solid sealing structure is employed in which a space between the substrate 152 and the substrate 151 is filled with the adhesive layer 142. Alternatively, a hollow sealing structure in which the space is filled with an inert gas (e.g., nitrogen or argon) may be employed. Here, the adhesive layer 142 maybe provided not to overlap with the light-emitting devices. The space may be filled with a resin different from that of the frame-shaped adhesive layer 142.

The conductive layer 123 is provided over the insulating layer 214 in the connection portion 140. An example is described in which the conductive layer 123 has a stacked-layer structure of a conductive layer obtained by processing the same conductive film as the conductive layer 112a, the conductive layer 112b, and the conductive layer 112c; a conductive layer obtained by processing the same conductive film as the conductive layer 126a, the conductive layer 126b, and the conductive layer 126c; and a conductive layer obtained by processing the same conductive film as the conductive layer 129a, the conductive layer 129b, and the conductive layer 129c. An end portion of the conductive layer 123 is covered with the mask layer 118a, the insulating layer 125, and the insulating layer 127. The common layer 114 is provided over the conductive layer 123, and the common electrode 115 is provided over the common layer 114. The conductive layer 123 and the common electrode 115 are electrically connected to each other through the common layer 114. Note that the common layer 114 is not necessarily formed in the connection portion 140. In this case, the conductive layer 123 and the common electrode 115 are in direct contact with each other to be electrically connected to each other.

The display device 100G has a top-emission structure. Light emitted by the light-emitting device is emitted toward the substrate 152 side. For the substrate 152, a material having a high visible-light-transmitting property is preferably used. The pixel electrode contains a material that reflects visible light, and a counter electrode (the common electrode 115) contains a material that transmits visible light.

A stacked-layer structure including the substrate 151 and the components thereover up to the insulating layer 214 corresponds to the layer 101 including transistors in Embodiment 1.

The transistor 201 and the transistor 205 are formed over the substrate 151. These transistors can be fabricated using the same material in the same process.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material in which impurities such as water and hydrogen do not easily diffuse is preferably used for at least one of the insulating layers covering the transistors. In that case, the insulating layer can function as a barrier layer. Such a structure can effectively inhibit diffusion of impurities into the transistors from the outside and increase the reliability of the display device.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably has a function of an etching protective layer. In that case, a depressed portion can be inhibited from being formed in the insulating layer 214 at the time of processing the conductive layer 112a, the conductive layer 126a, the conductive layer 129a, or the like. Alternatively, a depressed portion may be formed in the insulating layer 214 at the time of processing the conductive layer 112a, the conductive layer 126a, the conductive layer 129a, or the like.

Each of the transistor 201 and the transistor 205 includes a conductive layer 221 functioning as a gate electrode, the insulating layer 211 functioning as a gate insulating layer, a conductive layer 222a and the conductive layer 222b functioning as a source electrode and a drain electrode, a semiconductor layer 231, the insulating layer 213 functioning as a gate insulating layer, and a conductive layer 223 functioning as a gate electrode. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device of this embodiment. For example, a planar transistor, a staggered transistor, an inverted staggered transistor, or the like can be used. A top-gate transistor structure or a bottom-gate transistor structure may be employed. Alternatively, gates may be provided above and below the semiconductor layer where a channel is formed.

The structure where the semiconductor layer where a channel is formed is held between two gates is used for the transistor 201 and the transistor 205. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case degradation of the transistor characteristics can be inhibited.

The semiconductor layer of the transistor preferably includes a metal oxide (also referred to as an oxide semiconductor). That is, a transistor including a metal oxide in its channel formation region (hereinafter, also referred to as an OS transistor) is preferably used for the display device of this embodiment.

As examples of the oxide semiconductor having crystallinity, a CAAC (C-Axis Aligned Crystalline)-OS, an nc (nanocrystalline)-OS, and the like can be given.

Alternatively, a transistor containing silicon in its channel formation region (a Si transistor) may be used. As examples of silicon, single crystal silicon, polycrystalline silicon, amorphous silicon, and the like can be given. In particular, a transistor containing low-temperature polysilicon (LTPS) in its semiconductor layer (hereinafter also referred to as an LTPS transistor) is preferably used. The LTPS transistor has high field-effect mobility and favorable frequency characteristics.

With the use of Si transistors such as LTPS transistors, a circuit required to be driven at a high frequency (e.g., a source driver circuit) can be formed on the same substrate as the display portion. Thus, external circuits mounted on the display device can be simplified, and parts costs and mounting costs can be reduced.

An OS transistor has much higher field-effect mobility than a transistor containing amorphous silicon. In addition, the OS transistor has an extremely low leakage current between a source and a drain in an off state (hereinafter also referred to as off-state current), and electric charge accumulated in a capacitor that is connected in series to the transistor can be retained for a long period. Furthermore, power consumption of the display device can be reduced with the use of an OS transistor.

To increase the emission luminance of the light-emitting device included in the pixel circuit, the amount of current fed through the light-emitting device needs to be increased. For this, it is necessary to increase the source-drain voltage of a driving transistor included in the pixel circuit. Since an OS transistor has a higher breakdown voltage between the source and the drain than a Si transistor, a high voltage can be applied between the source and the drain of the OS transistor. Accordingly, when an OS transistor is used as the driving transistor included in the pixel circuit, the amount of current flowing through the light-emitting device can be increased, so that the emission luminance of the light-emitting device can be increased.

When transistors operate in a saturation region, a change in source-drain current with respect to a change in gate-source voltage can be smaller in an OS transistor than in a Si transistor. Accordingly, when an OS transistor is used as the driving transistor in the pixel circuit, the amount of current flowing between the source and the drain can be set minutely by a change in gate-source voltage; hence, the amount of current flowing through the light-emitting device can be controlled. Accordingly, the number of gray levels in the pixel circuit can be increased.

Regarding saturation characteristics of current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through light-emitting devices even when the current-voltage characteristics of the EL devices vary, for example. In other words, when the OS transistor operates in the saturation region, the source-drain current hardly changes with an increase in the source-drain voltage; hence, the emission luminance of the light-emitting device can be stable.

As described above, with the use of an OS transistor as a driving transistor included in the pixel circuit, it is possible to achieve “inhibition of black-level degradation”, “increase in emission luminance”, “increase in gray level”, “inhibition of variation in light-emitting devices”, and the like.

The semiconductor layer preferably contains indium, M (M is one or more selected from gallium, aluminum, silicon, boron, yttrium, tin, antimony, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more selected from aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Alternatively, an oxide containing indium (In), aluminum (Al), and zinc (Zn) (also referred to as IAZO) is preferably used for the semiconductor layer. Alternatively, an oxide containing indium (In), aluminum (Al), gallium (Ga), and zinc (Zn) (also referred to as IAGZO) is preferably used for the semiconductor layer.

When the semiconductor layer is an In-M-Zn oxide, the atomic ratio of In is preferably higher than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30% of an intended atomic ratio.

For example, when the atomic ratio is described as In:Ga:Zn=4:2:3 or a composition in the neighborhood thereof, the case is included where the atomic ratio of Ga is greater than or equal to 1 and less than or equal to 3 and the atomic ratio of Zn is greater than or equal to 2 and less than or equal to 4 with the atomic ratio of In being 4. When the atomic ratio is described as In:Ga:Zn=5:1:6 or a composition in the neighborhood thereof, the case is included where the atomic ratio of Ga is greater than 0.1 and less than or equal to 2 and the atomic ratio of Zn is greater than or equal to 5 and less than or equal to 7 with the atomic ratio of In being 5. When the atomic ratio is described as In:Ga:Zn=1:1:1 or a composition in the neighborhood thereof, the case is included where the atomic ratio of Ga is greater than 0.1 and less than or equal to 2 and the atomic ratio of Zn is greater than 0.1 and less than or equal to 2 with the atomic ratio of In being 1.

The transistor included in the circuit 164 and the transistor included in the display portion 162 may have the same structure or different structures. One structure or two or more types of structures may be employed for a plurality of transistors included in the circuit 164. Similarly, one structure or two or more types of structures may be employed for a plurality of transistors included in the display portion 162.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display device can have low power consumption and high driving capability. Note that a structure where an LTPS transistor and an OS transistor are used in combination is referred to as LTPO in some cases. Note that as a further suitable example, a structure can be given where an OS transistor is used as, for example, a transistor functioning as a switch for controlling conduction and non-conduction between wirings and an LTPS transistor is used as, for example, a transistor for controlling current.

For example, one of the transistors included in the display portion 162 functions as a transistor for controlling current flowing through the light-emitting device and can be referred to as a driving transistor. One of a source and a drain of the driving transistor is electrically connected to the pixel electrode of the light-emitting device. An LTPS transistor is preferably used as the driving transistor. In that case, the amount of current flowing through the light-emitting device can be increased in the pixel circuit.

Another transistor included in the display portion 162 functions as a switch for controlling selection and non-selection of the pixel and can be referred to as a selection transistor. A gate of the selection transistor is electrically connected to a gate line, and one of a source and a drain thereof is electrically connected to a source line (signal line). An OS transistor is preferably used as the selection transistor. In that case, the gray level of the pixel can be maintained even with an extremely low frame frequency (e.g., lower than or equal to 1 fps); thus, power consumption can be reduced by stopping the driver in displaying a still image.

As described above, the display device of one embodiment of the present invention can have all of a high aperture ratio, high resolution, high display quality, and low power consumption.

Note that the display device of one embodiment of the present invention has a structure including the OS transistor and the light-emitting device having an MML (metal maskless) structure. With this structure, the leakage current that might flow through the transistor and the leakage current that might flow between adjacent light-emitting devices (also referred to as lateral leakage current, side leakage current, or the like) can be extremely low. With the structure, a viewer can notice any one or more of the image crispness, the image sharpness, a high chroma, and a high contrast ratio in an image displayed on the display device. When the leakage current that would flow through the transistor and the lateral leakage current between the light-emitting devices are extremely low, light leakage that might occur in black display (what is called black-level degradation) or the like can be minimized.

FIG. 31B and FIG. 31C illustrate other structure examples of transistors.

A transistor 209 and a transistor 210 each include the conductive layer 221 functioning as a gate electrode, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as agate electrode, and the insulating layer 215 covering the conductive layer 223. The insulating layer 211 is positioned between the conductive layer 221 and the channel formation region 231i. The insulating layer 225 is positioned at least between the conductive layer 223 and the channel formation region 231i. Furthermore, an insulating layer 218 covering the transistor may be provided.

FIG. 31B illustrates an example of the transistor 209 in which the insulating layer 225 covers the top surface and the side surface of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source electrode, and the other functions as a drain electrode.

Meanwhile, in the transistor 210 illustrated in FIG. 31C, the insulating layer 225 overlaps with the channel formation region 231i of the semiconductor layer 231 and does not overlap with the low-resistance regions 231n. The structure illustrated in FIG. 31C can be formed by processing the insulating layer 225 with the conductive layer 223 as a mask, for example. In FIG. 31C, the insulating layer 215 is provided to cover the insulating layer 225 and the conductive layer 223, and the conductive layer 222a and the conductive layer 222b are connected to the low-resistance regions 231n through the openings in the insulating layer 215.

In FIG. 31A, a connection portion 204 is provided in a region of the substrate 151 where the substrate 152 does not overlap. In the connection portion 204, the wiring 165 is electrically connected to the FPC 172 through a conductive layer 166 and a connection layer 242. An example is described in which the conductive layer 166 has a stacked-layer structure of a conductive layer obtained by processing the same conductive film as the conductive layer 112a, the conductive layer 112b, and the conductive layer 112c; a conductive layer obtained by processing the same conductive film as the conductive layer 126a, the conductive layer 126b, and the conductive layer 126c; and a conductive layer obtained by processing the same conductive film as the conductive layer 129a, the conductive layer 129b, and the conductive layer 129c. The conductive layer 166 is exposed on the top surface of the connection portion 204. Thus, the connection portion 204 and the FPC 172 can be electrically connected to each other through the connection layer 242.

The light-blocking layer 117 is preferably provided on the surface of the substrate 152 that faces the substrate 151. The light-blocking layer 117 can be provided between adjacent light-emitting devices, in the connection portion 140, and in the circuit 164, for example. A variety of optical members can be provided on the outer side of the substrate 152 (the side opposite to the substrate 151).

The material that can be used for the substrate 120 illustrated in FIG. 1B and the like can be used for each of the substrate 151 and the substrate 152.

The material that can be used for the resin layer 122 illustrated in FIG. 1B and the like can be used for the adhesive layer 142.

As the connection layer 242, an anisotropic conductive film (ACF), an anisotropic conductive paste (ACP), or the like can be used.

### [Display Device 100H]

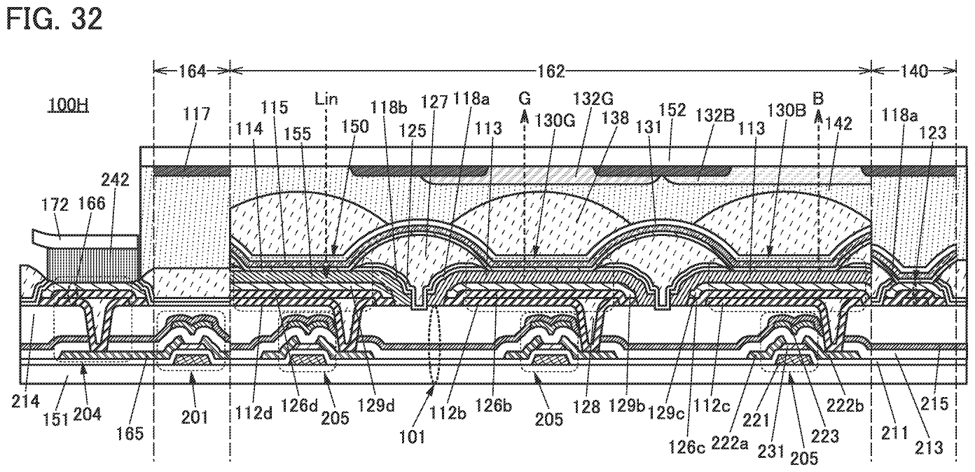

A display device 100H illustrated in FIG. 32 is different from the display device 100G mainly in including the light-receiving device 150.

The light-receiving device 150 includes a conductive layer 112d, a conductive layer 126d over the conductive layer 112d, and a conductive layer 129d over the conductive layer 126d.

The conductive layer 112d is connected to the conductive layer 222b included in the transistor 205 through an opening provided in the insulating layer 214.

The top surface and the side surface of the conductive layer 126d and the top surface and the side surface of the conductive layer 129d are covered with the second layer 155. The second layer 155 includes at least an active layer.

The side surface and part of the top surface of the second layer 155 are covered with the insulating layer 125 and the insulating layer 127. The mask layer 118b is positioned between the second layer 155 and the insulating layer 125. The common layer 114 is provided over the second layer 155, the insulating layer 125, and the insulating layer 127, and the common electrode 115 is provided over the common layer 114. The common layer 114 and the common electrode 115 are each one continuous film provided to be shared by the light-receiving device and the light-emitting devices.

The lens 138 is provided over the light-receiving device 150 to include a region overlapping with at least the light-receiving device. As described above, in the case where the lens 138 is provided over the light-receiving device, light (the light Lin) incident from the outside can enter the light-receiving device 150 more efficiently than in the case where the lens 138 is not provided. That is, the display device of one embodiment of the present invention can include a light-receiving device having high light detection performance.

The display device 100H can employ any of the pixel layouts that are described in Embodiment 3 with reference to FIG. 21A to FIG. 21J, for example. Embodiment 1 and Embodiment 6 can be referred to for the details of the display device that includes the light-receiving device.

This embodiment can be combined with any of the other embodiments as appropriate.

### Embodiment 5

In this embodiment, light-emitting devices that can be used for the display device of one embodiment of the present invention will be described.

In this specification and the like, a structure where emission colors (e.g., blue (B), green (G), and red (R)) are separately formed for light-emitting devices is referred to as an SBS structure in some cases.

The emission color of the light-emitting device can be red, green, blue, cyan, magenta, yellow, white, or the like. Furthermore, the color purity can be increased when the light-emitting device has a microcavity structure.

### [Light-Emitting Device]

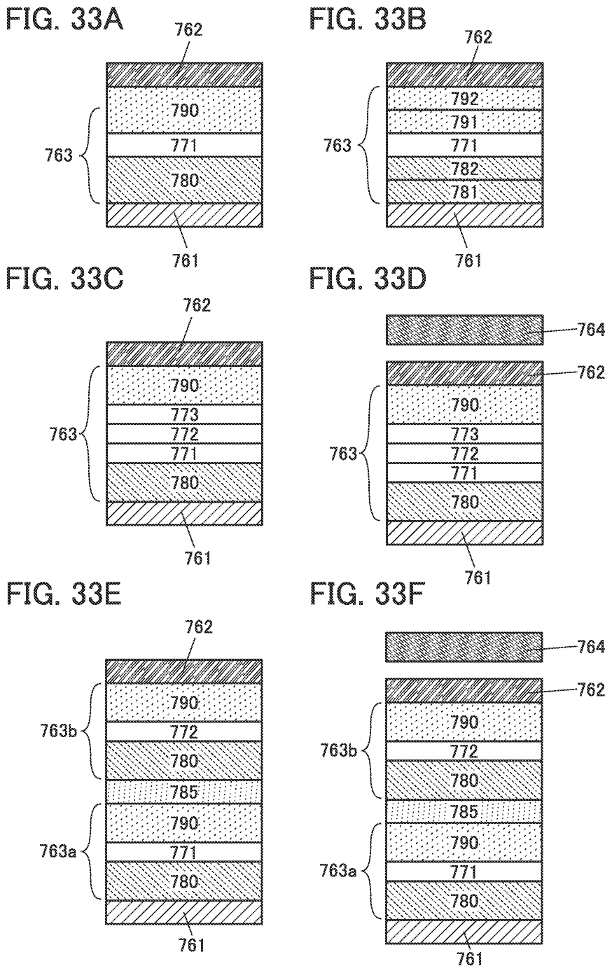

As illustrated in FIG. 33A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance with a high hole-injection property (a hole-injection layer), a layer containing a substance with a high hole-transport property (a hole-transport layer), and a layer containing a substance with a high electron-blocking property (an electron-blocking layer). Furthermore, the layer 790 includes one or more of a layer containing a substance with a high electron-injection property (an electron-injection layer), a layer containing a substance with a high electron-transport property (an electron-transport layer), and a layer containing a substance with a high hole-blocking property (a hole-blocking layer). In the case where the lower electrode 761 is a cathode and the upper electrode 762 is an anode, the above structures of the layer 780 and the layer 790 are replaced with each other.

The structure including the layer 780, the light-emitting layer 771, and the layer 790, which is provided between a pair of electrodes, can function as a single light-emitting unit, and the structure in FIG. 33A is referred to as a single structure in this specification.

FIG. 33B is a variation example of the EL layer 763 included in the light-emitting device illustrated in FIG. 33A. Specifically, the light-emitting device illustrated in FIG. 33B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected to the light-emitting layer 771, and the efficiency of the recombination of carriers in the light-emitting layer 771 can be increased.

Note that structures in which a plurality of light-emitting layers (the light-emitting layer 771, a light-emitting layer 772, and a light-emitting layer 773) are provided between the layer 780 and the layer 790 as illustrated in FIG. 33C and FIG. 33D are variations of the single structure.

A structure where a plurality of light-emitting units (an EL layer 763a and an EL layer 763b) are connected in series with a charge-generation layer 785 therebetween as illustrated in FIG. 33E and FIG. 33F is referred to as a tandem structure in this specification. Note that the tandem structure may be referred to as a stack structure. The tandem structure enables a light-emitting device capable of high-luminance light emission.

In FIG. 33C and FIG. 33D, light-emitting substances that emit light of the same color, or moreover, the same light-emitting substance may be used for the light-emitting layer 771, the light-emitting layer 772, and the light-emitting layer 773. For example, a light-emitting substance emitting blue light may be used for the light-emitting layer 771, the light-emitting layer 772, and the light-emitting layer 773. A color conversion layer may be provided as a layer 764 illustrated in FIG. 33D.

Alternatively, light-emitting substances emitting light of different colors may be used for the light-emitting layer 771, the light-emitting layer 772, and the light-emitting layer 773. White light emission can be obtained when the light-emitting layer 771, the light-emitting layer 772, and the light-emitting layer 773 emit light of complementary colors. A color filter (also referred to as a coloring layer) may be provided as the layer 764 illustrated in FIG. 33D. When white light passes through the color filter, light of a desired color can be obtained.

The light-emitting device emitting white light preferably contains two or more kinds of light-emitting substances. To obtain white light emission, two or more light-emitting substances are selected such that their emission colors are complementary. For example, when an emission color of a first light-emitting layer and an emission color of a second light-emitting layer are complementary colors, the light-emitting device can be configured to emit white light as a whole. The same applies to a light-emitting device including three or more light-emitting layers.

In FIG. 33E and FIG. 33F, light-emitting substances emitting light of the same color, or moreover, the same light-emitting substance may be used for the light-emitting layer 771 and the light-emitting layer 772. Alternatively, light-emitting substances emitting light of different colors may be used for the light-emitting layer 771 and the light-emitting layer 772. White light emission can be obtained when the light-emitting layer 771 and the light-emitting layer 772 emit light of complementary colors. FIG. 33F illustrates an example where the layer 764 is further provided. One or both of a color conversion layer and a color filter (coloring layer) can be used as the layer 764.

In FIG. 33C, FIG. 33D, FIG. 33E, and FIG. 33F, each of the layer 780 and the layer 790 may independently have a stacked-layer structure of two or more layers as illustrated in FIG. 33B.

Next, materials that can be used for the light-emitting device will be described.

A conductive film transmitting visible light is used as the electrode through which light is extracted, which is either the lower electrode 761 or the upper electrode 762. A conductive film reflecting visible light is preferably used as the electrode through which light is not extracted. In the case where the display device includes a light-emitting device emitting infrared light, a conductive film transmitting visible light and infrared light is preferably used as the electrode through which light is extracted, and a conductive film reflecting visible light and infrared light is preferably used as the electrode through which light is not extracted.

A conductive film transmitting visible light may be used as the electrode through which light is not extracted. In that case, the electrode is preferably placed between a reflective layer and the EL layer 763. In other words, light emitted from the EL layer 763 may be reflected by the reflective layer to be extracted from the display device.

As a material that forms the pair of electrodes of the light-emitting device, a metal, an alloy, an electrically conductive compound, a mixture thereof, and the like can be used as appropriate. Specific examples include indium tin oxide (In—Sn oxide, also referred to as ITO), In—Si—Sn oxide (also referred to as ITSO), indium zinc oxide (In—Zn oxide), In—W—Zn oxide, an alloy containing aluminum (an aluminum alloy) such as an alloy of aluminum, nickel, and lanthanum (Al—Ni—La), and an alloy of silver, palladium, and copper (Ag—Pd—Cu, also referred to as APC). In addition, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use an element belonging to Group 1 or Group 2 in the periodic table, which is not described above (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

The light-emitting devices preferably employ a micro optical resonator (microcavity) structure. Therefore, one of the pair of electrodes of the light-emitting device preferably includes an electrode having properties of transmitting and reflecting visible light (a semi-transmissive and semi-reflective electrode), and the other preferably includes an electrode having a property of reflecting visible light (a reflective electrode). When the light-emitting device has a microcavity structure, light obtained from the light-emitting layer can be resonated between the electrodes, whereby light emitted from the light-emitting device can be intensified.

Note that the semi-transmissive and semi-reflective electrode can have a stacked-layer structure of a reflective electrode and an electrode having a visible-light-transmitting property (also referred to as a transparent electrode).

The light transmittance of the transparent electrode is higher than or equal to 40%. For example, an electrode having a visible light (light with a wavelength greater than or equal to 400 nm and less than 750 nm) transmittance higher than or equal to 40% is preferably used in the light-emitting device. The semi-transmissive and semi-reflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity less than or equal to 1×10⁻² Ωcm.

Either a low molecular compound or a high molecular compound can be used in the light-emitting device, and an inorganic compound may be included. Each layer included in the light-emitting device can be formed by any of the following methods: an evaporation method (including a vacuum evaporation method), a transfer method, a printing method, an ink-jet method, a coating method, and the like.

The light-emitting layer can contain one or more kinds of light-emitting substances. As the light-emitting substance, a substance exhibiting an emission color of blue, violet, bluish violet, green, yellowish green, yellow, orange, red, or the like is used as appropriate. Alternatively, as the light-emitting substance, a substance emitting near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material and an assist material) in addition to the light-emitting substance (a guest material). As one or more kinds of organic compounds, one or both of a substance with a high hole-transport property (a hole-transport material) and a substance with a high electron-transport property (an electron-transport material) can be used. Alternatively, as one or more kinds of organic compounds, a bipolar material or a TADF material may be used.

The light-emitting layer preferably contains a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination is selected to form an exciplex that exhibits light emission whose wavelength overlaps with the wavelength of the lowest-energy-side absorption band of the light-emitting substance, energy can be transferred smoothly and light emission can be obtained efficiently. With this structure, high efficiency, low-voltage driving, and a long lifetime of the light-emitting device can be achieved at the same time.

In addition to the light-emitting layer, the EL layer 763 may further include layers containing a substance with a high hole-injection property, a substance with a high hole-transport property, a hole-blocking material, a substance with a high electron-transport property, a substance with a high electron-injection property, an electron-blocking material, a substance with a bipolar property (a substance with a high electron-transport property and a high hole-transport property), and the like.

The hole-injection layer injects holes from the anode to the hole-transport layer and contains a material with a high hole-injection property. Examples of the material with a high hole-injection property include an aromatic amine compound and a composite material containing a hole-transport material and an acceptor material (electron-accepting material).

As the hole-transport material, a later-described material with a high hole-transport property that can be used for the hole-transport layer can be used.

As the acceptor material, an oxide of a metal belonging to any of Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable since it is stable in the air, has a low hygroscopic property, and is easy to handle. Alternatively, an organic acceptor material containing fluorine can be used. Alternatively, an organic acceptor material such as a quinodimethane derivative, a chloranil derivative, or a hexaazatriphenylene derivative can be used. As the material with a high hole-injection property, a mixed material formed by mixing the above oxide of a metal belonging to any of Group 4 to Group 8 of the periodic table (typically, molybdenum oxide) and an organic material may be used.

The hole-transport layer transports holes injected from the anode by the hole-injection layer, to the light-emitting layer. The hole-transport layer contains a hole-transport material. As the hole-transport material, a substance having a hole mobility higher than or equal to 1×10⁻⁶ cm²/Vs is preferable. Note that other substances can also be used as long as the substances have a hole-transport property higher than an electron-transport property. As the hole-transport material, a material with a high hole-transport property, such as a π-electron rich heteroaromatic compound (e.g., a carbazole derivative, a thiophene derivative, or a furan derivative) or an aromatic amine (a compound having an aromatic amine skeleton), is preferable.

The electron-transport layer transports electrons injected from the cathode by the electron-injection layer, to the light-emitting layer. The electron-transport layer contains an electron-transport material. As the electron-transport material, a substance having an electron mobility higher than or equal to 1×10⁻⁶ cm²/Vs is preferable. Note that other substances can also be used as long as the substances have an electron-transport property higher than a hole-transport property. As the electron-transport material, any of the following materials with a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

The electron-injection layer injects electrons from the cathode to the electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The difference between the LUMO level of the material with a high electron-injection property and the work function value of the material used for the cathode is preferably small (specifically, smaller than or equal to 0.5 eV).

The electron-injection layer can be formed using, for example, an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate. The electron-injection layer may have a stacked-layer structure of two or more layers. The stacked-layer structure can be, for example, a structure where lithium fluoride is used for the first layer and ytterbium is used for the second layer.

The electron-injection layer may contain an electron-transport material. For example, a compound having an unshared electron pair and an electron deficient heteroaromatic ring can be used as the electron-transport material. Specifically, a compound having at least one of a pyridine ring, a diazine ring (a pyrimidine ring, a pyrazine ring, or a pyridazine ring), and a triazine ring can be used.

Note that the lowest unoccupied molecular orbital (LUMO) level of the organic compound having an unshared electron pair is preferably higher than or equal to −3.6 eV and lower than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2′-(1,3-phenylene)bis[9-phenyl-1,10-phenanthroline] (abbreviation: mPPhen2P), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

In the case of fabricating a tandem light-emitting device, a charge-generation layer (also referred to as an intermediate layer) is provided between two light-emitting units. The intermediate layer has a function of injecting electrons into one of the two light-emitting units and injecting holes to the other when voltage is applied between the pair of electrodes.

For the charge-generation layer, for example, a material that can be used for the electron-injection layer, such as lithium, can be suitably used. For the charge-generation layer, for example, a material that can be used for the hole-injection layer can be suitably used. As the charge-generation layer, a layer containing a hole-transport material and an acceptor material (electron-accepting material) can be used. As the charge-generation layer, a layer containing an electron-transport material and a donor material can be used. Forming such a charge-generation layer can inhibit an increase in the driving voltage that would be caused by stacking light-emitting units.

This embodiment can be combined with any of the other embodiments as appropriate.

### Embodiment 6

In this embodiment, a light-receiving device that can be used for the display device of one embodiment of the present invention and a display device having a light detection function will be described.

For example, a pn or pin photodiode can be used as the light-receiving device. The light-receiving device functions as a photoelectric conversion device (also referred to as a photoelectric conversion element) that detects light entering the light-receiving device and generates electric charge. The amount of electric charge generated from the light-receiving device depends on the amount of light entering the light-receiving device.

It is particularly preferable to use an organic photodiode that includes a layer containing an organic compound, as the light-receiving device. An organic photodiode, which is easily made thin, lightweight, and large in area and has a high degree of freedom for shape and design, can be used in a variety of display devices.

### [Light-Receiving Device]

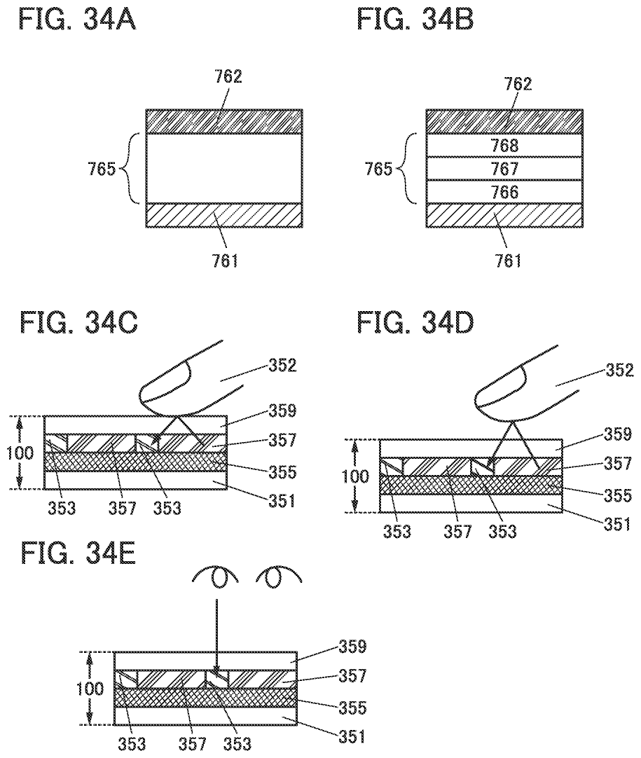

As illustrated in FIG. 34A, the light-receiving device includes a layer 765 between a pair of electrodes (the lower electrode 761 and the upper electrode 762). The layer 765 includes at least one active layer, and may further include another layer.

FIG. 34B shows a variation example of the EL layer 765 included in the light-receiving device illustrated in FIG. 34A. Specifically, the light-receiving device illustrated in FIG. 34B includes a layer 766 over the lower electrode 761, an active layer 767 over the layer 766, a layer 768 over the active layer 767, and the upper electrode 762 over the layer 768.

The active layer 767 functions as a photoelectric conversion layer.

In the case where the lower electrode 761 is an anode and the upper electrode 762 is a cathode, the layer 766 includes one or both of a hole-transport layer and an electron-blocking layer. The layer 768 includes one or both of an electron-transport layer and a hole-blocking layer. In the case where the lower electrode 761 is a cathode and the upper electrode 762 is an anode, the above structures of the layer 766 and the layer 768 are replaced with each other.

Here, the display device of one embodiment of the present invention may include a layer common to the light-receiving device and the light-emitting device (the layer can be regarded as a continuous layer shared by the light-receiving device and the light-emitting device). Such a layer may have different functions in the light-emitting device and the light-receiving device. In this specification, the name of a component is based on its function in the light-emitting device in some cases. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. A layer common to the light-receiving device and the light-emitting device may have the same function in both the light-emitting device and the light-receiving device. For example, the hole-transport layer functions as a hole-transport layer in both the light-emitting device and the light-receiving device, and the electron-transport layer functions as an electron-transport layer in both the light-emitting device and the light-receiving device.

Next, materials that can be used for the light-receiving device will be described.

Either a low molecular compound or a high molecular compound can be used for the light-receiving device, and an inorganic compound may be contained. Each layer included in the light-receiving device can be formed by an evaporation method (including a vacuum evaporation method), a transfer method, a printing method, an ink-jet method, a coating method, or the like.

The active layer included in the light-receiving device includes a semiconductor. Examples of the semiconductor include an inorganic semiconductor such as silicon and an organic semiconductor including an organic compound. This embodiment describes an example where an organic semiconductor is used as the semiconductor included in the active layer. An organic semiconductor is preferably used, in which case the light-emitting layer and the active layer can be formed by the same method (e.g., a vacuum evaporation method) and thus the same manufacturing apparatus can be used.

Examples of an n-type semiconductor material included in the active layer include electron-accepting organic semiconductor materials such as fullerene (e.g., C₆₀ and C₇₀) and fullerene derivatives. Examples of the fullerene derivative include [6,6]-Phenyl-C₇₁-butyric acid methyl ester (abbreviation: PC70BM), [6,6]-Phenyl-C₆₁-butyric acid methyl ester (abbreviation: PC60BM), and 1′,1″,4′,4″-Tetrahydro-di[1,4]methanonaphthaleno[1,2:2′,3′,56,60:2″,3″ ][5,6]fullerene-C₆₀ (abbreviation: ICBA).

Other examples of an n-type semiconductor material include perylenetetracarboxylic acid derivatives such as N,N-dimethyl-3,4,9,10-perylenetetracarboxylic diimide (abbreviation: Me-PTCDI) and 2,2′-(5,5′-(thieno[3,2-b]thiophene-2,5-diyl)bis(thiophene-5,2-diyl))bis(methan-1-yl-1-ylidene)dimalononitrile (abbreviation: FT2TDMN).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper(II) phthalocyanine (CuPc), tetraphenyldibenzoperiflanthene (DBP), zinc phthalocyanine (ZnPc), tin phthalocyanine (SnPc), quinacridone, and rubrene.

Other examples of a p-type semiconductor material include a carbazole derivative, a thiophene derivative, a furan derivative, and a compound having an aromatic amine skeleton. Other examples of a p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of the same kind, which have molecular orbital energy levels close to each other, can increase the carrier-transport property.

For the active layer, a high molecular compound such as Poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

For example, the active layer is preferably formed by co-evaporation of an n-type semiconductor and a p-type semiconductor. Alternatively, the active layer may be formed by stacking an n-type semiconductor and a p-type semiconductor.

The active layer may contain a mixture of three or more kinds of materials. For example, a third material may be mixed with an n-type semiconductor material and a p-type semiconductor material in order to extend the wavelength range of the light to be detected. The third material may be a low molecular compound or a high molecular compound.

In addition to the active layer, the light-receiving device may further include a layer containing a substance with a high hole-transport property, a substance with a high electron-transport property, a substance with a bipolar property (a substance with a high electron-transport property and a high hole-transport property), or the like. Without limitation to the above, the light-receiving device may further include a layer containing a substance with a high hole-injection property, a hole-blocking material, a substance with a high electron-injection property, an electron-blocking material, or the like. Layers other than the active layer included in the light-receiving device can be formed using a material that can be used for the light-emitting device.

As the hole-transport material or the electron-blocking material, a high molecular compound such as poly(3,4-ethylenedioxythiophene)/poly(styrenesulfonic acid) (PEDOT/PSS), or an inorganic compound such as molybdenum oxide or copper iodide (CuI) can be used, for example. As the electron-transport material or the hole-blocking material, an inorganic compound such as zinc oxide (ZnO), or an organic compound such as polyethylenimine ethoxylate (PEIE) can be used. The light-receiving device may include a mixed film of PEIE and ZnO, for example.

### [Display Device Having Light Detection Function]

In the display device of one embodiment of the present invention, the light-emitting devices are arranged in a matrix in a display portion, and an image can be displayed on the display portion. Furthermore, the light-receiving devices are arranged in a matrix in the display portion, and the display portion has one or both of an image capturing function and a sensing function in addition to an image displaying function. The display portion can be used as an image sensor or a touch sensor. That is, by detecting light with the display portion, an image can be captured or the proximity or contact of a target (e.g., a finger, a hand, or a pen) can be detected.

Furthermore, in the display device of one embodiment of the present invention, the light-emitting devices can be used as a light source of the sensor. In the display device of one embodiment of the present invention, when an object reflects (or scatters) light emitted by the light-emitting device included in the display portion, the light-receiving device can detect reflected light (or scattered light); thus, image capturing or touch detection is possible even in a dark place.

Accordingly, a light-receiving portion and a light source do not need to be provided separately from the display device; hence, the number of components of an electronic device can be reduced. For example, a biometric authentication device, a capacitive touch panel for scroll operation, or the like is not necessarily provided separately from the electronic device. Thus, with the use of the display device of one embodiment of the present invention, the electronic device can be provided with reduced manufacturing cost.

Specifically, the display device of one embodiment of the present invention includes a light-emitting device and a light-receiving device in a pixel. In the display device of one embodiment of the present invention, an organic EL device is used as the light-emitting device, and an organic photodiode is used as the light-receiving device. The organic EL device and the organic photodiode can be formed over the same substrate. Thus, the organic photodiode can be incorporated in the display device that includes the organic EL device.

In the display device including the light-emitting device and the light-receiving device in the pixel, the pixel has a light-receiving function; thus, the display device can detect the contact or proximity of an object while displaying an image. For example, all the subpixels included in the display device can display an image; alternatively, some of the subpixels can emit light as a light source, and the other subpixels can display an image.

In the case where the light-receiving device is used as an image sensor, the display device can capture an image with the use of the light-receiving device. For example, the display device of this embodiment can be used as a scanner.

For example, image capturing for personal authentication with the use of a fingerprint, a palm print, the iris, the shape of a blood vessel (including the shape of a vein and the shape of an artery), a face, or the like can be performed using the image sensor.

For example, an image of the periphery, surface, or inside (e.g., fundus) of an eye of a user of a wearable device can be captured using the image sensor. Therefore, the wearable device can have a function of detecting one or more selected from blinking, movement of an iris, and movement of an eyelid of the user.

The light-receiving device can be used for a touch sensor (also referred to as a direct touch sensor), a near touch sensor (also referred to as a hover sensor, a hover touch sensor, a contactless sensor, or a touchless sensor), or the like.

Here, the touch sensor or the near touch sensor can detect the proximity or contact of an object (e.g., a finger, a hand, or a pen).

The touch sensor can detect an object when the display device and the object come in direct contact with each other. The near touch sensor can detect an object even when the object is not in contact with the display device. For example, the display device is preferably capable of detecting an object when the distance between the display device and the object is greater than or equal to 0.1 mm and less than or equal to 300 mm, preferably greater than or equal to 3 mm and less than or equal to 50 mm. With this structure, the display device can be controlled without an object directly contacting with the display device. In other words, the display device can be controlled in a contactless (touchless) manner. With the above structure, the display device can have a reduced risk of being dirty or damaged, or can be operated without the object directly contacting with a dirt (e.g., dust or a virus) attached to the display device.

The refresh rate can be variable in the display device of one embodiment of the present invention. For example, the refresh rate is adjusted (adjusted in the range of 1 Hz to 240 Hz, for example) in accordance with contents displayed on the display device, whereby power consumption can be reduced. The driving frequency of the touch sensor or the near touch sensor may be changed in accordance with the refresh rate. For example, when the refresh rate of the display device is 120 Hz, the driving frequency of the touch sensor or the near touch sensor can be higher than 120 Hz (can typically be 240 Hz). With this structure, low power consumption can be achieved, and the response speed of the touch sensor or the near touch sensor can be increased.

The display device 100 illustrated in FIG. 34C to FIG. 34E includes a layer 353 including a light-receiving device, a functional layer 355, and a layer 357 including a light-emitting device, between a substrate 351 and a substrate 359.

The functional layer 355 includes a circuit for driving a light-receiving device and a circuit for driving a light-emitting device. One or more of a switch, a transistor, a capacitor, a resistor, a wiring, a terminal, and the like can be provided in the functional layer 355. Note that in the case where the light-emitting device and the light-receiving device are driven by a passive-matrix method, a structure including neither a switch nor a transistor may be employed.

For example, after light emitted by the light-emitting device in the layer 357 including the light-emitting device is reflected by a finger 352 in contact with the display device 100 as illustrated in FIG. 34C, the light-receiving device in the layer 353 including the light-receiving device detects the reflected light. Thus, the contact of the finger 352 with the display device 100 can be detected.

Alternatively, the display device may have a function of detecting an object that is close to (but does not touch) the display device as illustrated in FIG. 34D and FIG. 34E or capturing an image of such an object. FIG. 34D illustrates an example where a human finger is detected, and FIG. 34E illustrates an example where information on the periphery, surface, or inside of the human eye (e.g., the number of blinks, movement of an eyeball, and movement of an eyelid) is detected.

This embodiment can be combined with any of the other embodiments as appropriate.

### Embodiment 7

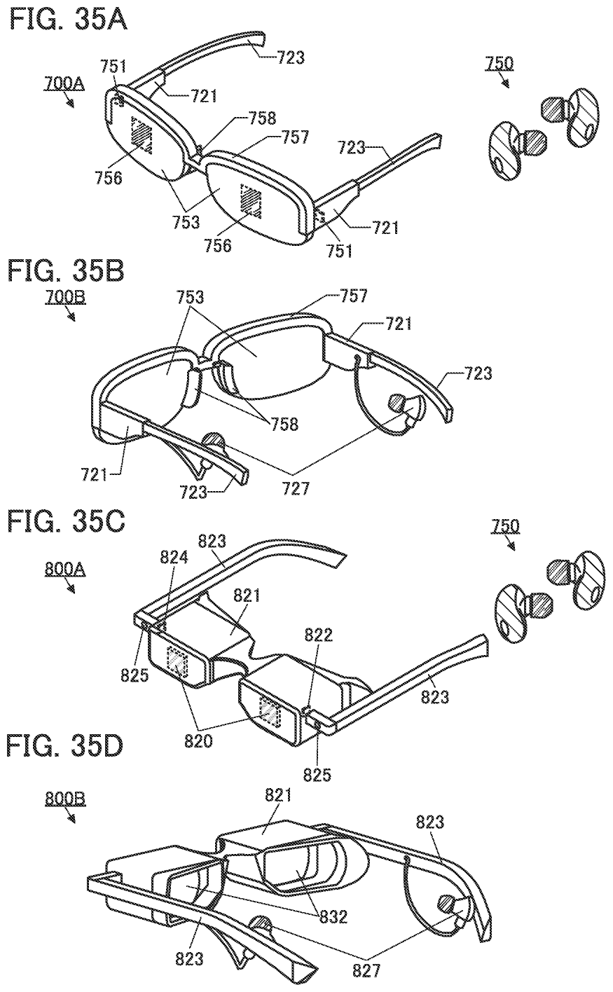

In this embodiment, electronic devices of embodiments of the present invention are described with reference to FIG. 35 to FIG. 37.

Electronic devices of this embodiment each include the display device of one embodiment of the present invention in a display portion. The display device of one embodiment of the present invention can achieve higher resolution, higher definition, and higher luminance. In the case where the display device of one embodiment of the present invention includes the light-receiving device described in Embodiment 1 and Embodiment 6, the display device can have high light detection performance. Thus, the display device of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or notebook personal computer, a monitor of a computer or the like, digital signage, and a large game machine like a pachinko machine.

In particular, the display device of one embodiment of the present invention can have a higher resolution, and thus can be suitably used for an electronic device having a relatively small display portion. Examples of such an electronic device include a watch-type or a bracelet-type information terminal device (wearable device), and a wearable device worn on a head, such as a device for VR such as a head-mounted display, a glasses-type device for AR, and a device for MR.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of the display device having one or both of such high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device that can be worn on a head are described with reference to FIG. 35A to FIG. 35D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher sense of immersion.

An electronic device 700A illustrated in FIG. 35A and an electronic device 700B illustrated in FIG. 35B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used as each of the display panels 751. Thus, the electronic devices are capable of performing ultrahigh-resolution display. In the display device of one embodiment of the present invention, light emitted from the light-emitting portion is extracted through lenses; thus, high light extraction efficiency can be achieved and an extremely bright image can be displayed. Accordingly, the display device of one embodiment of the present invention used for an electronic device capable of AR display can display an image with high visibility even when external light is intense.

In the case where the display device includes a light-receiving device, iris authentication can be performed by capturing an image of eyes with the light-receiving device. In addition, eye tracking can also be performed with the light-receiving device. By eye tracking, an object or a location at which a user looks can be specified, so that selection of the functions of the electronic device, execution of software, and the like can be performed.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A and the electronic device 700B are provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables executing various types of processing. For example, processing such as a pause or a restart of a moving image can be executed by a tap operation, and processing such as fast forward and fast rewind can be executed by a slide operation. When the touch sensor module is provided in each of the two housings 721, the range of the operation can be increased.

Any of various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device. One or both of an inorganic semiconductor and an organic semiconductor can be used for an active layer of the photoelectric conversion device.

An electronic device 800A illustrated in FIG. 35C and an electronic device 800B illustrated in FIG. 35D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, the electronic devices are capable of performing ultrahigh-resolution display. Such electronic devices provide an enhanced sense of immersion to the user.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be worn on the user's head with the wearing portions 823. FIG. 35C or the like illustrates an example where the wearing portion 823 has a shape like a temple (also referred to as a joint or the like) of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portions 825 are provided is described here, a range sensor capable of measuring a distance from an object (hereinafter also referred to as a sensing portion) just needs to be provided. In other words, the image capturing portion 825 is one embodiment of the sensing portion. As the sensing portion, an image sensor or a distance image sensor such as LIDAR (Light Detection And Ranging) can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, any one or more of the display portion 820, the housing 821, and the wearing portion 823 can employ a structure including the vibration mechanism. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 35A has a function of transmitting information to the earphones 750 with the wireless communication function. For another example, the electronic device 800A illustrated in FIG. 35C has a function of transmitting information to the earphones 750 with the wireless communication function.

The electronic device may include an earphone portion. The electronic device 700B in FIG. 35B includes earphone portions 727. For example, the earphone portion 727 and the control portion can be connected to each other by wire. Part of a wiring that connects the earphone portion 727 and the control portion may be positioned inside the housing 721 or the wearing portion 723.

Similarly, the electronic device 800B illustrated in FIG. 35D includes earphone portions 827. For example, the earphone portion 827 and the control portion 824 can be connected to each other by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, the electronic device of one embodiment of the present invention is suitable for both the glasses-type device (e.g., the electronic device 700A and the electronic device 700B) and the goggles-type device (e.g., the electronic device 800A and the electronic device 800B).

The electronic device of one embodiment of the present invention can transmit information to earphones by wire or wirelessly.

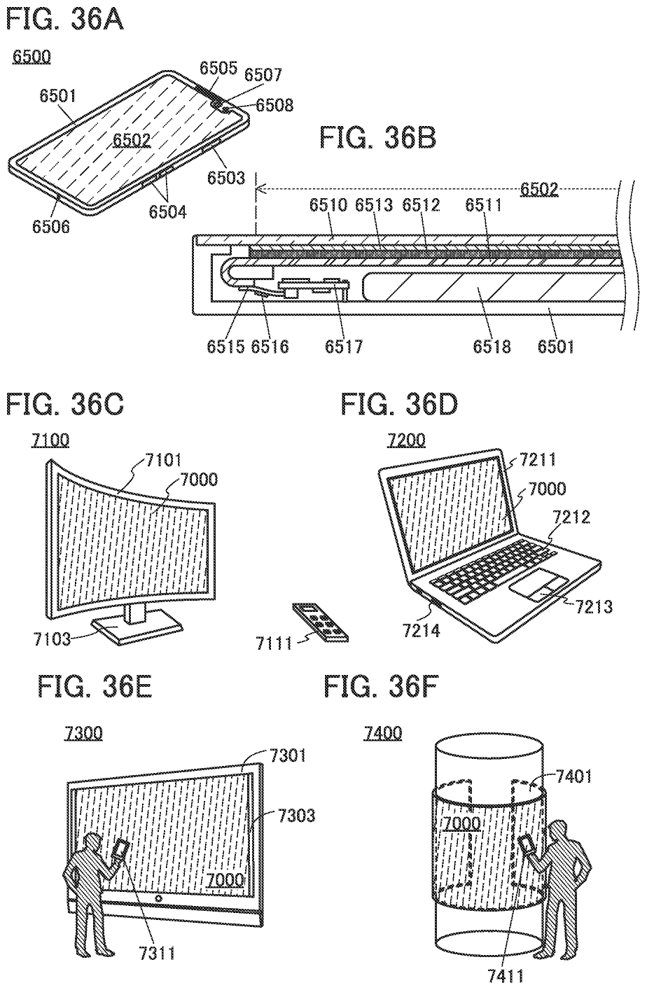

An electronic device 6500 illustrated in FIG. 36A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. In the display device of one embodiment of the present invention, light emitted from the light-emitting portion is extracted through lenses; thus, high light extraction efficiency can be achieved and an extremely bright image can be displayed.

FIG. 36B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated). The light-receiving device of the display device of one embodiment of the present invention can have the function of the touch sensor panel. The light-receiving device of the display device of one embodiment of the present invention is configured to detect light through a lens, has characteristically high photosensitivity, and excels in detecting a touched position. Moreover, an image for fingerprint authentication can be obtained with the use of the light-receiving device.

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of a pixel portion, whereby an electronic device with a narrow bezel can be achieved.

FIG. 36C illustrates an example of a television device. In a television device 7100, a display portion 7000 is incorporated in a housing 7101. Here, the housing 7101 is supported by a stand 7103.

The display device of one embodiment of the present invention can be used in the display portion 7000. In the display device of one embodiment of the present invention, light emitted from the light-emitting portion is extracted through lenses; thus, high light extraction efficiency can be achieved and an extremely bright image can be displayed.

Operation of the television device 7100 illustrated in FIG. 36C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be operated.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 36D illustrates an example of a notebook personal computer. A notebook personal computer 7200 includes a housing 7211, a keyboard 7212, a pointing device 7213, an external connection port 7214, and the like. In the housing 7211, the display portion 7000 is incorporated.

The display device of one embodiment of the present invention can be used for the display portion 7000. In the display device of one embodiment of the present invention, light emitted from the light-emitting portion is extracted through lenses; thus, high light extraction efficiency can be achieved and an extremely bright image can be displayed.

FIG. 36E and FIG. 36F illustrate examples of digital signage. In the display device of one embodiment of the present invention, light emitted from the light-emitting portion is extracted through lenses; thus, high light extraction efficiency can be achieved and an extremely bright image can be displayed.

Digital signage 7300 illustrated in FIG. 36E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 36F is digital signage 7400 attached to a cylindrical pillar 7401. The digital signage 7400 includes the display portion 7000 provided along a curved surface of the pillar 7401.

The display device of one embodiment of the present invention can be used for the display portion 7000 illustrated in each of FIG. 36E and FIG. 36F.

A larger area of the display portion 7000 allows a larger amount of information to be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation. The touch panel can include the light-receiving device of the display device of one embodiment of the present invention. The light-receiving device of the display device of one embodiment of the present invention is configured to detect light through a lens and has high photosensitivity. Thus, the touch panel can have high sensitivity and excel in detecting a touched position.

As illustrated in FIG. 36E and FIG. 36F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

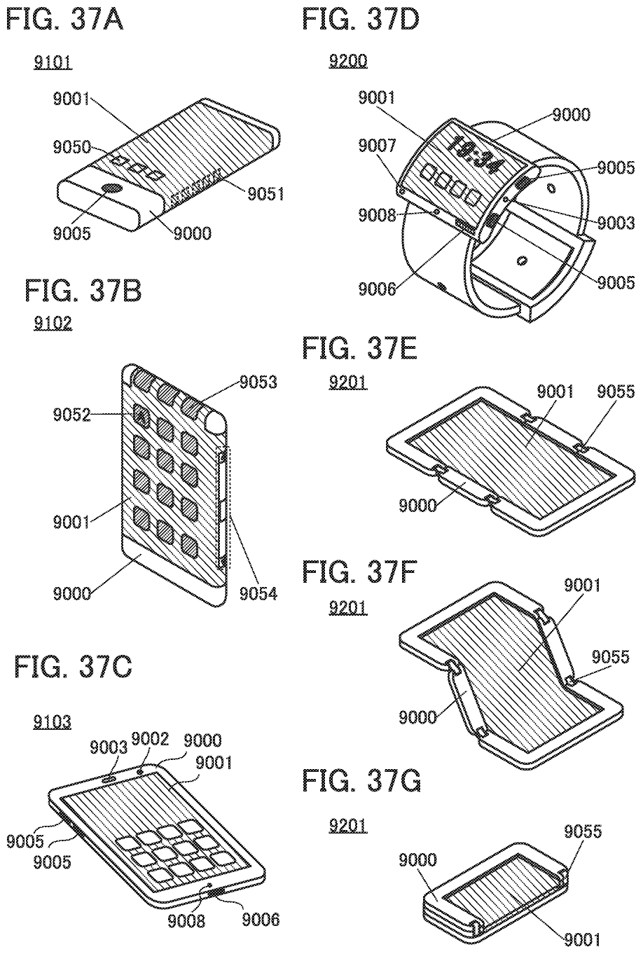

Electronic devices illustrated in FIG. 37A to FIG. 37G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The display device of one embodiment of the present invention can be used for the display portion 9001 in FIG. 37A to FIG. 37G.

The electronic devices illustrated in FIG. 37A to FIG. 37G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. In addition, the electronic devices may each include a camera or the like and have a function of taking a still image or a moving image and storing the taken image in a recording medium (an external recording medium or a recording medium incorporated in the camera), a function of displaying the taken image on the display portion, or the like.

The details of the electronic devices illustrated in FIG. 37A to FIG. 37G are described below. The display device of one embodiment of the present invention can be applied to these electronic devices. In the display device of one embodiment of the present invention, light emitted from the light-emitting portion is extracted through lenses; thus, high light extraction efficiency can be achieved and an extremely bright image can be displayed. These electronic devices can each have a function of a touch sensor panel. The light-receiving device of the display device of one embodiment of the present invention can have the function of the touch sensor panel. The light-receiving device of the display device of one embodiment of the present invention is configured to detect light through a lens, has characteristically high photosensitivity, and excels in detecting a touched position. Moreover, an image for fingerprint authentication can be obtained with the use of the light-receiving device.

FIG. 37A is a perspective view illustrating a portable information terminal 9101. The portable information terminal 9101 can be used as a smartphone, for example. Note that the portable information terminal 9101 may include the speaker 9003, the connection terminal 9006, the sensor 9007, or the like. The portable information terminal 9101 can display characters and image information on its plurality of surfaces. FIG. 37A illustrates an example where three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 37B is a perspective view illustrating a portable information terminal 9102. The portable information terminal 9102 has a function of displaying information on three or more surfaces of the display portion 9001. Here, an example is illustrated in which information 9052, information 9053, and information 9054 are displayed on different surfaces. For example, a user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 37C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the side surface of the housing 9000; and the connection terminal 9006 on the bottom surface of the housing 9000.

FIG. 37D is a perspective view illustrating a watch-type portable information terminal 9200. For example, the portable information terminal 9200 can be used as a Smartwatch (registered trademark). The display surface of the display portion 9001 is curved, and display can be performed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 37E to FIG. 37G are perspective views illustrating a foldable portable information terminal 9201. FIG. 37E is a perspective view of an opened state of the portable information terminal 9201, FIG. 37G is a perspective view of a folded state thereof, and FIG. 37F is a perspective view of a state in the middle of change from one of FIG. 37E and FIG. 37G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

When the electronic devices described in this embodiment include the display devices of embodiments of the present invention, the display devices included in the electronic devices can have high display quality. Moreover, higher-resolution display can be achieved. Higher-definition display can be achieved. Higher-luminance display can be achieved. Higher light detection performance can be achieved. Higher reliability can be achieved. Higher yield can be achieved.

This embodiment can be combined with any of the other embodiments as appropriate.

### REFERENCE NUMERALS

100A: display device, 100B: display device, 100C: display device, 100D: display device, 100E: display device, 100F: display device, 100G: display device, 100H: display device, 100: display device, 101: layer including transistors, 103: region, 110a: subpixel, 110B: subpixel, 110b: subpixel, 110c: subpixel, 110d: subpixel, 110e: subpixel, 110G: subpixel, 110R: subpixel, 110: pixel, 111a: pixel electrode, 111b: pixel electrode, 111c: pixel electrode, 111d: pixel electrode, 112a: conductive layer, 112b: conductive layer, 112c: conductive layer, 112d: conductive layer, 113A: film, 113: first layer, 114: common layer, 115: common electrode, 117: light-blocking layer, 118a: mask layer, 118A: mask film, 118b: mask layer, 119a: mask layer, 119A: mask film, 120: substrate, 122: resin layer, 123: conductive layer, 124a: pixel, 124b: pixel, 125A: insulating film, 125: insulating layer, 126a: conductive layer, 126b: conductive layer, 126c: conductive layer, 126d: conductive layer, 127a: insulating film, 127b: insulating layer, 127: insulating layer, 128: layer, 129a: conductive layer, 129b: conductive layer, 129c: conductive layer, 129d: conductive layer, 130a: light-emitting device, 130B: light-emitting device, 130b: light-emitting device, 130c: light-emitting device, 130G: light-emitting device, 130R: light-emitting device, 131: protective layer, 132B: coloring layer, 132G: coloring layer, 132R: coloring layer, 136: mask, 137: mask, 138a: insulating film, 138b: insulating layer, 138: lens, 140: connection portion, 142: adhesive layer, 150: light-receiving device, 151: substrate, 152: substrate, 155: second layer, 162: display portion, 164: circuit, 165: wiring, 166: conductive layer, 172: FPC, 173: IC, 190a: resist mask, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 351: substrate, 352: finger, 353: layer, 355: functional layer, 357: layer, 359: substrate, 700A: electronic device, 700B: electronic device, 721: housing, 723: wearing portion, 727: earphone portion, 750: earphone, 751: display panel, 753: optical member, 756: display region, 757: frame, 758: nose pad, 761: lower electrode, 762: upper electrode, 763a: EL layer, 763b: EL layer, 763: EL layer, 764: layer, 765: layer, 766: layer, 767: active layer, 768: layer, 771: light-emitting layer, 772: light-emitting layer, 773: light-emitting layer, 780: layer, 781: layer, 782: layer, 785: charge-generation layer, 790: layer, 791: layer, 792: layer, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: notebook personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display device comprising:
a first light-emitting device;
a lens over the first light-emitting device, the lens comprising a region overlapping with the first light-emitting device;
a protective layer covering the lens; and
a coloring layer over the protective layer,
wherein the first light-emitting device comprises a pixel electrode, an EL layer over the pixel electrode, and a common electrode over the EL layer,
wherein the EL layer comprises a first light-emitting material emitting blue light and a second light-emitting material emitting light having a longer wavelength than blue light,
wherein a refractive index of the lens is higher than a refractive index of the common electrode, and
wherein a refractive index of the protective layer is lower than the refractive index of the lens.

2. The display device according to claim 1,
wherein the display device comprises a second light-emitting device adjacent to the first light-emitting device, and
wherein the second light-emitting device has the same structure as the first light-emitting device and comprises an insulating layer in a region between the first light-emitting device and the second light-emitting device.

3. The display device according to claim 2,
wherein a top surface of the insulating layer has a convex curved shape.

4. The display device according to claim 1,
wherein the lens is a plano-convex lens that comprises a planar surface on a side facing the common electrode and has a convex shape on a side facing the coloring layer.

5. A display device comprising:
a first light-emitting device;
a first lens over the first light-emitting device, the first lens comprising a region overlapping with the first light-emitting device;
a light-receiving device;
a second lens over the light-receiving device, the second lens comprising a region overlapping with the light-receiving device;
a protective layer covering the first lens and the second lens; and
a coloring layer over the protective layer,
wherein the first light-emitting device comprises a first pixel electrode, an EL layer over the first pixel electrode, and a common electrode over the EL layer,
wherein the EL layer comprises a first light-emitting material emitting blue light and a second light-emitting material emitting light having a longer wavelength than blue light,
wherein the light-receiving device comprises a second pixel electrode, an active layer over the second pixel electrode, and the common electrode over the active layer,
wherein the active layer functions as a photoelectric conversion layer,
wherein a refractive index of the first lens and a refractive index of the second lens are each higher than a refractive index of the common electrode, and
wherein a refractive index of the protective layer is lower than the refractive index of the first lens and the refractive index of the second lens.

6. The display device according to claim 5,
wherein the display device comprises a second light-emitting device adjacent to each of the first light-emitting device and the light-receiving device, and
wherein the second light-emitting device has the same structure as the first light-emitting device, comprises a first insulating layer in a region between the first light-emitting device and the second light-emitting device, and comprises a second insulating layer in a region between the second light-emitting device and the light-receiving device.

7. The display device according to claim 6,
wherein the first insulating layer and the second insulating layer comprise the same material, and a top surface of the first insulating layer and a top surface of the second insulating layer each have a convex curved shape.

8. The display device according to claim 5,
wherein each of the first lens and the second lens is a plano-convex lens that comprises a planar surface on a side facing the common electrode and has a convex shape on a side facing the coloring layer.

9. An electronic device comprising the display device according to claim 1 and an optical member,
wherein the display device can project display on the optical member, and
wherein the optical member is capable of transmitting light, and an image in which an image transmitted through the optical member and the display are superimposed on each other can be seen when the optical member is seen.
